(19) United States
(12) Patent Application Publication
(10) Pub. No.: US 2026/0114114 A1
(43) Pub. Date: Apr. 23, 2026

(54) ORGANIC ELECTROLUMINESCENT ELEMENT AND COMPOSITION FOR ORGANIC MATERIALS

(71) Applicant: MERCK PATENT GMBH, DARMSTADT (DE)

(72) Inventors: Yuta NAKAMURA, Tokyo (JP); Satoru INOUE, Tokyo (JP); Taketo NAMIKAWA, Tokyo (JP); Yasuo MIYATA, Yokohama-shi (JP); Kenichi TABATA, Tokyo (JP); Hiromoto II, Tokyo (JP)

(21) Appl. No.: 19/413,234

(22) Filed: Dec. 9, 2025

Related U.S. Application Data
(63) Continuation of application No. 16/344,541.

(30) Foreign Application Priority Data
Nov. 25, 2016 (JP) 2016-228471
Apr. 7, 2017 (JP) 2017-076424
Aug. 21, 2017 (JP) 2017-158486

(51) Int. Cl. H10K 50/11; C09K 11/06; H10K 85/30; H10K 101/40

(52) U.S. Cl. CPC H10K 50/11; C09K 11/06; H10K 85/342; H10K 85/346; H10K 85/371; C09K 2211/1022; C09K 2211/1029; C09K 2211/1044; C09K 2211/1088; C09K 2211/185; H10K 2101/40

(57) ABSTRACT

The present invention addresses the problem of providing: an organic electroluminescent element which is capable of emitting light with high luminous efficiency, while having a long service life; and a composition for organic materials. An organic electroluminescent element according to the present invention comprises a positive electrode, a negative electrode and one or more organic functional layers arranged between the positive electrode and the negative electrode, and is characterized in that: the organic functional layers contain a phosphorescent metal complex and a fluorescent compound; the phosphorescent metal complex is a compound having a structure that is represented by a specific general formula; and the phosphorescent metal complex is a core-shell type dopant that satisfies a specific formula.

### CROSS REFERENCE TO RELATED APPLICATION

This application is a continuation of U.S. application Ser. No. 16/344,541, filed Apr. 24, 2019, which is U.S. National Phase application under 35 U.S.C. 371 of International Application No. PCT/JP2017/041923 filed on Nov. 22, 2017, which, in turn, claims a priority under the Paris Convention of Japanese Patent Application No. 2016-228471 filed on Nov. 25, 2016, Japanese Patent Application No. 2017-076424 filed on Apr. 7, 2017, and Japanese Patent Application No. 2017-158486 filed on Aug. 21, 2017, the entire contents of which are incorporated herein by reference.

### TECHNICAL FIELD

The present invention relates to an organic electroluminescent element and a composition for organic materials, and more particularly to an organic electroluminescent element which emits light with high efficiency and long lifetime, and a composition for organic materials.

### BACKGROUND

An organic electroluminescent element (hereinafter also referred to as “an organic EL element”) has a structure in which a light emitting layer containing a light emitting compound is sandwiched between a cathode and an anode. Electrons and holes are injected into the light emitting layer, and an exciton is generated by recombining them. It is an element that emits light using light emission (fluorescence and phosphorescence) when this exciton is deactivated. It is possible to emit light at a voltage of several V to several tens V, and since it is a self-luminescent type, it has a wide viewing angle and high visibility. In addition, since it is a thin film type complete solid-state element, attention has been drawn from the viewpoint of space saving, and portability. For organic EL elements in the future, it is desired to develop organic EL elements that emit light with high luminous efficiency with lower power consumption. Since the fluorescent compound cannot emit light from the lowest triplet excited state (hereinafter abbreviated as “T₁”), when electrons and holes are recombined in the fluorescent compound driven by an electric field, the 75% triplet excitons generated are wasted with no radiation deactivation (thermal deactivation). It has problems in luminous efficiency. On the other hand, metal complexes having heavy atoms such as Ir and Pt are capable of spin inversion by the heavy atom effect, which is inherently forbidden from the singlet excited state to the triplet excited state by the heavy atom effect, and in principle, Quantum efficiency 100% can be expected. Therefore, from the viewpoint of high luminance, attention has been focused on phosphorescent compounds having better luminous efficiency than fluorescent compounds as luminescent materials. However, with regard to the blue phosphorescent compound, satisfactory levels have not been found in terms of lifetime and color purity.

Therefore, attempts have been made to achieve both high luminous efficiency and high lifetime by causing a phosphorescent compound (particularly, a phosphorescent metal complex) and a fluorescent compound to coexist and to emit light.

For example, there are many white light emitting elements that emit light by making to exist together a blue fluorescent compound, a green phosphorescent metal complex, and a red phosphorescent compound. However, since energy transfer from T₁ of the phosphorescent metal complex to the T₁ level of the blue fluorescent compound occurs and thermal deactivation occurs from T₁ of the blue fluorescent compound, it was difficult to emit light with high efficiency and long lifetime (refer to FIG. 1).

In addition, attempts have been made to emit light with highly efficiency by using a fluorescent compound having high color purity and long lifetime. For example, it was proposed the following: a phosphorescent metal complex and a fluorescent compound are made to coexist, and energy is transferred from T₁ of the phosphorescent compound to the lowest singlet excited state (hereinafter abbreviated as “S₁”) of the fluorescent compound and fluorescence is emitted from S₁ of the fluorescent compound (that is, a phosphorescent metal complex is used as a fluorescent sensitizer) with high efficiency (for example, refer to Patent Document 1 and Non-Patent Document 1).

However, in an organic EL device in which a phosphorescent metal complex and a fluorescent light emitting compound coexist and a phosphorescent metal complex is used as a fluorescent sensitizer to cause fluorescence emission, improvement in luminous efficiency is still not sufficient compared to elements in which all light sources including a blue light source are phosphorescent. The cause is ascribed to a Dexter type energy transfer from T₁ of the phosphorescent metal complex to T₁ of the fluorescent compound and thermal deactivation occurs from T₁ of the fluorescent compound (refer to FIG. 2).

That is, both in the case of emitting light from each of the phosphorescent metal complex and the fluorescent compound and in the case of using the phosphorescent metal complex as a sensitizer for fluorescence emission from the fluorescent compound, the reason for reducing high efficiency luminescence is that the energy transfer of Dexter type from T₁ of the phosphorescent metal complex to T₁ of the fluorescent compound, and the thermal deactivation from T₁ of the fluorescent compound accompanied therewith.

These problems will be described in more detail. The phosphorescent metal complex has an exciton lifetime (τ) of phosphorescence of about several μs to several 100 μs, and in principle it is 2 to 3 orders longer than the fluorescence lifetime of the fluorescent compound.

Therefore, when a phosphorescent metal complex and a fluorescent compound are made to coexist, Dexter type energy transfer is easily caused from T₁ of the phosphorescent metal complex to the lowest triplet excited state of the fluorescent compound.

For example, as indicated in FIG. 1, when a green phosphorescent metal complex and a blue fluorescent compound are used in combination, Dexter type energy transfer occurs from T₁ of the green phosphorescent metal complex to T₁ of the blue fluorescent compound and thermal deactivates occurs from T1 of the fluorescent compound. As a result, there is a problem that the green phosphorescent luminous efficiency of the green phosphorescent metal complex is lowered. In this case, Forster type energy transfer does not occur to the lowest singlet excited state (hereinafter also referred to as “S₁”) of the blue fluorescent compound having a higher energy level than T₁ of the green phosphorescent metal complex. That is, there is no fluorescent sensitization.

Next, as indicated in FIG. 2, when a phosphorescent metal complex is used as a fluorescent sensitizer, in parallel with the Forster type energy transfer (fluorescence sensitization) from T₁ of the phosphorescent metal complex to S₁ of the fluorescent compound, Dexter type energy transfer is likely to occur to the lowest triplet excited state of the fluorescent compound. As a result, the T₁ exciton of the fluorescent compound does not emit light and causes thermal deactivation, causing a decrease in luminous efficiency.

Also, since the exciton lifetime of a phosphorescent metal complex is usually sufficiently longer than the fluorescence lifetime of a fluorescent compound, excitons generated on phosphorescent metal complexes tend to transfer energy to quenching substances generated and accumulated over time during electric field drive. As a result, thermal deactivation from the quenching substance is caused, so that luminance reduction occurs with the lapse of time of element driving. In this way, since the emission intensity of the organic EL element is lowered, when the phosphorescent metal complex is used as a fluorescent sensitizer, there occurs the problem of lowering the lifetime of the organic EL element as a result (refer to FIG. 3).

Here, the quenching phenomenon due to energy transfer from the phosphorescent metal complex to the quenching substance can be explained by the Stern-Volmer equation (Numerical formula (SV)) indicated below.

$$\frac{PL ( with Quencher )}{PL 0 ( without Quencher )} = \frac{1}{1 + K q \times [ Q ] \times τ 0} = \frac{1}{1 + K q \times ( K d \times t ) \times τ 0} \qquad Numerical formula ( SV )$$

In the numerical formula (SV), PL (with Quencher) is the emission intensity in the presence of a quenching substance, PLO (without Quencher) is the emission intensity in the absence of a quenching substance, Kq is the energy transfer rate from the luminescent material to the quenching substance, [Q](=Kd×t) is the quenching substance concentration, Kd is the formation rate of the quenching substance due to aggregation and decomposition, t is the integrated excitation time by light or electric current, and to is the phosphorescence lifetime of the luminescent material in the absence of a quenching substance.

As is apparent from the numerical formula (SV), phosphorescent metal complexes tend to cause energy transfer from the long exciton lifetime to the quenching substance. Furthermore, particularly in the blue phosphorescent metal complex, since the level of the triplet excited state is high, overlapping is likely to occur between the emission spectrum of the dopant and the absorption spectrum of the quenching substance, and the energy transfer rate (Kq) is increased. For this reason, blue phosphorescent metal complexes tend to quench in principle, and when used as a sensitizer, there is a problem with increasing the lifetime. Further, the length of the phosphorescence lifetime of the phosphorescent metal complex means the length of the excitons staying on the phosphorescent metal complex. Particularly when the element is driven under a high current density, that is, when many molecules become excited state, Triplet-triplet annihilation (TTA) which is known as a factor of lowering the light emitting property, which is not a problem at low current density, is likely to occur. Which in turn causes a significant reduction in the luminance half-life (hereinafter also referred to as “a half-life”) of the element. This is evaluated by roll-off J₀ and acceleration coefficient, and when driving under high exciton density also shows the same light emission lifetime as in the state driven at low exciton density, the acceleration factor becomes 1, and the driving condition Means that the radiation can be deactivated irrespective of the current driving condition irrespective of the current driving condition if the J 0 value is large. When it is driven under a high exciton density and shows the same light emission lifetime as that in a state driven at a low exciton density, the acceleration coefficient is 1, which means that radiation inactivation is possible regardless of the driving condition. When the J₀ value is large, it means that the light emitting property can be maintained regardless of the current driving condition. Note that J₀ refers to the current density at which the EQE value becomes half of the maximum EQE obtained by increasing the current density in the organic EL element. The acceleration coefficient is n in the following equation (E).

$${t}_{1} / {t}_{2} = {( {L}_{1} / {L}_{2} )}^{- n} \qquad Equation ( E )$$

L₁: Initial luminance at application of a current density of 2.5 mA/cm²
L₂: Initial luminance at application of a current density of 16.25 mA/cm²
t₁: Luminance half-life of the element at luminance L₁ (low luminance and low current 2.5 mA/cm²)
t₂: Luminance half-life of the element at luminance L₂ (high luminance and high current 16.25 mA/cm²

In addition, it has recently been proposed to use a fluorescent sensitizer other than a phosphorescent metal complex. For example, it was proposed a thermally activated delayed fluorescence (hereinafter abbreviated as TADF) compound as an assistant to make it emit fluorescence with high efficiency (for example, refer to Patent Document 2).

However, since the TADF compound has a longer exciton lifetime than the phosphorescent metal complex, when it is used as a sensitizer, thermal deactivation is likely to occur via a quenching substance, and there is a problem of lengthening the lifetime.

In view of the above background, it has been required a technical proposal for emitting light with high luminous efficiency and long lifetime by using a phosphorescent metal complex having high exciton resistance, which is more resistant to thermal deactivation by a quenching substance than a TADF compound.

### PRIOR ART DOCUMENTS

### Patent Documents

Patent Document 1: Japanese Patent No. 4571359
Patent Document 2: JP-A 2015-144224

### Non-Patent Document

Non-patent Document: Journal of Physics D: Applied Physics. Vol. 41 (2008) 125108

### SUMMARY OF THE INVENTION

### Problems to be Solved by the Invention

The present invention has been made in view of the above problems and circumstances. An object to be solved is to provide an organic electroluminescence element capable of emitting light with high luminous efficiency and long lifetime and to provide a composition of organic materials therefor.

### Means to Solve the Problems

In order to solve the above-mentioned problem, the present inventors examined the cause of the above problem. In the course of examination they found that it was possible to provide an organic electroluminescence element capable of emitting light with high luminous efficiency and long lifetime by an organic electroluminescence element which contains a specific phosphorescent metal complex and a fluorescent compound in the organic functional layer. Thus the present invention has been achieved.

That is, it is possible to attain the above object of the present invention by the following means.
1. An organic electroluminescent element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by Formula (1), and the phosphorescent metal complex satisfies the following Expression (a).

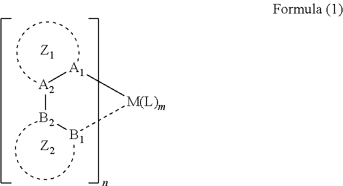

In Formula (1): M represents Ir or Pt; A₁, A₂, B₁ and B₂ each independently represent a carbon atom or a nitrogen atom; a ring Z₁ represents a 6-membered aromatic hydrocarbon ring, or a 5- or 6-membered aromatic heterocyclic ring formed with A₁ and A₂, or an aromatic condensed ring containing at least one of the aforesaid rings; a ring Z₂ represents a 5- or 6-membered aromatic heterocyclic ring formed with B₁ and B2, or an aromatic condensed ring containing at least one of the aforesaid rings; among a bond between A₁ and M, and a bond between B₁ and M, one is a coordinate bond and the other is a covalent bond; the ring Z₁ and the ring Z₂ each independently may have a substituent, and the ring Z₁ and the ring Z₂ have at least one substituent represented by Formula (2); the substituent of the ring Z₁ and the substituent of the ring Z₁₂ may be bonded to form a condensed ring structure, and ligands represented by the ring Z₁ and the ring Z₂ may be linked to each other; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, the ligands represented by the ring Z₁ and the ring Z₂, or L may be the same or different; the ligands represented by the ring Z₁ and the ring Z₂ may be linked to L.

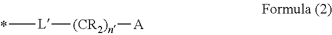

In Formula (2), a symbol * represents a linking site with the ring Z₁ or the ring Z₂ in Formula (1); L′ represents a single bond or a linking group; R represents a hydrogen atom or a substituent; n′ represents an integer of 3 or more; a plurality of Rs may be the same or different; and A represents a hydrogen atom or a substituent.

$$\{ {V}_{all} / {V}_{core} \} > 2 \qquad Expression ( a )$$

In Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions.
2. The organic electroluminescent element described in the embodiment 1, wherein L′ in Formula (2) represents a non-conjugated linking group.
3. The organic electroluminescent element described in the embodiment 1 or 2, wherein the ligands represented by Z₁ and Z₂ in Formula (1) contain three or more substituents.
4. An organic electroluminescent element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by any one of Formulas (3) to (5), and the phosphorescent metal complex satisfies the following Expression (b).

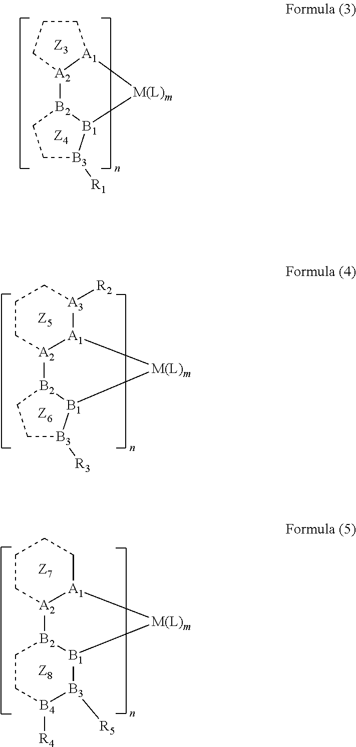

In Formulas (3) to (5): M represents Ir or Pt; A₁ to A₃, and B₁ to B₄ each independently represent a carbon atom or a nitrogen atom; among a bond between A₁ and M, and a bond between B₁ and M, one is a coordinate bond and the other is a covalent bond; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, ligands represented by a ring Z₃ and a ring Z₄, ligands represented by a ring Z₅ and a ring Z₆, and ligands represented by a ring Z₇ and a ring Z₈, or L may be the same or different; the ligands represented by the ring Z₃ to Z₈ may be linked to L.

In Formula (3), the ring Z₃ represents a 5-membered aromatic heterocyclic ring formed with A₁ and A₂, or an aromatic condensed ring containing the aforesaid ring; the ring Z₄ represents a 5-membered aromatic heterocyclic ring formed with B₁ to B₃, or an aromatic condensed ring containing the aforesaid ring; R₁ represents a substituent having 2 or more carbon atoms; the ring Z₃ and the ring Z₄ may have a substituent besides R₁ and may form a condensed ring structure by bonding of the substituents of the ring Z₃ and the ring Z4; the ligands represented by the ring Z₃ and the ring Z₄ may be linked to each other.

In Formula (4), the ring Z₅ represents a 6-membered aromatic hydrocarbon ring, a 6-membered aromatic heterocyclic ring formed with A₁ to A₃, or an aromatic condensed ring containing at least one of the aforesaid rings; the ring Z₆ represents a 5-membered aromatic heterocyclic ring formed with B₁ to B₃, or an aromatic condensed ring containing at least one of the aforesaid rings; R₂ and R₃ each represent a hydrogen atom or a substituent, at least one of R₂ and R₃ represents a substituent having 2 or more carbon atoms; the ring Z₅ and the ring Z₆ may have a substituent besides R₂ and R₃ and may form a condensed ring structure by bonding of the substituents of the ring Z₅ and the ring Z₆, and the ligands represented by the ring Z₅ and the ring Z₆ may be linked to each other.

In Formula (5), the ring Z₇ represents a 6-membered aromatic hydrocarbon ring, a 6-membered aromatic heterocyclic ring formed with A₁ and A₂, or an aromatic condensed ring containing at least one of the aforesaid rings; the ring Z₈ represents a 6-membered aromatic hydrocarbon ring or a 6-membered aromatic heterocyclic ring formed with B₁ to B₄, or an aromatic condensed ring containing at least one of the aforesaid rings; R₄ and R₅ each represent a hydrogen atom or a substituent, at least one of R₄ and R₅ represents a substituent having 2 or more carbon atoms; the ring Z₇ and the ring Z₈ may have a substituent besides R₄ and R₅ and may form a condensed ring structure by bonding of the substituents of the ring Z₇ and the ring Z₈, and the ligands represented by the ring Z₇ and the ring Z₈ may be linked to each other.

$$\{ {V}_{all} / {V}_{core} \} > 2 \qquad Expression ( b )$$

In Expression (b), Vₐₗₗ represents a molecular volume of a compound having a chemical structure represented by any one of Formulas (3) to (5) including the substituents bonded to the ring Z₃ to the ring Z₈; when M represents Ir, n=3 and m=0 are fixed, and when M represents Pt, n=2 and m=0 are fixed; V_{core} represents a molecular volume of a compound having a chemical structure in which the substituent bonded to the ring Z₃ to the ring Z₈ is replaced with a hydrogen atom from the chemical structure indicating the molecular volume of Vₐn; and when there are a plurality of ligands represented by the ring Z₃ and the ring Z₄, ligands represented by the ring Z₅ and the ring Z₆, ligands represented by the ring Z₇ and the ring Z₈, Vₐₗₗ and V_{core} satisfy Expression (b) in all cases expressed by the aforesaid conditions.
5. The organic electroluminescent element described in the embodiment 4, wherein the ligands represented by the ring Z₃ and the ring Z₄ in Formula (3), the ligands represented by the ring Z₅ and the ring Z₆ in Formula (4), or the ligands represented by the ring Z₇ and the ring Z₈ in Formula (5) have three or more substituents.
6. The organic electroluminescent element described in any one of the embodiments 1 to 5, having an overlap between an emission spectrum of the phosphorescent metal complex and an absorption spectrum of the fluorescent compound.
7. The organic electroluminescent element described in any one of the embodiments 1 to 6, wherein the phosphorescent metal complex and the fluorescent compound satisfy at least one of the following Expression (c) and Expression (d),

$$P ( HOMO ) > FL ( HOMO ) \qquad Expression ( c )$$

In Expression (c), P(HOMO) represents a HOMO energy level of the phosphorescent metal complex, and FL(HOMO) represents a HOMO energy level of the fluorescent compound.

$$P ( LUMO ) < FL ( LUMO ) \qquad Expression ( d )$$

In Expression (d), P(LUMO) represents a LUMO energy level of the phosphorescent metal complex, and FL(LUMO) represents a LUMO energy level of the fluorescent compound.
8. The organic electroluminescent element described in any one of the embodiments 1 to 7, having a gas barrier layer which has a water vapor permeability in the range of 0.001 to 1 g/(m²·day) measured by a method in accordance with JIS K 7129-1992 and an oxygen permeability in the range of 0.001 to 1 mL/(m²·day) measured by a method in accordance with JIS K 7126-1987.
9. A composition for organic materials containing a phosphorescent metal complex and a fluorescent compound, wherein the phosphorescent metal complex is a compound having a structure represented by Formula (1), and the phosphorescent metal complex satisfies the following Expression (a).

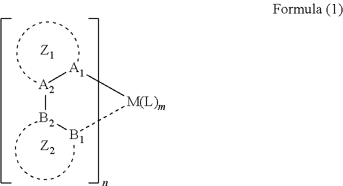

In Formula (1): M represents Ir or Pt; A₁, A₂, B₁ and B₂ each independently represent a carbon atom or a nitrogen atom; a ring Z₁ represents a 6-membered aromatic hydrocarbon ring, or a 5- or 6-membered aromatic heterocyclic ring formed with A₁ and A₂, or an aromatic condensed ring containing at least one of the aforesaid rings; a ring Z₂ represents a 5- or 6-membered aromatic heterocyclic ring formed with B₁ and B2, or an aromatic condensed ring containing at least one of the aforesaid rings; among a bond between A₁ and M, and a bond between B₁ and M, one is a coordinate bond and the other is a covalent bond; the ring Z₁ and the ring Z₂ each independently may have a substituent, and the ring Z₁ and the ring Z₂ have at least one substituent represented by Formula (2); the substituent of the ring Z₁ and the substituent of the ring Z₁₂ may be bonded to form a condensed ring structure, and ligands represented by the ring Z₁ and the ring Z₂ may be linked to each other; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, the ligands represented by the ring Z₁ and the ring Z₂, or L may be the same or different; the ligands represented by the ring Z₁ and the ring Z₂ may be linked to L.

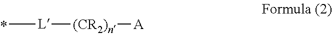

In Formula (2), a symbol * represents a linking site with the ring Z₁ or the ring Z₂ in Formula (1); L′ represents a single bond or a linking group; R represents a hydrogen atom or a substituent; n′ represents an integer of 3 or more; a plurality of Rs may be the same or different; and A represents a hydrogen atom or a substituent.

$$\{ {V}_{all} / {V}_{core} \} > 2 \qquad Expression ( a )$$

In Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions.
10. A composition for organic materials containing a phosphorescent metal complex and a fluorescent compound, wherein the phosphorescent metal complex is a compound having a structure represented by any one of Formulas (3) to (5), and the phosphorescent metal complex satisfies the following Expression (b).

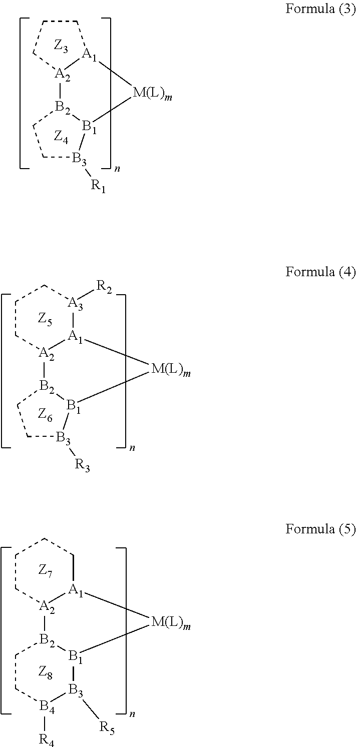

In Formulas (3) to (5): M represents Ir or Pt; A₁ to A₃, and B₁ to B₄ each independently represent a carbon atom or a nitrogen atom; among a bond between A₁ and M, and a bond between B₁ and M, one is a coordinate bond and the other is a covalent bond; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, ligands represented by a ring Z₃ and a ring Z₄, ligands represented by a ring Z₅ and a ring Z₆, and ligands represented by a ring Z₇ and a ring Z₈, or L may be the same or different; the ligands represented by the ring Z₃ to Z₈ may be linked to L.

In Formula (3), the ring Z₃ represents a 5-membered aromatic heterocyclic ring formed with A₁ and A₂, or an aromatic condensed ring containing the aforesaid ring; the ring Z₄ represents a 5-membered aromatic heterocyclic ring formed with B₁ to B₃, or an aromatic condensed ring containing the aforesaid ring; R₁ represents a substituent having 2 or more carbon atoms; the ring Z₃ and the ring Z₄ may have a substituent besides R₁ and may form a condensed ring structure by bonding of the substituents of the ring Z₃ and the ring Z4; the ligands represented by the ring Z₃ and the ring Z₄ may be linked to each other.

In Formula (4), the ring Z₅ represents a 6-membered aromatic hydrocarbon ring, a 6-membered aromatic heterocyclic ring formed with A₁ to A₃, or an aromatic condensed ring containing at least one of the aforesaid rings; the ring Z₆ represents a 5-membered aromatic heterocyclic ring formed with B₁ to B₃, or an aromatic condensed ring containing at least one of the aforesaid rings; R₂ and R₃ each represent a hydrogen atom or a substituent, at least one of R₂ and R₃ represents a substituent having 2 or more carbon atoms; the ring Z₅ and the ring Z₆ may have a substituent besides R₂ and R₃ and may form a condensed ring structure by bonding of the substituents of the ring Z₅ and the ring Z₆, and the ligands represented by the ring Z₅ and the ring Z₆ may be linked to each other.

In Formula (5), the ring Z₇ represents a 6-membered aromatic hydrocarbon ring, a 6-membered aromatic heterocyclic ring formed with A₁ and A₂, or an aromatic condensed ring containing at least one of the aforesaid rings; the ring Z₈ represents a 6-membered aromatic hydrocarbon ring or a 6-membered aromatic heterocyclic ring formed with B₁ to B₄, or an aromatic condensed ring containing at least one of the aforesaid rings; R₄ and R₅ each represent a hydrogen atom or a substituent, at least one of R₄ and R₅ represents a substituent having 2 or more carbon atoms; the ring Z₇ and the ring Z₈ may have a substituent besides R₄ and R₅ and may form a condensed ring structure by bonding of the substituents of the ring Z₇ and the ring Z₈, and the ligands represented by the ring Z₇ and the ring Z₈ may be linked to each other.

$$\{ {V}_{all} / {V}_{core} \} > 2 \qquad Expression ( b )$$

In Expression (b), Vₐₗₗ represents a molecular volume of a compound having a chemical structure represented by any one of Formulas (3) to (5) including the substituents bonded to the ring Z₃ to the ring Z₈; when M represents Ir, n=3 and m=0 are fixed, and when M represents Pt, n=2 and m=0 are fixed; V_{core} represents a molecular volume of a compound having a chemical structure in which the substituent bonded to the ring Z₃ to the ring Z₈ is replaced with a hydrogen atom from the chemical structure indicating the molecular volume of Vₐₗₗ; and when there are a plurality of ligands represented by the ring Z₃ and the ring Z₄, ligands represented by the ring Z₅ and the ring Z₆, ligands represented by the ring Z₇ and the ring Z₈, Vₐₗₗ and V_{core} satisfy Expression (b) in all cases expressed by the aforesaid conditions.

### Effects of the Invention

By the above-described embodiments of the present invention, it is possible to provide an organic electroluminescence element and a composition for organic materials capable of emitting light (phosphorescence emission and fluorescence emission) with high luminous efficiency and long lifetime in a light emitting layer containing a phosphorescent metal complex and a fluorescent compound. As a more preferable effect, it is possible to provide an electroluminescent element capable of increasing fluorescence emission (fluorescent sensitization) from a fluorescent compound with a phosphorescent metal complex.

A formation mechanism or an action mechanism of the effects of the present invention is not clearly identified, but it is supposed as follows.

First, the case of phosphorescence emission from a phosphorescent metal complex will be described.

<Reduction in Phosphorescent Efficiency from Phosphorescent Metal Complex>

As indicated in FIG. 1, when a green phosphorescent metal complex and a blue fluorescent compound are used in combination, energy transfer from T₁ of the green phosphorescent metal complex to T₁ of the blue fluorescent compound occurs in a Dexter type energy transfer and heat deactivation occurs from T₁ of the fluorescent compound. As a result, reduction in efficiency of green phosphorescence emission from the green phosphorescent metal complex is caused.

<Suppression of Reduction in Phosphorescent Efficiency from Phosphorescent Metal Complex>

In order to suppress the decrease in the phosphorescent efficiency and to make fluorescence with high efficiency, it can be accomplished by suppressing thermal deactivation via Dexter type energy transfer from T₁ of the phosphorescent metal complex to T₁ of the fluorescent compound causing reduction in efficiency. Therefore, the inventors of the present invention used a dopant (hereinafter also referred to as “a core-shell type dopant”) having a core portion and a shell portion as the phosphorescent metal complex.

As indicated in FIG. 4, a core-shell type dopant 10 has a shell portion 12 around a core portion 11. Therefore, the core-shell type dopant 10 enables to provide a physical distance between the core portion 11 which is the luminescence center and a fluorescent compound 13, as compared with a usual dopant 20.

Note that Dexter type energy transfer is large in distance dependence and energy transfer is difficult when the distance between compounds is large. On the other hand, Förster energy transfer is less dependent on distance, and energy transfer is less likely to decrease even if the distance between compounds is large.

As a result, as indicated in FIG. 5, it is possible to suppress Dexter type energy transfer, which has a large distance dependence of energy transfer, and make phosphorescence emission with high efficiency.

Next, the case where the phosphorescent metal complex is used as a sensitizer for fluorescence emission and fluorescence is emitted from the fluorescent compound will be described.

### <Expression of Fluorescence Sensitization by Phosphorescent Metal Complex>

As indicated in FIG. 2, fluorescence sensitization with a phosphorescent metal complex is done via Forster energy transfer from T₁ of a phosphorescent metal complex to S₁ of a fluorescent compound to result in fluorescence emission from the fluorescent compound. This Förster type energy transfer is likely to occur when there is overlap between the emission spectrum of the luminescent metal complex and the absorption spectrum of the fluorescent compound. Therefore, in order to obtain the effect of the present invention, it is preferable that the luminescent metal complex and the fluorescent luminescent compound satisfy the above-described conditions.

### <Expression Mechanism of High Efficiency Fluorescence Emission>

In order to use fluorescent metal complex as a sensitizer and to make fluorescence emission with higher efficiency than conventional, it can be accomplished by suppressing thermal deactivation via Dexter type energy transfer from T₁ of the phosphorescent metal complex to T₁ of the fluorescent compound causing efficiency decrease.

Therefore, the inventors of the present invention used a core-shell type dopant as a phosphorescent metal complex.

Note that Dexter type energy transfer is large in distance dependence and energy transfer is difficult when the distance between compounds is large. On the other hand, Förster energy transfer is less dependent on distance, and energy transfer is less likely to decrease even if the distance between compounds is large.

As a result, as indicated in FIG. 6, it is possible to preferentially suppress Dexter type energy transfer having a large distance dependence of energy transfer, and make fluorescence emission with high efficiency.

### <Simultaneous Expression Mechanism of High Luminous Efficiency and Long Lifetime Fluorescence>

In order to make fluorescent light emission with a higher efficiency and a longer lifetime than before by using a phosphorescent metal complex as a sensitizer, it is also important to suppress the energy transfer from the sensitizer to the quenching substance, which causes a decrease in the lifetime. This problem can also be solved by using a core-shell type dopant as a sensitizer. That is, as indicated in FIG. 7, when a core-shell type dopant is used, the physical distance between the fluorescent compound and the quenching substance generated at the same time of driving can also be increased.

As a result, it is possible to suppress inactivation (Kq in the numerical formula (SV)) due to Dexter transfer to the quenching substance. Therefore, even if a quenching substance is generated over time, it is possible to obtain an organic EL element in which thermal deactivation hardly occurs.

In addition, it is difficult for roll-off to occur even when driven under high current density due to ultrafast exciton discharge that could not be achieved with the phosphorescent compound alone. As a result, even when driven under a high current density, it is possible to provide an element that is close to the driving condition under a low current density, that is, an element that suppresses an increase in the acceleration coefficient (that is, the acceleration coefficient n is close to 1).

In this way, it is presumed that a luminescent element with higher lifetime and higher efficiency than the conventional one can be manufactured.

Quenching of S₁ of the quenching substance by Förster energy transfer is in a competitive relationship with Förster energy transfer to S₁ of the fluorescent compound.

Therefore, it is presumed that it is possible to further suppress the deactivation by the quenching substance by giving priority to the Förster energy transfer to S₁ of the fluorescent compound.

For example, by increasing the overlap between the emission spectrum of the phosphorescent metal complex and the absorption spectrum of the fluorescent compound, the Förster energy transfer to S₁ of the fluorescent compound may be preferentially occurred. It is presumed that it can further emit fluorescence with higher luminous efficiency and longer lifetime.

Further, suppression of deactivation by a quenching substance improves the resistance to quenching substances such as water and oxygen. As a result, the gas barrier layer according to the present invention does not require the high gas barrier property conventionally employed. Conventionally, for example, in order to secure the reliability of a flexible organic EL element, it is necessary to have a gas barrier layer having a high gas barrier property with respect to a flexible substrate, which was one of the factors to increase the cost. Since the luminescent material according to the present invention is resistant to water and oxygen, a gas barrier layer having high gas barrier property is not required, and as a result, even when a gas barrier layer having low gas barrier property is adopted, it can withstand practical use and eventually it can reduce the cost. As the performance of the gas barrier layer according to the present invention, it is preferable that the gas barrier layer has gas barrier properties of the water vapor permeability (WVTR) measured by a method in accordance with JIS K 7129-1992 in the range 0.001 to 1 g/(m²·day) and the oxygen permeability (OTR) measured by a method in accordance with JIS K 7126-1987 in the range 0.001 to 1 mL/(m²·day·atm). It can withstand practical use even if it does not have a high gas barrier property as in the past, for example, WVTR does not have a gas barrier property of 1.0×10⁻⁵ g/(m²·day) or less. More preferably, the performance of the gas barrier layer according to the present invention is that WVTR is in the range of 0.01 to 1 g/(m²·day) and OTR is in the range of 0.01 to 1 mL/(m²·day·atm). The gas barrier layer of the present invention may be formed on a substrate, or as a sealing member, or both of them in the organic EL element, and can be arbitrarily placed depending on the form of the organic EL element.

The difference between the organic EL element of the present invention and the conventional organic EL element will be further described with reference to FIG. 8A and FIG. 8B.

### (1) Driving Under Low Current Density

The amount of excitons formed in the light emitting layer is small. Therefore, even in the conventional technique using the phosphorescent compound and the host compound, the excitons produced interact by a mechanism such as TTA and do not cause nonradiative deactivation.

### (2) Suppression of Emission Reduction by TTA

The amount of excitons formed in the light emitting layer is large. Therefore, in the prior art, since the exciton discharging ability is as low as μ sec, nonradiative deactivation is developed by interaction by a mechanism such as TTA (refer to FIG. 8A). On the other hand, in the present invention, since the generated exciton can rapidly radiate and deactivate to the ground state, it is difficult for TTA to occur, and the luminescence can be maintained (refer to FIG. 8B). Therefore, it is possible to emit light at a near condition of a low current density driving and the acceleration coefficient becomes close to 1.

### (3) Suppression of Emission Reduction by Recombination Position

When the carrier balance is destroyed due to driving under a high current density and light is emitted near the interface between HTL and ETL, in the prior art, as in (2), it causes a nonradiative deactivation process by interaction of a mechanism such as TTA (refer to FIG. 8A). On the other hand, in the present invention, even when the recombination position is shifted to the interface as in the conventional technique, it is possible to transfer energy to the fluorescent compound by Förster energy transfer. Therefore, the light emitting region can be widely used as compared with the prior art, and the exciton density can be relaxed (refer to FIG. 8B). In addition, since the energy transfer to the fluorescent compound can greatly shorten the exciton retention time, it becomes more difficult for nonradiative deactivation to occur.

### (4) Suppression of Light Emission Reduction Due to Fluctuation of Light Emitting Position During Element Driving

Even when the excitons are recombined at the ideal light emitting position in the initial state, the film quality fluctuates due to energization and driving heat while the element is being driven, and the carrier balance is changed, whereby the light emitting property is reduced as described in the above (3) (refer to FIG. 8A). According to the present invention, as described in the above (3), it is possible not only to widely use the light emitting region even when the recombination position varies during driving, but also to promptly discharge excitons. For this reason, it is also effective to suppress the decrease of the light emitting property due to the fluctuation of the recombination position during driving (refer to FIG. 8B).

### BRIEF DESCRIPTION OF THE DRAWINGS

FIG. 1 is a diagram indicating energy levels (in the case of no fluorescent sensitization) in a case where a conventional green luminescent metal complex and a blue fluorescent compound are used in combination.

FIG. 2 is a diagram indicating energy levels of a phosphorescent metal complex and a fluorescent compound in the case of fluorescent sensitization using a conventional phosphorescent metal complex.

FIG. 3 is a diagram indicating energy levels of a phosphorescent metal complex, a fluorescent compound, and a quenching substance in the case of fluorescence sensitization using a conventional phosphorescent metal complex.

FIG. 4 is a conceptual diagram explaining the relationship between the core-shell type dopant and the fluorescent compound and the relationship between the ordinary dopant (phosphorescent metal complex) and the fluorescent compound.

FIG. 5 is a diagram indicating energy levels in the case of using a green luminescent core-shell type dopant and a blue fluorescent compound in combination (in the case of no fluorescence sensitization).

FIG. 6 is a diagram indicating energy levels of a core-shell type dopant and a fluorescent compound in the case of fluorescent sensitization using a core-shell type dopant.

FIG. 7 is a diagram indicating energy levels of a core-shell type dopant, a fluorescent compound and a quenching substance in the case of fluorescence sensitization using a core-shell type dopant.

FIG. 8A is a schematic drawing for explaining light emission in the light emitting layer of the conventional organic EL element.

FIG. 8B is a schematic drawing for explaining the light emission in the light emitting layer of the organic EL element according to the present invention.

FIG. 9 is a schematic perspective view indicating an example of a display device using the organic EL element of the present invention.

FIG. 10 is a schematic perspective view indicating an example of the configuration of the display unit A described in FIG. 9.

FIG. 11 is a schematic perspective view indicating an example of a lighting device using the organic EL element of the present invention.

FIG. 12 is a schematic perspective view indicating an example of a lighting device using the organic EL element of the present invention.

FIG. 13 is a schematic cross-sectional view indicating an example of a lighting device using the flexible organic EL element of the present invention.

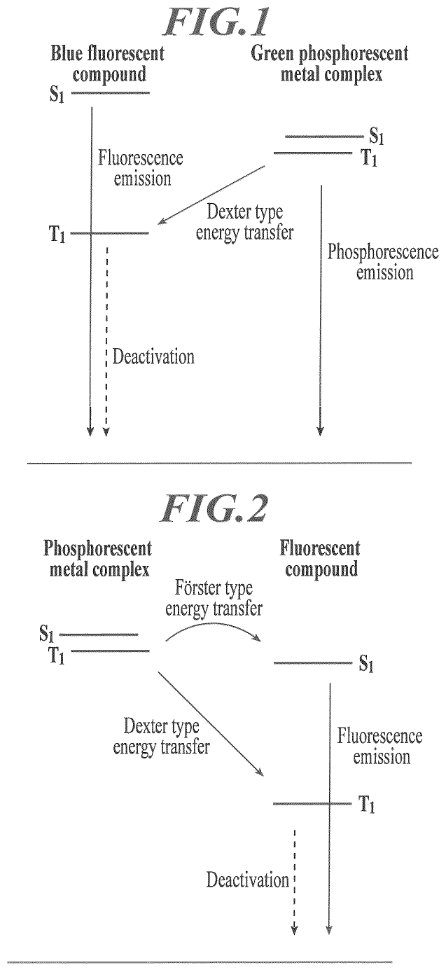

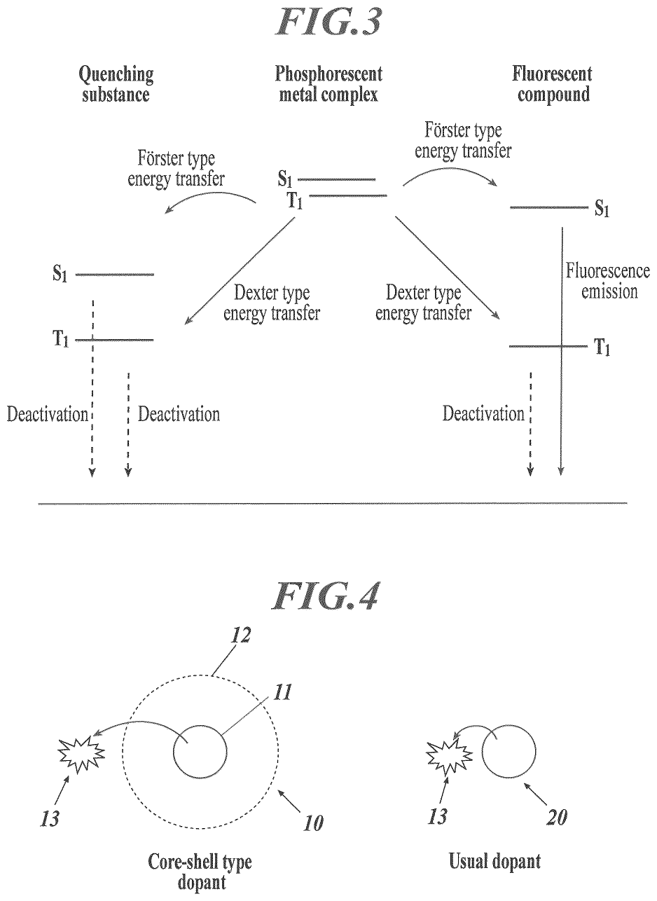

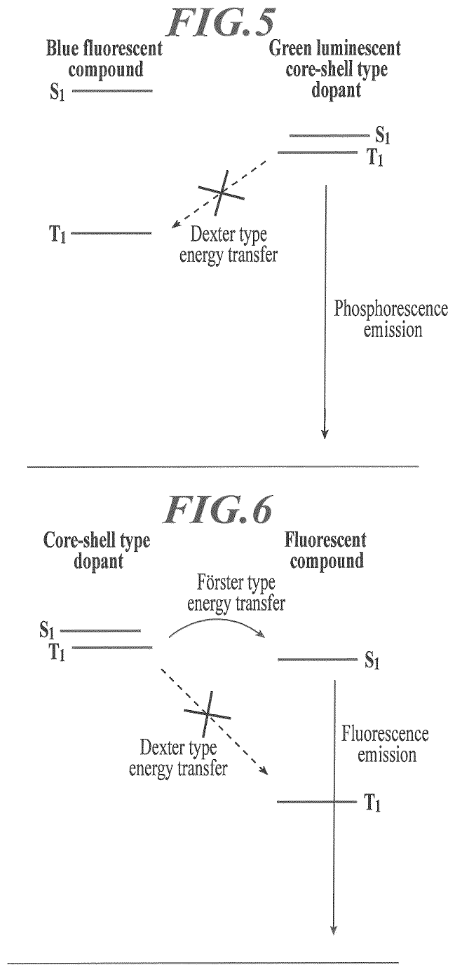

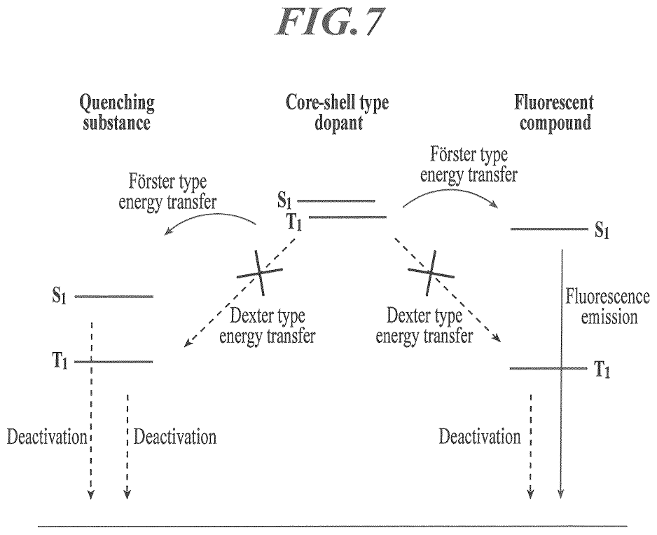

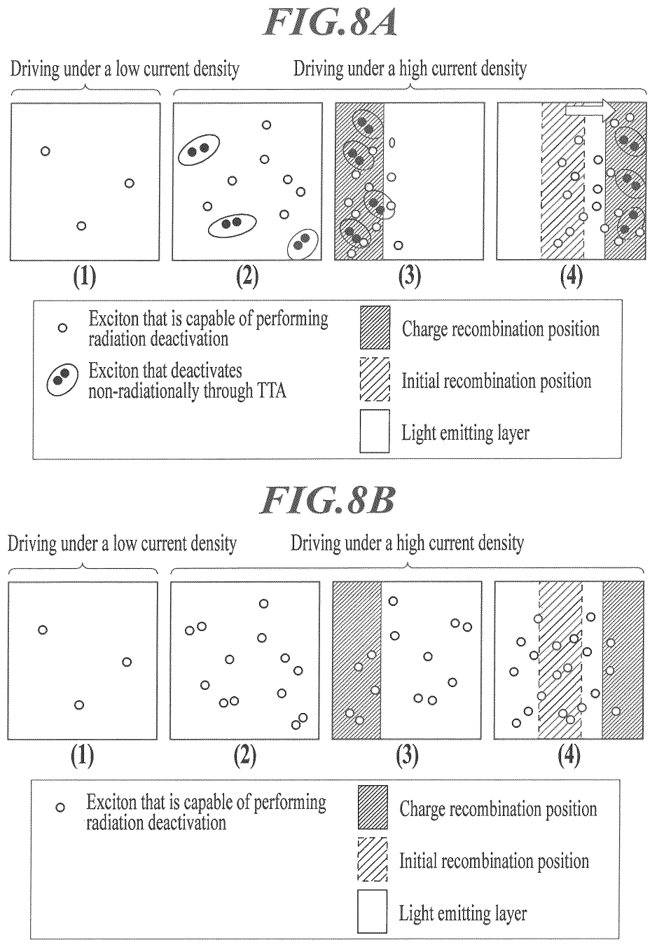

### EMBODIMENTS TO CARRY OUT THE INVENTION

An organic electroluminescent element of the present invention is an organic electroluminescent element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by Formula (1), and the phosphorescent metal complex satisfies the above-described Expression (a). This feature is a technical feature common or corresponding to the following embodiments.

As an embodiment, from the viewpoint of manifesting the effect of the present invention, it is preferable that L′ in Formula (2) represents a non-conjugated linking group to obtain an organic electroluminescence element capable of emitting light with high luminous efficiency and long lifetime. It is also preferable from the viewpoint that fluorescence can be enhanced by fluorescence sensitization with high luminous efficiency and long lifetime.

Further, it is preferable that the ligand represented by the ring Z₁ and the ring Z₂ in Formula (1) have three or more substituents. Thereby, an organic electroluminescence element capable of emitting fluorescence with high luminous efficiency and long lifetime can be obtained. It is also preferable from the viewpoint that fluorescence can be enhanced by fluorescence sensitization with high luminous efficiency and long lifetime.

An organic electroluminescent element of the present invention is an organic electroluminescent element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by any one of the above-described Formulas (3) to (5), and the phosphorescent metal complex satisfies the above-described Expression (b).

As an embodiment, from the viewpoint of manifesting the effect of the present invention, it is preferable that the ligands represented by the ring Z₃ and the ring Z₄ in Formula (3), the ligands represented by the ring Z₅ and the ring Z₆ in Formula (4), or the ligands represented by the ring Z₅ and the ring Z₆ in Formula (5) have three or more substituents to obtain an organic electroluminescence element capable of emitting light with high luminous efficiency and long lifetime. It is also preferable from the viewpoint that fluorescence can be enhanced by fluorescence sensitization with high luminous efficiency and long lifetime.

It is preferable that the organic electroluminescent element of the present invention has an overlap between an emission spectrum of the phosphorescent metal complex and an absorption spectrum of the fluorescent compound to obtain an organic electroluminescence element capable of emitting light with high luminous efficiency and long lifetime.

It is preferable that the phosphorescent metal complex and the fluorescent compound in the organic electroluminescent element of the present invention satisfy at least one of the above-described Expression (c) and Expression (d) to obtain an organic electroluminescence element capable of emitting light with high luminous efficiency and long lifetime.

As an embodiment, it is preferable that the organic electroluminescent element of the present invention has a gas barrier layer which has a water vapor permeability in the range of 0.001 to 1 g/(m²·day) measured by a method in accordance with JIS K 7129-1992 and an oxygen permeability in the range of 0.001 to 1 mL/(m²·day) measured by a method in accordance with JIS K 7126-1987.

As described above, according to the present invention,

it is possible to withstand practical use even when a gas barrier layer having low gas barrier property is adopted, and it can reduce the cost. The composition for organic materials of the present invention is a composition for organic materials containing a phosphorescent metal complex and a fluorescent compound, wherein the phosphorescent metal complex is a compound having a structure represented by the above-described Formula (1), and the phosphorescent metal complex satisfies the above-described Expression (a).

The composition for organic materials of the present invention is a composition for organic materials containing a phosphorescent metal complex and a fluorescent compound, wherein the phosphorescent metal complex is a compound having a structure represented by any one of the above-described Formulas (3) to (5), and the phosphorescent metal complex satisfies the above-described Expression (b). The composition for organic materials may be contained in the organic functional layer.

The present invention and the constitution elements thereof, as well as configurations and embodiments, will be detailed in the following. In the present description, when two figures are used to indicate a range of value before and after “to”, these figures are included in the range as a lowest limit value and an upper limit value.

### <<Outline of Organic Electroluminescence Element According to First Embodiment of the Present Invention>>

An organic electroluminescence element according to first embodiment of the present invention is an organic electroluminescence element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by the following Formula (1), and the phosphorescent metal complex satisfies the following Expression (a).

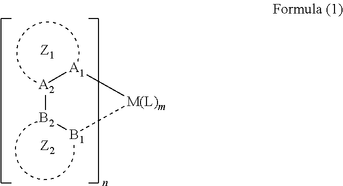

In Formula (1): M represents Ir or Pt; A₁, A₂, B₁ and B₂ each independently represent a carbon atom or a nitrogen atom; a ring Z₁ represents a 6-membered aromatic hydrocarbon ring, or a 5- or 6-membered aromatic heterocyclic ring formed with A₁ and A₂, or an aromatic condensed ring containing at least one of the aforesaid rings; a ring Z₂ represents a 5- or 6-membered aromatic heterocyclic ring formed with B₁ and B2, or an aromatic condensed ring containing at least one of the aforesaid rings; among a bond between A₁ and M, and a bond between B₁ and M, one is a coordinate bond and the other is a covalent bond; the ring Z₁ and the ring Z₂ each independently may have a substituent, and the ring Z₁ and the ring Z₂ have at least one substituent represented by Formula (2); the substituent of the ring Z₁ and the substituent of the ring Z₁₂ may be bonded to form a condensed ring structure, and ligands represented by the ring Z₁ and the ring Z₂ may be linked to each other; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, the ligands represented by the ring Z₁ and the ring Z₂, or L may be the same or different; the ligands represented by the ring Z₁ and the ring Z₂ may be linked to L.

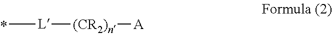

In Formula (2), a symbol * represents a linking site with the ring Z₁ or the ring Z₂ in Formula (1); L′ represents a single bond or a linking group; R represents a hydrogen atom or a substituent; n′ represents an integer of 3 or more; a plurality of Rs may be the same or different; and A represents a hydrogen atom or a substituent.

$$\{ {V}_{all} / {V}_{core} \} > 2 \qquad Expression ( a )$$

In Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions.

### <Phosphorescent Metal Complex According to First Embodiment>

An organic electroluminescence element according to the first embodiment of the present invention is characterized by containing a phosphorescent metal complex. In addition, the phosphorescent metal complex is a compound having a chemical structure represented by Formula (1).

### (Chemical Structure of Phosphorescent Metal Complex According to First Embodiment)

The phosphorescent metal complex according to the first embodiment has a chemical structure represented by Formula (1).

The phosphorescent metal complex according to the first embodiment is capable of providing a physical distance between the core portion which is the luminescence center and the quenching substance and to suppress energy transfer to the quenching substance by having a linear alkylene structure having 3 or more carbon atoms represented by Formula (2) in the ring Z₁ or the ring Z₂.

From the viewpoint of further suppressing the transfer of energy to the quenching substance, n′ in Formula (2) is preferably an integer of 4 or more, more preferably an integer of 6 or more.

In the phosphorescent metal complex according to the first embodiment, L′ in Formula (2) is preferably a non-conjugated linking group. By making L′ to be a non-conjugated linking group, the HOMO (highest occupied molecular orbital) portion and the LUMO (lowest unoccupied molecular orbital) portion are likely to be localized in the central metal, the ring Z₁ and the ring Z₂.

That is, delocalization of the HOMO portion and the LUMO portion to the substituent portion that forms the shell portion can be suppressed. As a result, it is possible to sufficiently provide a physical distance between the core portion which is the luminescent center and the quenching substance. Therefore, it is possible to further increase the effect of emitting light with high luminous efficiency and long lifetime. In addition, it is possible to increase the effect that fluorescence can be enhanced by fluorescence sensitization with high luminous efficiency and long lifetime.

Here, the non-conjugated linking group means a case in which the linking group cannot be expressed by repeating a single bond and a double bond, or a case when conjugation between aromatic rings constituting the linking group is sterically cut. Examples thereof are an alkylene group, a cycloalkylene group, an ether group, and a thioether group. Also, in the case where the planar structures of two aromatic rings have a chemical structure orthogonal due to steric hindrance induced by a substituent substituted on an aromatic ring, it is assumed that conjugation between aromatic rings is sterically broken.

In the phosphorescent metal complex according to the first embodiment, it is preferable that the ligand represented by the ring Z₁ and the ring Z₂ in Formula (1) have three or more substituents, from the viewpoint of luminous efficiency and light emission with a long lifetime. When n is 2 or more, each ligand preferably has three or more substituents.

With such a configuration, it is possible to form a shell portion three-dimensionally with respect to the core portion which is the luminescent center, and it is possible to provide a physical distance from the quenching substance in all directions.

Examples of a substituent in Formula (1) (other than the substituent represented by Formula (2)), a substituent R in Formula (2), and a substituent A include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group); a cycloalkyl group (for example, a cyclopentyl group, and a cyclohexyl group); an alkenyl group (for example, a vinyl group, an allyl group); an alkynyl group (for example, an ethynyl group and a propargyl group); an aromatic hydrocarbon group (also called an aromatic hydrocarbon ring, an aromatic carbon ring group or an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenantolyl group, an indenyl group, a pyrenyl group, and a biphenyl group); an aromatic heterocyclic group (for example, a pyridyl group, a pyrazyl group, a pyrimidinyl group, a triazyl a group, a furyl group, a pyrrolyl group, an imidazolyl group, a benzimidazolyl group, a pyrazolyl group, a pyrazinyl group, a triazolyl group (for example, 1,2,4-triazol-1-yl group, and 1,2,3-triazol-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, an azacarbazolyl group (indicating a ring structure in which one of the carbon atoms constituting the carbazole ring of the carbazolyl group is replaced with nitrogen atoms), a quinoxalinyl group, a pyridazinyl group, a triazinyl group, a quinazolinyl group, and a phthalazinyl group); a heterocyclic group (for example, a pyrrolidyl group, an imidazolidyl group, a morpholyl group, and an oxazolidyl group); an alkoxy group (for example, a methoxy group, an ethoxy group, a propyloxy group, a pentyloxy group, an hexyloxy group, an octyloxy group, and a dodecyloxy group); a cycloalkoxy group (for example, a cyclopentyloxy group and a cyclohexyloxy group); an aryloxy group (for example, a phenoxy group and a naphthyloxy group); an alkylthio group (for example, a methylthio group, an ethylthio group, a propylthio group, a pentylthio group, hexylthio group, an octylthio group, and a dodecylthio group); a cycloalkylthio group (for example, a cyclopentylthio group and a cyclohexylthio group); an arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group and a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); an acyl group (for example, an acetyl group, an ethyl carbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (for example, an acetyloxy group, an ethylcarbonyloxy group, a butylcarbonyloxy group, an octylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethyhexylcarbonylamino group, an octylcarbonylamino group, a dodecylcarbonylamino group, a phenylcarbonylamino group, and a naphthylcarbonylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethymexylaminocarbonyl group, a dodecylaminocarbonyl group, a phenylaminocarbonyl group, a naphthylaminocarbonyl group, and a 2-pyridylaminocarbonyl group); a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group); a sulfinyl group (for example, a methylsulfinyl group, an ethylsufinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group (for example, a methylsulfonyl group, an ethylsulfonyl group, a butylsulfinyl group, a cyclohexylsulfonyl group, a 2-ethylhexylsulfonyl group, and a dodecylsulfonyl group); an arylsulfonyl group or a heteroarylsulfonyl group (for example, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a dodecylamino group, an anilino group, a naphthylamino group, and a 2-pyridylamino group); a halogen atom (for example, a fluorine atom, a chlorine atom and a bromine atom); a fluorinated hydrocarbon group (for example, a fluoromethyl group, trifluoromethyl group, a pentafluoroethyl group and a pentafluorophenyl group); a cyano group; a nitro group; a hydroxyl group; a mercapto group; a silyl group (for example, a trimethylsilyl group, a triisopropylsilyl group, a triphenylsilyl group, and a phenyldiethylsilyl group) and a phosphono group.

Moreover, these substituents may be further substituted by the above-mentioned substituent. Further, a plurality of these substituents may be bonded with each other to form a ring.

The linking group L′ in Formula (2) is not particularly limited. Examples thereof are: a substituted or unsubstituted alkylene group having 1 to 12 carbon atoms; a substituted or unsubstituted arylene group having 6 to 30 ring forming carbon atoms; a substituted or unsubstituted heteroarylene group having 5 to 30 ring forming carbon atoms; and a divalent linking group composed of combination of these groups.

The alkylene group having 1 to 12 carbon atoms may have a straight chain structure or a branched structure, or may have a cyclic structure such as a cycloalkylene group. The arylene group having 6 to 30 ring forming carbon atoms may be a non-condensed or condensed ring.

Examples of the arylene group having 6 to 30 ring-forming carbon atoms are: an o-phenylene group, an m-phenylene group, a p-phenylene group, a naphthalenediyl group, a phenanthrenediyl group, a biphenylene group, a terphenylene group, a quaterphenylene group, a triphenylenediyl group, and a fluorenediyl group.

Examples of the hetero arylene group having 5 to 30 ring forming carbon atoms are derived from: a pyridine ring, a pyrazine ring, a pyrimidine ring, a piperidine ring, a triazine ring, a pyrrole ring, an imidazole ring, a pyrazole ring, a triazole ring, an indole ring, an isoindole ring, a benzimidazole ring, a furan ring, a benzofuran ring, an isobenzofuran ring, a dibenzofuran ring, a thiophene ring, a benzothiophene ring, a dibenzothiophene ring, a silole ring, a benzosilole ring, a dibenzosilole ring, a quinoline ring, an isoquinoline ring, a quinoxaline ring, a phenanthridine ring, a phenanthroline ring, an acridine ring, a phenazine ring, a phenoxazine ring, a phenothiazine ring, a phenoxathin ring, a pyridine ring, a pyrazine ring, a pyrimidine ring, a pyridazine ring, a triazine ring, an acridine ring, an oxazole ring, an oxadiazole ring, a benzoxazole ring, a thiazole ring, a thiadiazole ring, a benzothiazole ring, a benzodifuran ring, a thienothiophene ring, a benzodithiophene ring, a cyclazine ring, a quindoline ring, a tepenidine ring, a quinindoline ring, a triphenodithiadine ring, a triphenodioxazine ring, a phenanthradine ring, an anthrazine ring, a perimidine ring, a naphthofuran ring, a naphthothiophene ring, a benzodithiophene ring, a naphthodifuran ring, a naphthodithiophene ring, an anthrafumn ring, an anthradifumn ring, an anthrathiophene ring, an anthradithiophene ring, a thianthrene ring, a phenoxathiin ring, a naphthothiophene ring, a carbazole ring, a carboline ring, a diazacarbazole ring (it indicates a ring structure in which arbitral two or more carbon atoms constituting the carbazole ring is replaced with nitrogen atoms), an azadibenzofuran ring (it indicates a ring structure in which arbitral one or more carbon atoms constituting the dibenzofuran ring is replaced with nitrogen atoms), azadibenzothiophene ring (it indicates a ring structure in which arbitral one or more carbon atoms constituting the dibenzothiohene ring is replaced with nitrogen atoms), an indolocarbazole ring, and an indenoindole ring. A divalent group is derived from the above-described ring by removing two hydrogen atoms from the ring.

More preferable heteroarylene groups are a divalent group derived from the following by removing two hydrogen atoms in the ring: a pyridine ring, a pyrazine ring, a pyrimidine ring, a piperidine ring, a triazine ring, a dibenzofuran ring, a dibenzothiophene ring, a carbazole ring, a carboline ring, a diazacarbazole ring.

These linking groups may be substituted by the substituents described above.

<<Outline of Organic Electroluminescence Element According to Second Embodiment of the Present Invention>>

An organic electroluminescence element according to second embodiment of the present invention is an organic electroluminescence element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by any one of the following Formulas (3) to (5), and the phosphorescent metal complex satisfies the following Expression (b).

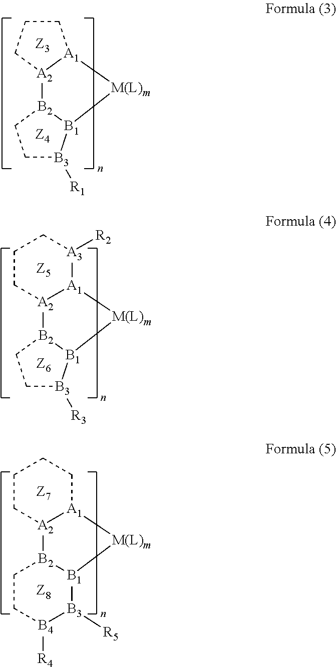

In Formulas (3) to (5): M represents Ir or Pt; A₁ to A₃, and B₁ to B₄ each independently represent a carbon atom or a nitrogen atom; among a bond between A₁ and M, and a bond between B₁ and M, one is a coordinate bond and the other is a covalent bond; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, ligands represented by a ring Z₃ and a ring Z₄, ligands represented by a ring Z₅ and a ring Z₆, and ligands represented by a ring Z₇ and a ring Z₈, or L may be the same or different; the ligands represented by the ring Z₃ to Z₈ may be linked to L.

In Formula (3), the ring Z₃ represents a 5-membered aromatic heterocyclic ring formed with A₁ and A₂, or an aromatic condensed ring containing the aforesaid ring; the ring Z₄ represents a 5-membered aromatic heterocyclic ring formed with B₁ to B₃, or an aromatic condensed ring containing the aforesaid ring; R₁ represents a substituent having 2 or more carbon atoms; the ring Z₃ and the ring Z₄ may have a substituent besides R₁ and may form a condensed ring structure by bonding of the substituents of the ring Z₃ and the ring Z4; the ligands represented by the ring Z₃ and the ring Z₄ may be linked to each other.

In Formula (4), the ring Z₅ represents a 6-membered aromatic hydrocarbon ring, a 6-membered aromatic heterocyclic ring formed with A₁ to A₃, or an aromatic condensed ring containing at least one of the aforesaid rings; the ring Z₆ represents a 5-membered aromatic heterocyclic ring formed with B₁ to B₃, or an aromatic condensed ring containing at least one of the aforesaid rings; R₂ and R₃ each represent a hydrogen atom or a substituent, at least one of R₂ and R₃ represents a substituent having 2 or more carbon atoms; the ring Z₅ and the ring Z₆ may have a substituent besides R₂ and R₃ and may form a condensed ring structure by bonding of the substituents of the ring Z₅ and the ring Z₆, and the ligands represented by the ring Z₅ and the ring Z₆ may be linked to each other.

In Formula (5), the ring Z₇ represents a 6-membered aromatic hydrocarbon ring, a 6-membered aromatic heterocyclic ring formed with A₁ and A₂, or an aromatic condensed ring containing at least one of the aforesaid rings; the ring Z₈ represents a 6-membered aromatic hydrocarbon ring or a 6-membered aromatic heterocyclic ring formed with B₁ to B₄, or an aromatic condensed ring containing at least one of the aforesaid rings; R₄ and R₅ each represent a hydrogen atom or a substituent, at least one of R₄ and R₅ represents a substituent having 2 or more carbon atoms; the ring Z₇ and the ring Z₈ may have a substituent besides R₄ and R₅ and may form a condensed ring structure by bonding of the substituents of the ring Z₇ and the ring Z₈, and the ligands represented by the ring Z₇ and the ring Z₈ may be linked to each other.

$$\{ {V}_{all} / {V}_{core} \} > 2 \qquad Expression ( b )$$

In Expression (b), Vₐₗₗ represents a molecular volume of a compound having a chemical structure represented by any one of Formulas (3) to (5) including the substituents bonded to the ring Z₃ to the ring Z₈; when M represents Ir, n=3 and m=0 are fixed, and when M represents Pt, n=2 and m=0 are fixed; V_{core} represents a molecular volume of a compound having a chemical structure in which the substituent bonded to the ring Z₃ to the ring Z₈ is replaced with a hydrogen atom from the chemical structure indicating the molecular volume of Vₐn; and when there are a plurality of ligands represented by the ring Z₃ and the ring Z₄, ligands represented by the ring Z₅ and the ring Z₆, ligands represented by the ring Z₇ and the ring Z₈, Vₐₗₗ and V_{core} satisfy Expression (b) in all cases expressed by the aforesaid conditions.

### <Phosphorescent Metal Complex According to Second Embodiment>

An organic electroluminescence element according to the first embodiment of the present invention is characterized by containing a phosphorescent metal complex. In addition, the phosphorescent metal complex is a compound having a chemical structure represented by any one of the above-described Formulas (3) to (5).

### (Chemical Structure of Phosphorescent Metal Complex According to Second Embodiment)

The phosphorescent metal complex according to the second embodiment has a chemical structure represented by any one of the above-described Formulas (3) to (5).

The phosphorescent metal complex according to the second embodiment has a substituent having 2 or more carbon atoms in R₁ to R₅ in Formulas (3) to (5), whereby it is possible to provide a physical distance between the core portion which is the luminescence center and the quenching substance and to suppress energy transfer to the quenching substance. Therefore, it is possible to emit light with high luminous efficiency and long lifetime. In addition, fluorescence can be emitted by fluorescence sensitization with high luminous efficiency and long lifetime.

In order to further suppress the transfer of energy to the quenching substance, the substituent is preferably a substituent having 3 or more carbon atoms, and more preferably a substituent having 4 or more carbon atoms.

It is preferable that the phosphorescent metal complex according to the second embodiment has three or more substituents in the ligands represented by the ring Z₃ and the ring Z₄, the ligands represented by the ring Z₅ and the ring Z₆, or the ligands represented by the ring Z₇ and the ring Z₈. When n is 2 or more, each ligand preferably has three or more substituents.

With making such a chemical structure, it is possible to form a shell portion three-dimensionally with respect to the core portion which is the luminescent center, and it is possible to provide a physical distance from the quenching substance in all directions.

Examples of the substituent in Formulas (3) to (5) are the same as those exemplified as the substituent of Formula (1).

### <Molecular Volume of Phosphorescent Metal Complex (Core-Shell Type Dopant) According to the Present Invention>

The phosphorescent metal complex according to the present invention (the phosphorescent metal complex according to the first embodiment and the second embodiment) has the above specific chemical structure and satisfy the following Expression (a) or Expression (b).

In the case of the phosphorescent metal complex having the chemical structure represented by Formula (1) which is the first embodiment, the following expression is satisfied.

$$\{ {V}_{all} / {V}_{core} \} > 2 \qquad Expression ( a )$$

In Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions.

In the case of the phosphorescent metal complex having the chemical structure represented by any one of Formulas (3) to (5) which is the second embodiment, the following expression is satisfied.

$$\{ {V}_{all} / {V}_{core} \} > 2 \qquad Expression ( b )$$

In Expression (b), Vₐₗₗ represents a molecular volume of a compound having a chemical structure represented by any one of Formulas (3) to (5) including the substituents bonded to the ring Z₃ to the ring Z₈; when M represents Ir, n=3 and m=0 are fixed, and when M represents Pt, n=2 and m=0 are fixed; V_{core} represents a molecular volume of a compound having a chemical structure in which the substituent bonded to the ring Z₃ to the ring Z₈ is replaced with a hydrogen atom from the chemical structure indicating the molecular volume of Vₐₗₗ; and when there are a plurality of ligands represented by the ring Z₃ and the ring Z₄, ligands represented by the ring Z₅ and the ring Z₆, ligands represented by the ring Z₇ and the ring Z₈, Vₐₗₗ and V_{core} satisfy Expression (b) in all cases expressed by the aforesaid conditions.

Vₐₗₗ in Expression (a) or Expression (b) is made to be n=3 and m=0 when M is Ir in each of Formulas (1) and (3) to (5). In the case where M is Pt, Vₐₗₗ is made to be n=2 and m=0. Vₐₗₗ represents a molecular volume of a structure including the substituent bonded to the rings Z₁ to Z₈.

On the other hand, V_{core} represents a molecular volume of a chemical structure in which hydrogen atoms are replaced with the substituents bonded to the rings Z₁ to Z₈ from the chemical structure showing the molecular volume of Vₐₗₗ. Also, when the Z₁ to Z₈ are aromatic condensed rings, V_{core} represents a molecular volume of a structure in which the substituent bonded to the aromatic condensed ring is replaced with a hydrogen atom.

When there are a plurality of ligands represented by the ring Z₁ and the ring Z₂, ligands represented by the ring Z₃ and the ring Z₄, ligands represented by the ring Z₅ and the ring Z₆, ligands represented by the ring Z₇ and the ring Z₈, Vₐₗₗ and V_{core} are required to satisfy Expression (a) or Expression (a) in all cases expressed by the aforesaid conditions. Specifically, it is as follows.

As indicated in the following Example (1), in the case of a luminescent metal complex in which a ligand represented by the ring Z₅ and Z₆ in Formula (4), and a ligand represented by the ring Z₇ and Z₈ in Formula (5) exist, two chemical structures of the following example (2) and example (3) are conceivable as a chemical structure fixing that n=3 and m=0. When the molecular volume of the chemical structure of the following example (2) is Vₐₗₗ and the molecular volume of the chemical structure of the following example (3) is Vₐₗₗ₂, V_{core} of the chemical structure of the following example (2) is the molecular volume of the compound having the chemical structure represented by the following example (4), V_{core} of the chemical structure of the following example (3) is the molecular volume of the compound having the chemical structure represented by the following example (5) (defined as Vₐₗₗ₂). Then, (Vₐₗₗ/V_{core}) and (Vₐₗₗ₂/V_{core2}) must satisfy the above expression (b).

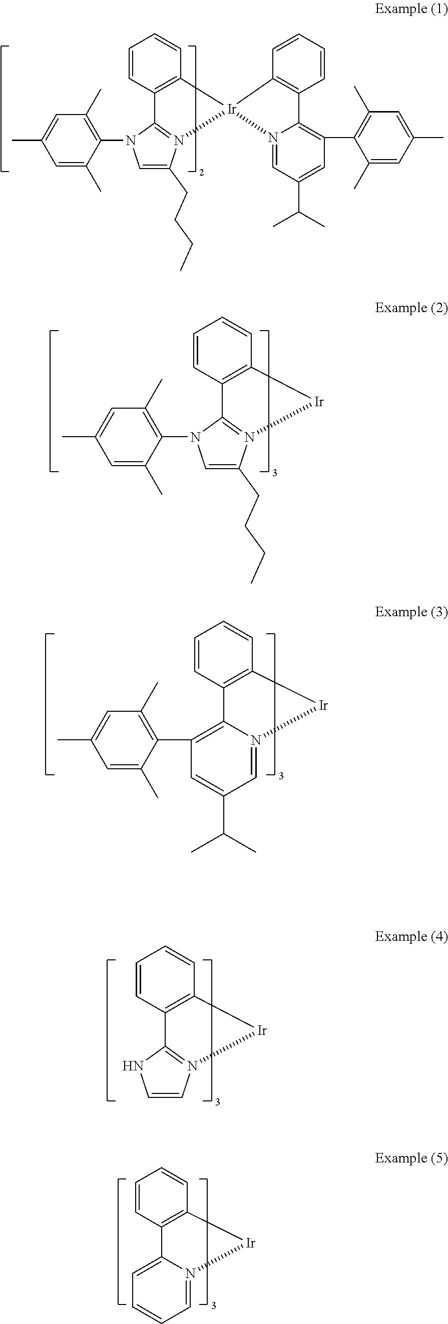

Note that Vₐₗₗ and V_{core} are the van der Waals molecular volume in detail, and it can be calculated by molecular drawing software, for example, Winmostar (made by X-Ability Co., Ltd.). In the phosphorescent metal complex according to the present invention, the volume ratio (Vₐₗₗ/V_{core}) of Vₐₗₗ to V_{core} is larger than 2. It is preferable that the volume ratio (Vₐₗₗ/V_{core}) is 2.5 or more from the viewpoint of high luminescence efficiency and long lifetime and capable of emitting light. It is also preferable from the viewpoint that fluorescence can be enhanced by fluorescence sensitization with high luminous efficiency and long lifetime.

Energy transfer from the core-shell type dopant to the quenching substance can be suitably suppressed by molecularly designing the phosphorescent metal complex so as to increase the volume ratio.

The upper limit of the volume ratio is not particularly limited, but it is preferably 5 or less, more preferably 3 or less, from the viewpoint of ease of production.

For example, Ir(ppy)₃, which is well-known as a green phosphorescent complex, does not have a shell portion as indicated in the following example (6), so that (Vₐₗₗ/V_{core}) is 2 or less. Specifically, Vₐₗₗ=V_{core}=0.45004 nm³, and (Vₐₗₗ/V_{core})=1.

On the other hand, as indicated in the following example (7), a metal complex having a shell portion by introducing a substituent satisfying Formula (2) to Ir(ppy)₃ has a value of (Vₐₗₗ/V_{core}) larger than 2. Specifically, Vₐₗₗ=0.96005 nm³, V_{core}=0.45004 nm³, and (Vₐₗₗ/V_{core})=2.13.

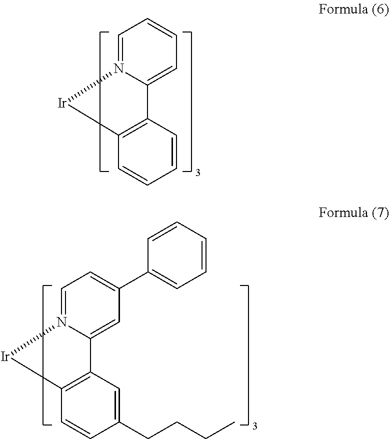

The phosphorescent metal complex according to the present invention satisfies Expression (a) or Expression (b) as described above and it is a “core-shell type dopant” composed of a core portion and a shell portion.

Specific examples of the luminescent metal complex according to the present invention are listed below, but the present invention is not limited thereto.

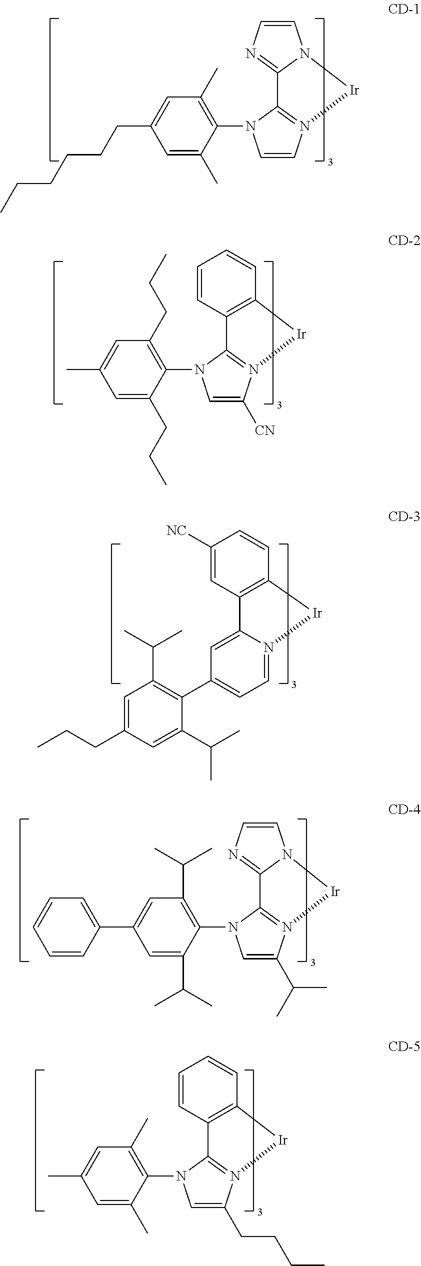

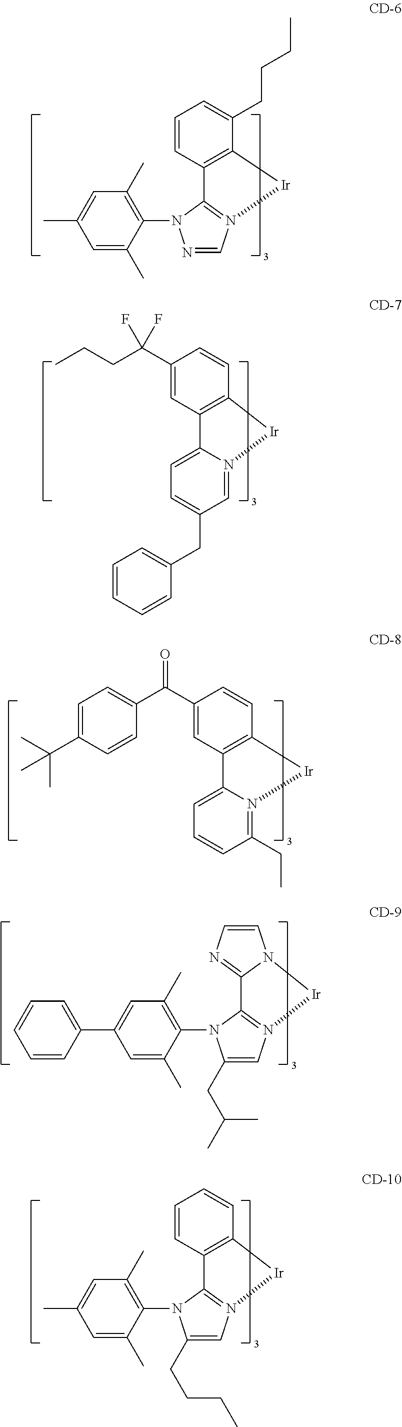

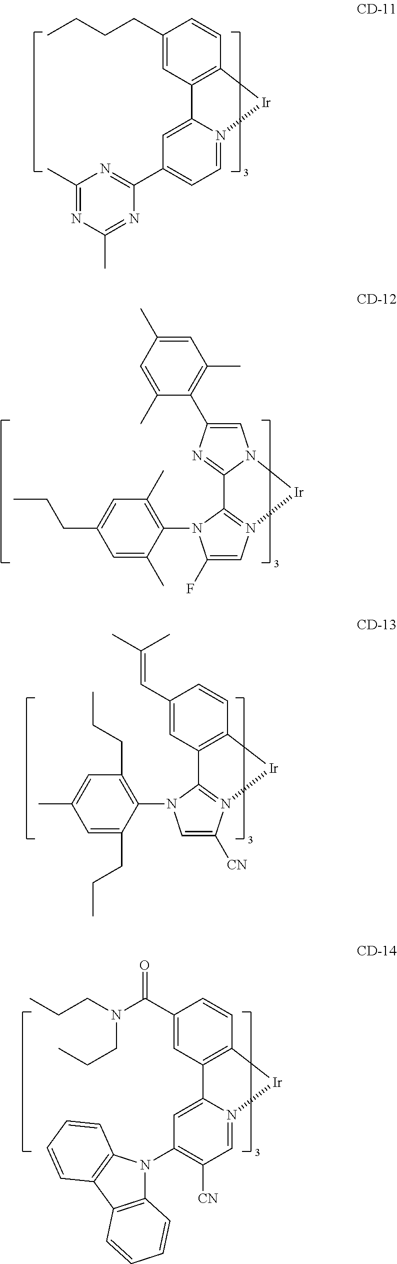

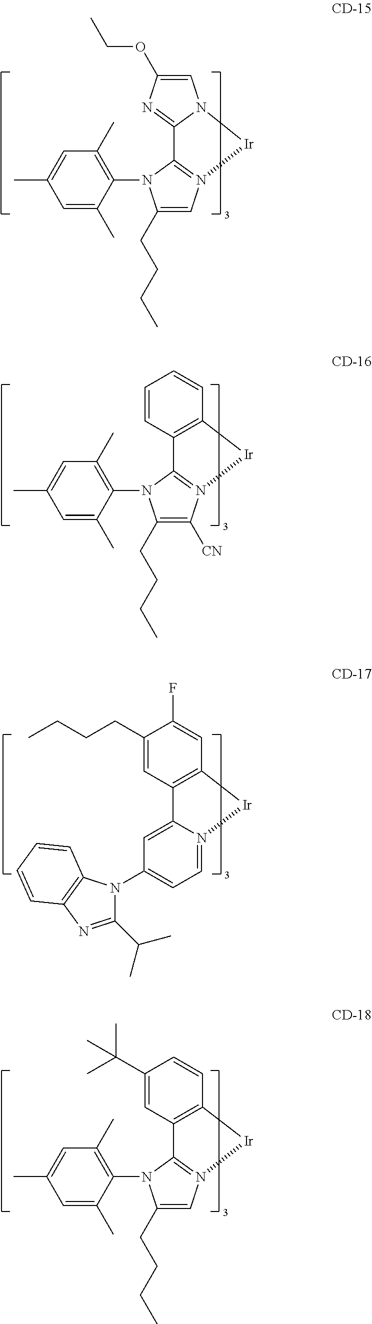

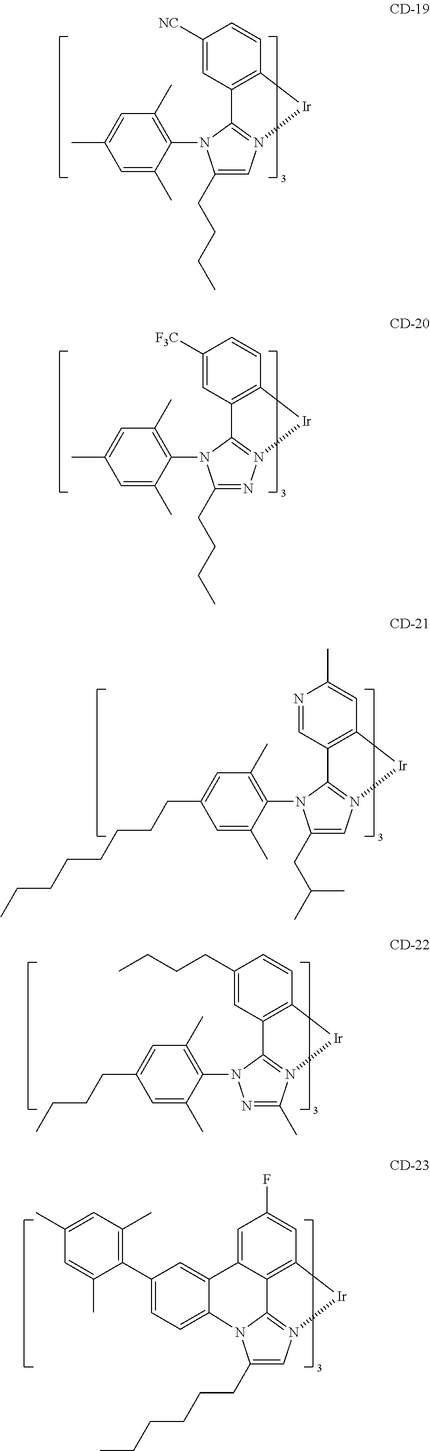

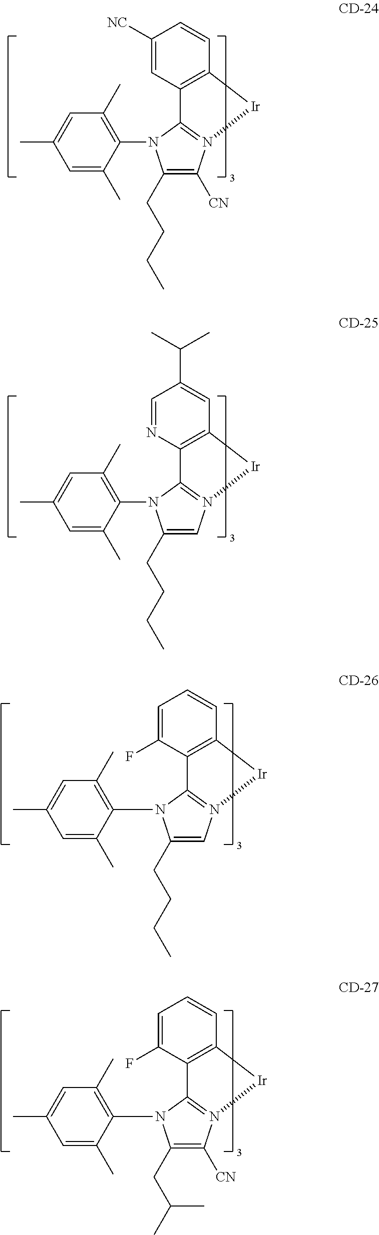

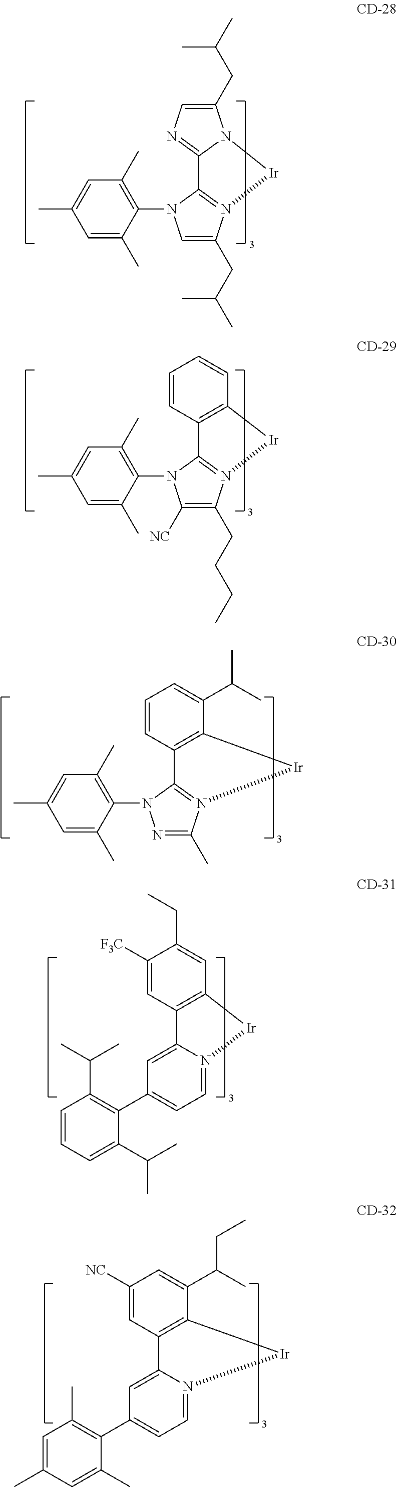

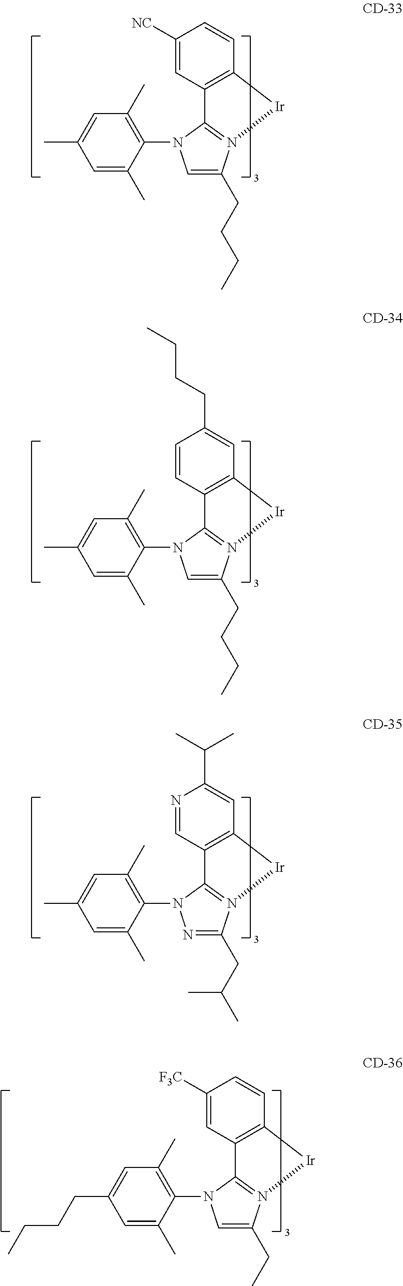

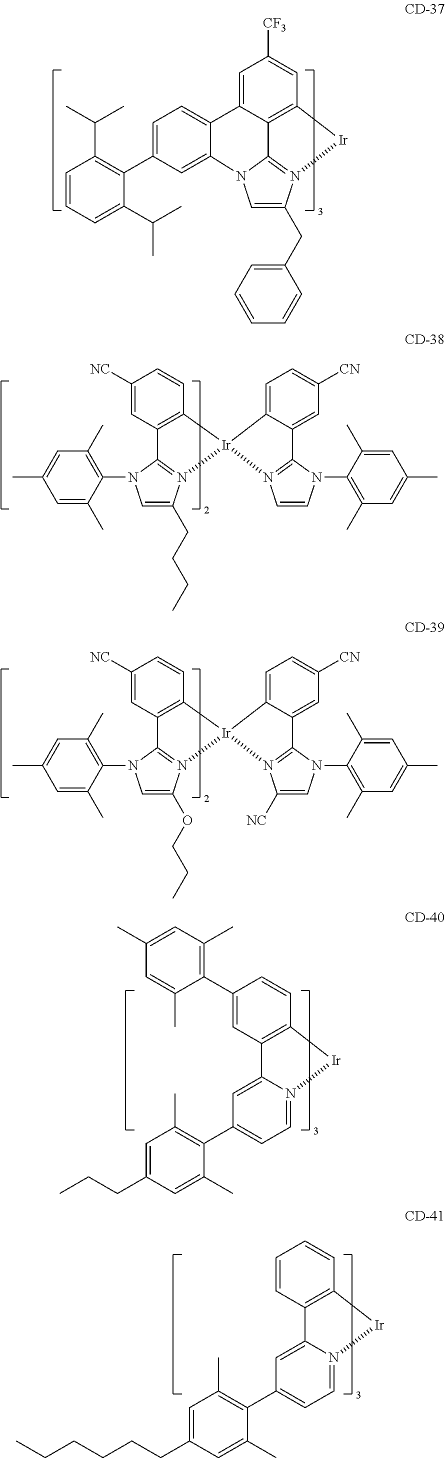

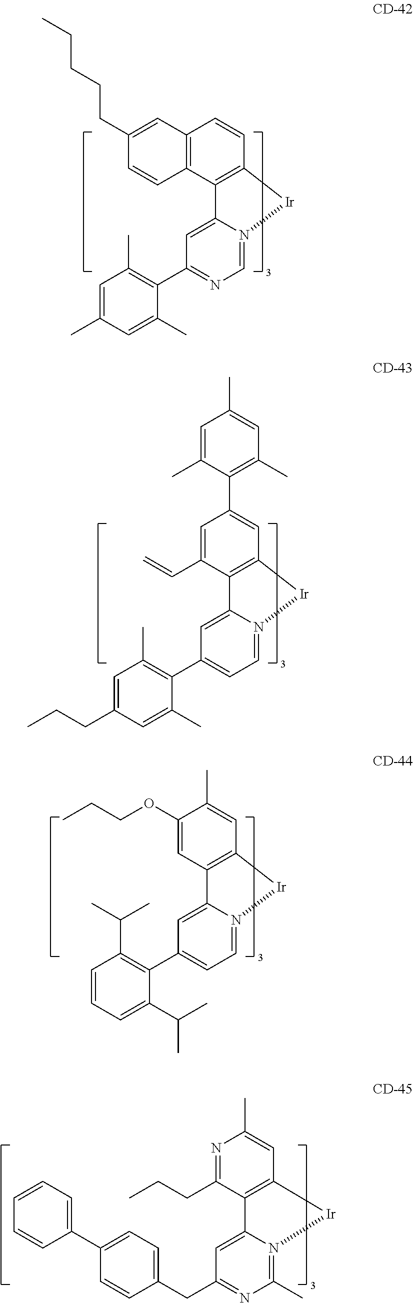

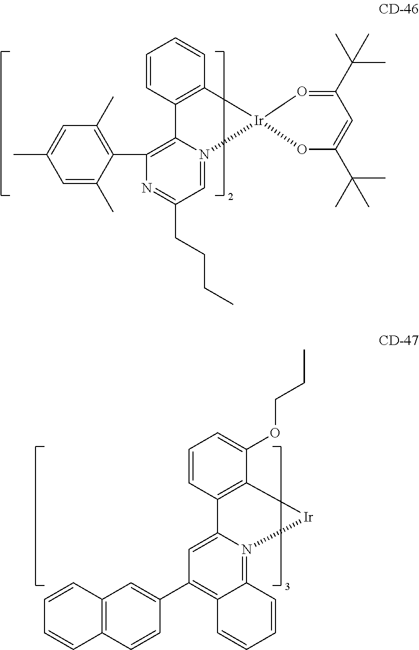

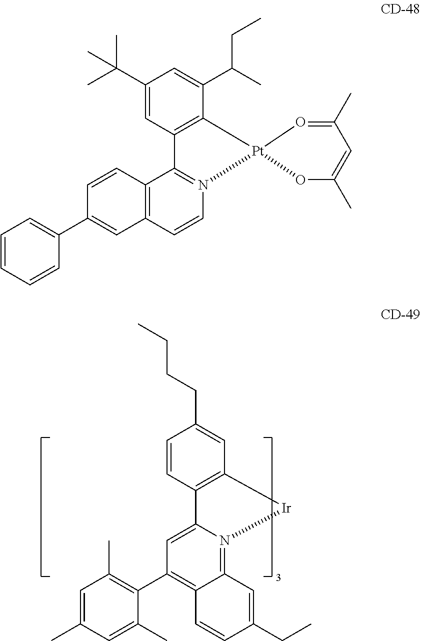

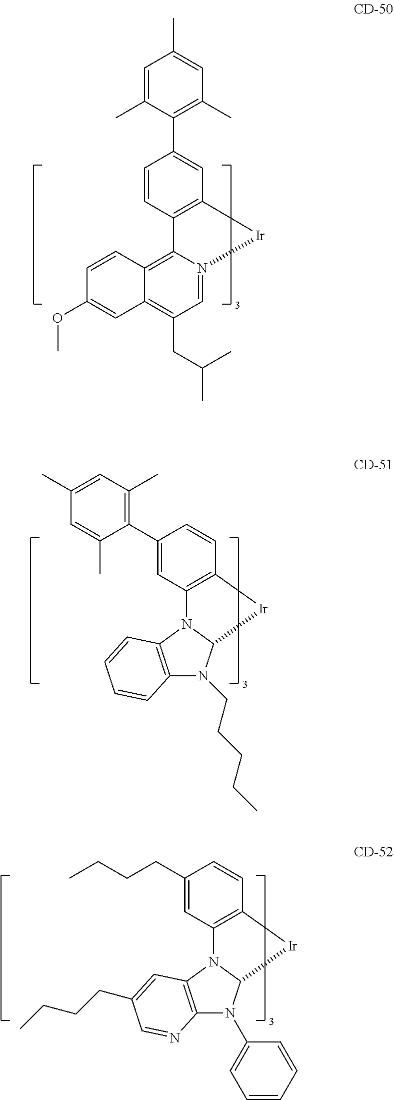

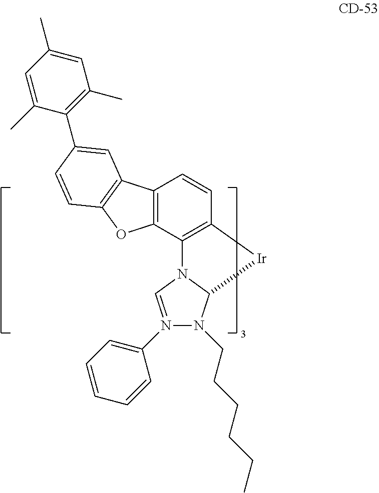

There is no particular limitation on the molecular weight of the phosphorescent metal complex according to the present invention.

The phosphorescent metal complex according to the present invention is preferably contained in the organic functional layer within the range of 1 to 50 mass %.

### <Fluorescent Compound>

The fluorescent compound used in the present invention is a compound capable of emitting light from a singlet excited state and is not particularly limited as long as light emission from a singlet excited state is observed.

Examples of the fluorescent compound usable in the present invention are: an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, and a rare earth complex compound.

In recent years, light emitting dopants utilizing delayed fluorescence were developed. These dopants may be used.

Specific examples of a light emitting dopant utilizing delayed fluorescence are compounds described in: WO 2011/156793, JP-A 2011-213643, and JP-A2010-93181. However, the present invention is not limited to them.

The molecular weight of the fluorescent compound according to the present invention is not particularly limited.

Examples of the fluorescent compound according to the present invention are listed below, but the present invention is not limited thereto.

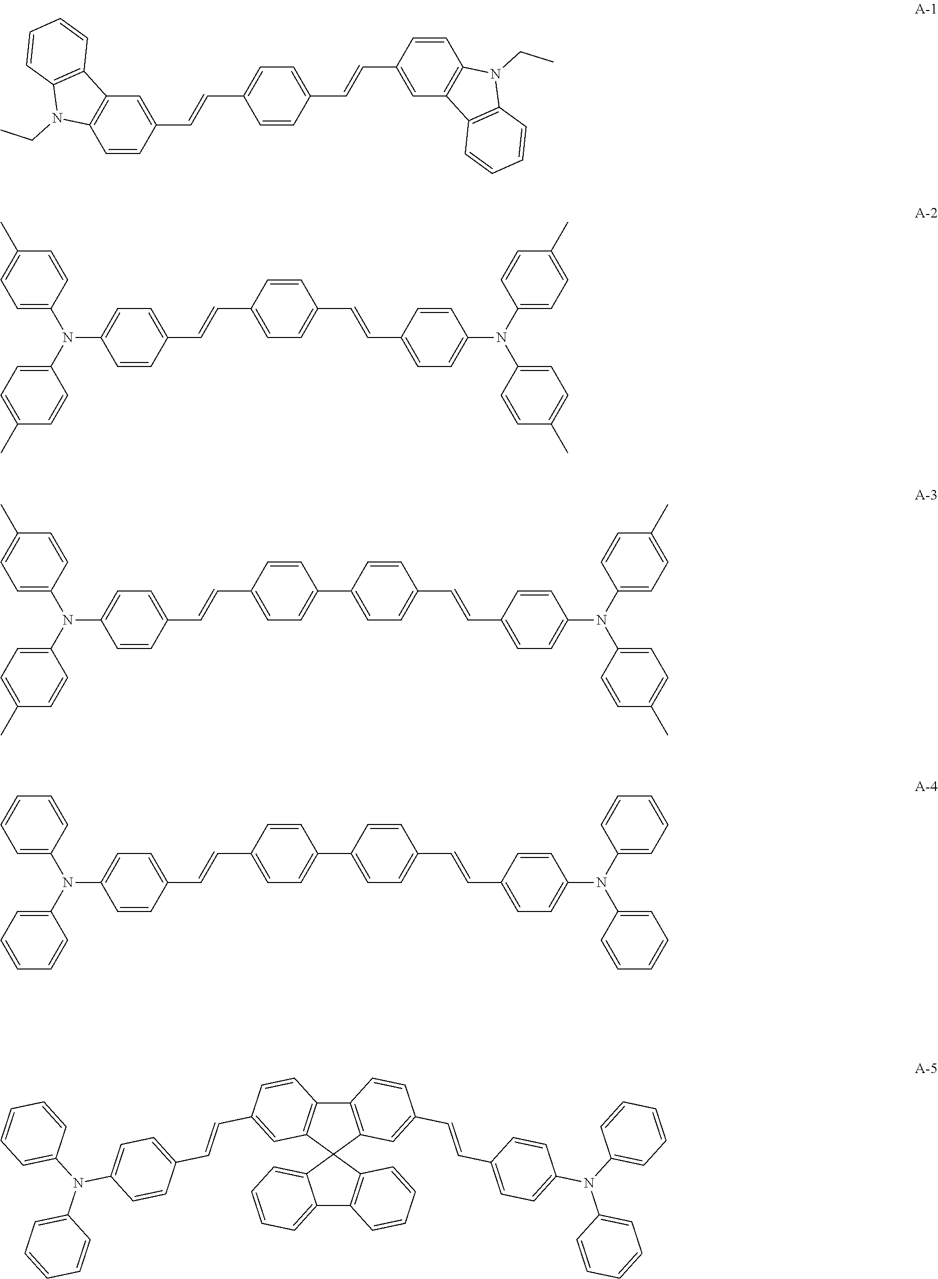 [SMILES: CCn1c2ccccc2c2cc(/C=C/c3ccc(/C=C/c4ccc5c(c4)c4ccccc4n5CC)cc3)ccc21 ; Cc1ccc(N(c2ccc(C)cc2)c2ccc(/C=C/c3ccc(/C=C/c4ccc(N(c5ccc(C)cc5)c5ccc(C)cc5)cc4)cc3)cc2)cc1 ; Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1 ; C(=C\c1ccc(N(c2ccccc2)c2ccccc2)cc1)/c1ccc(-c2ccc(/C=C/c3ccc(N(c4ccccc4)c4ccccc4)cc3)cc2)cc1 ; C(=C\c1ccc2c(c1)C1(c3ccccc3-c3ccccc31)c1cc(/C=C/c3ccc(N(c4ccccc4)c4ccccc4)cc3)ccc1-2)/c1ccc(N(c2ccccc2)c2ccccc2)cc1]

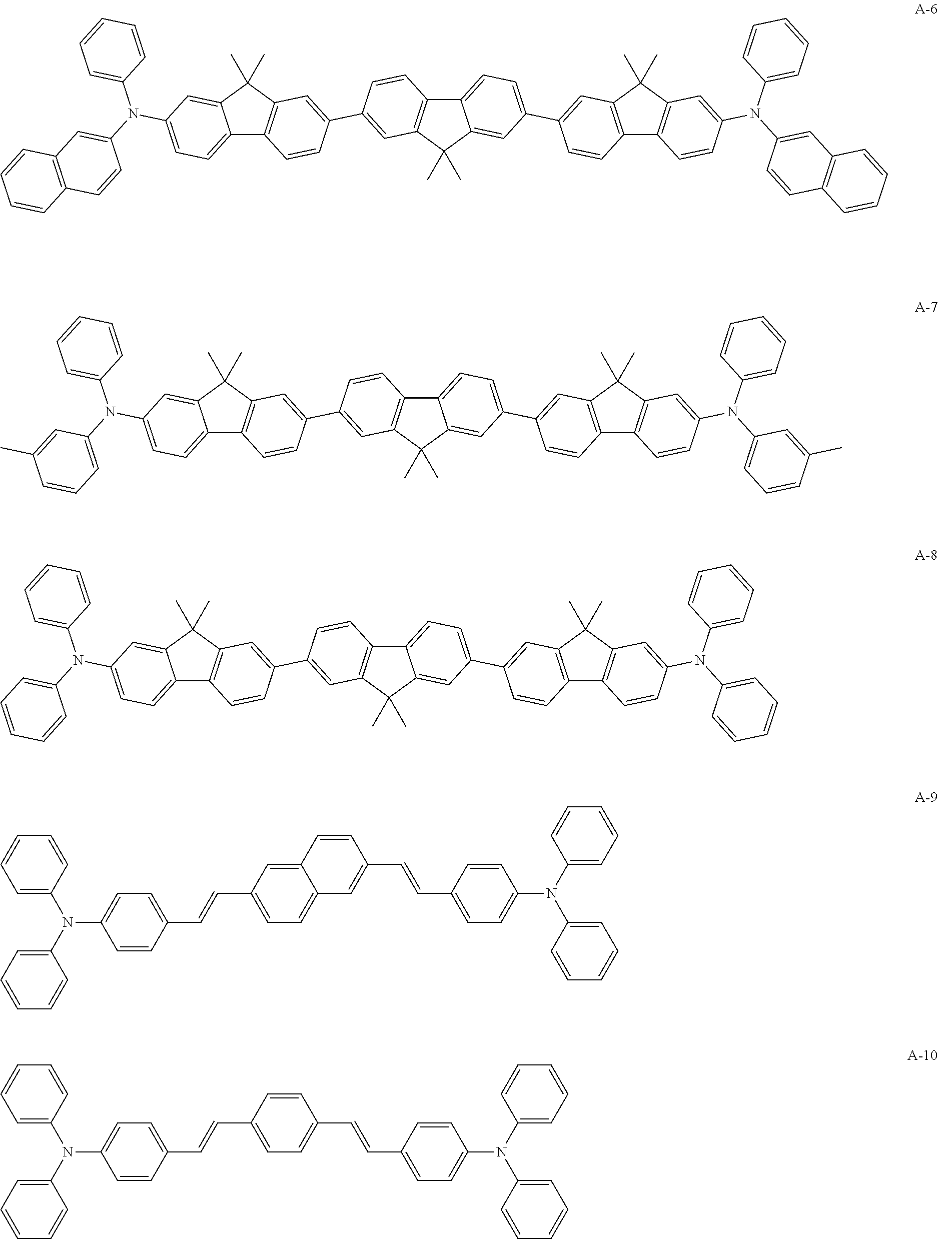

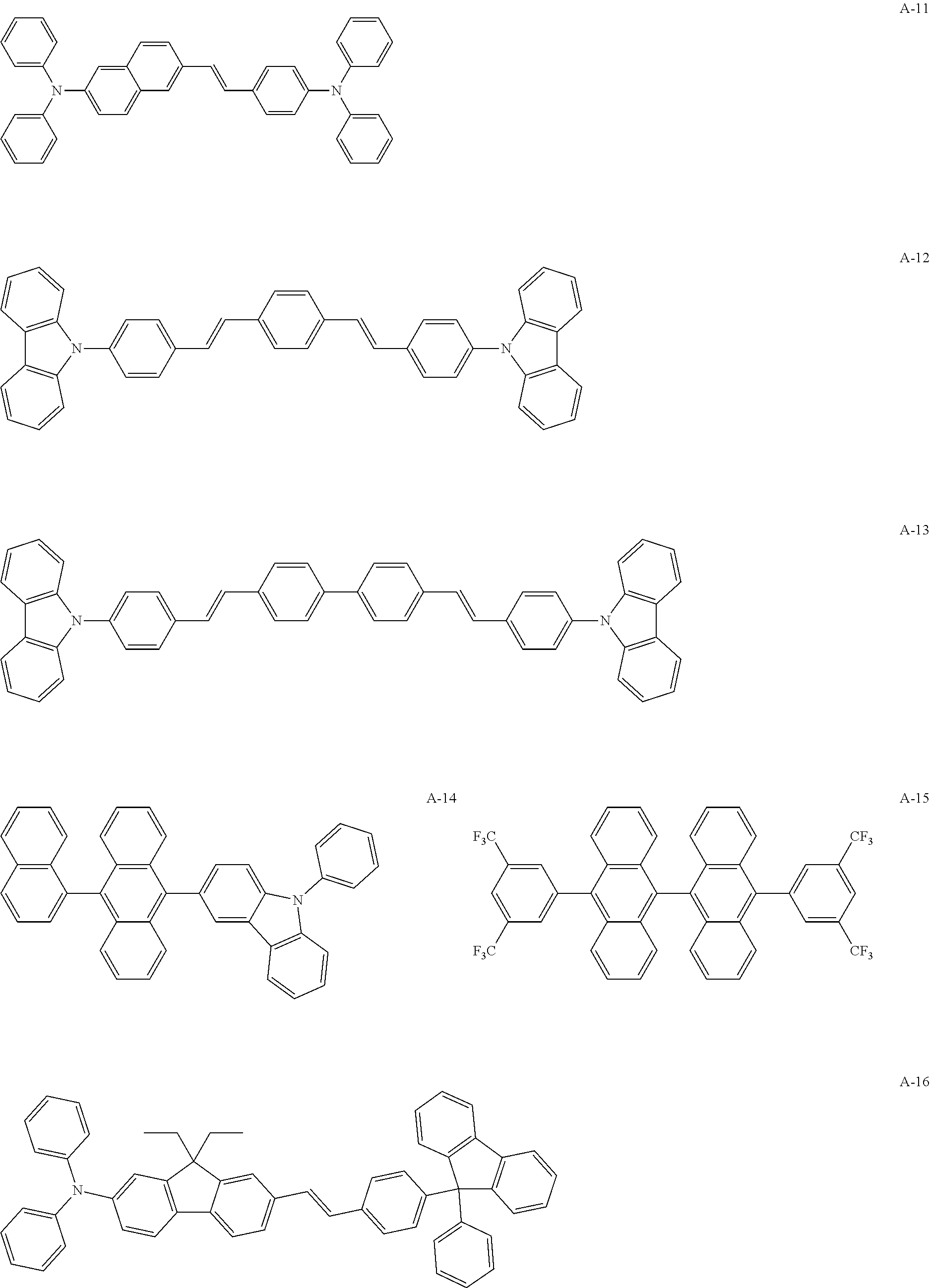

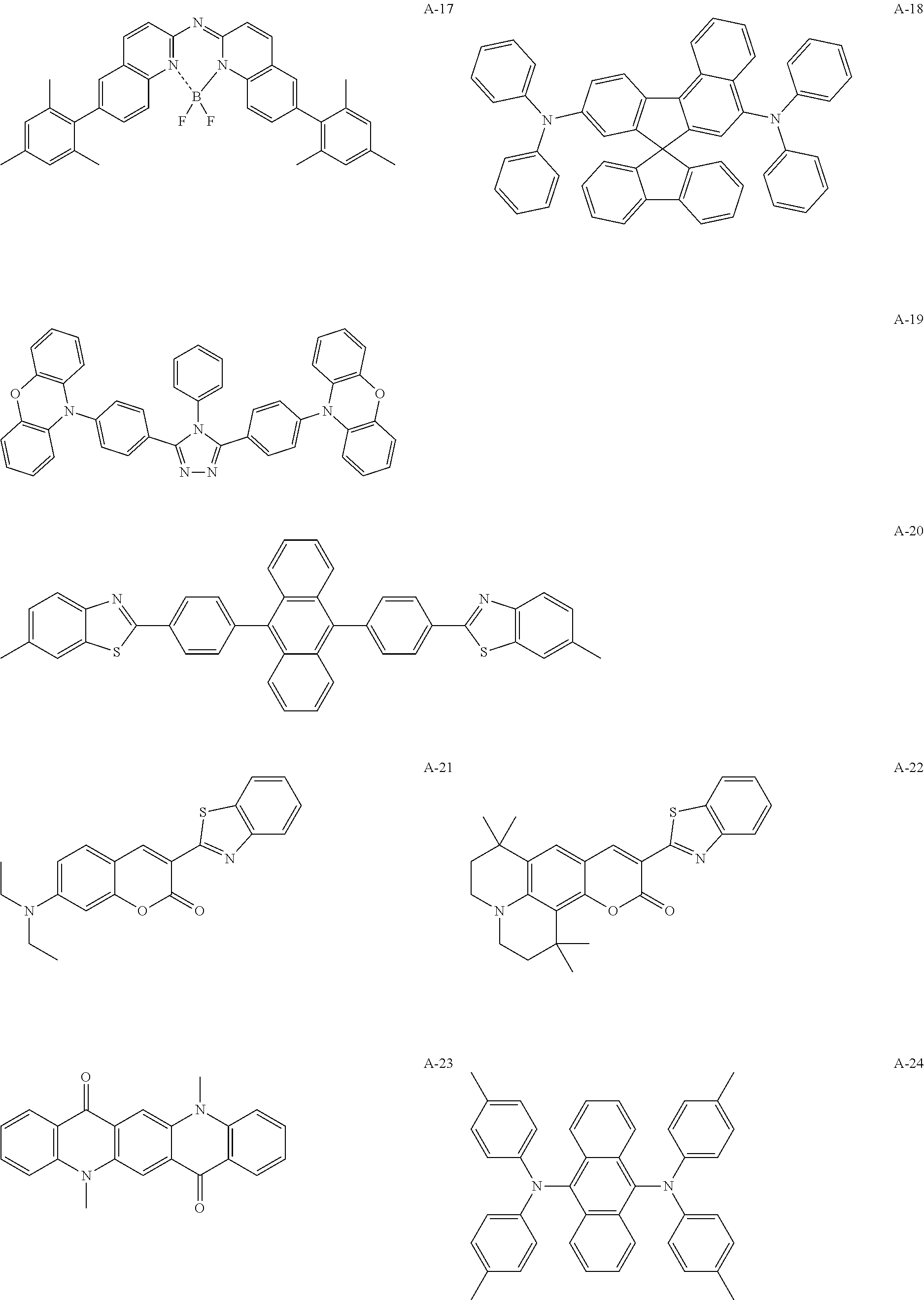

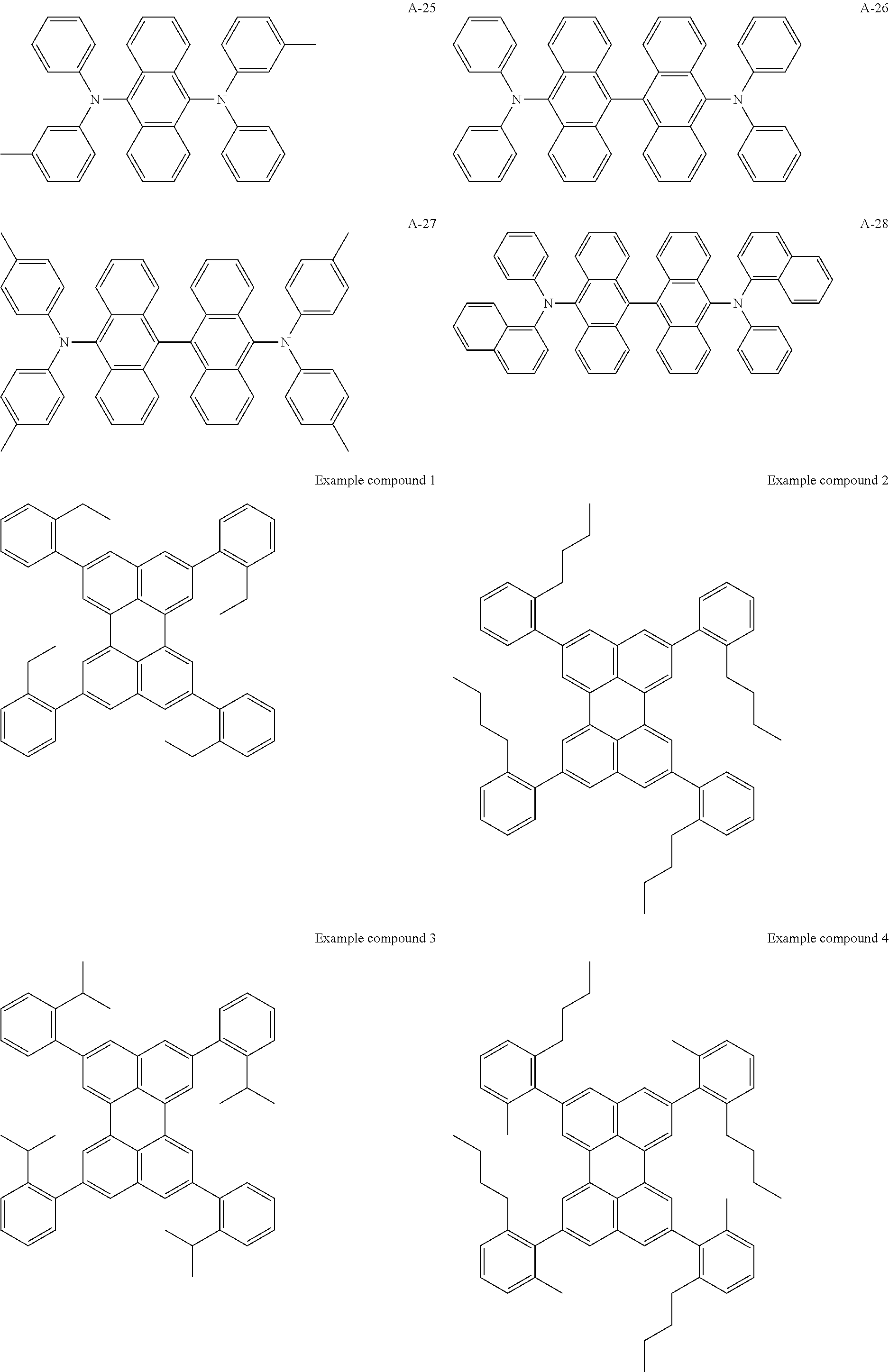

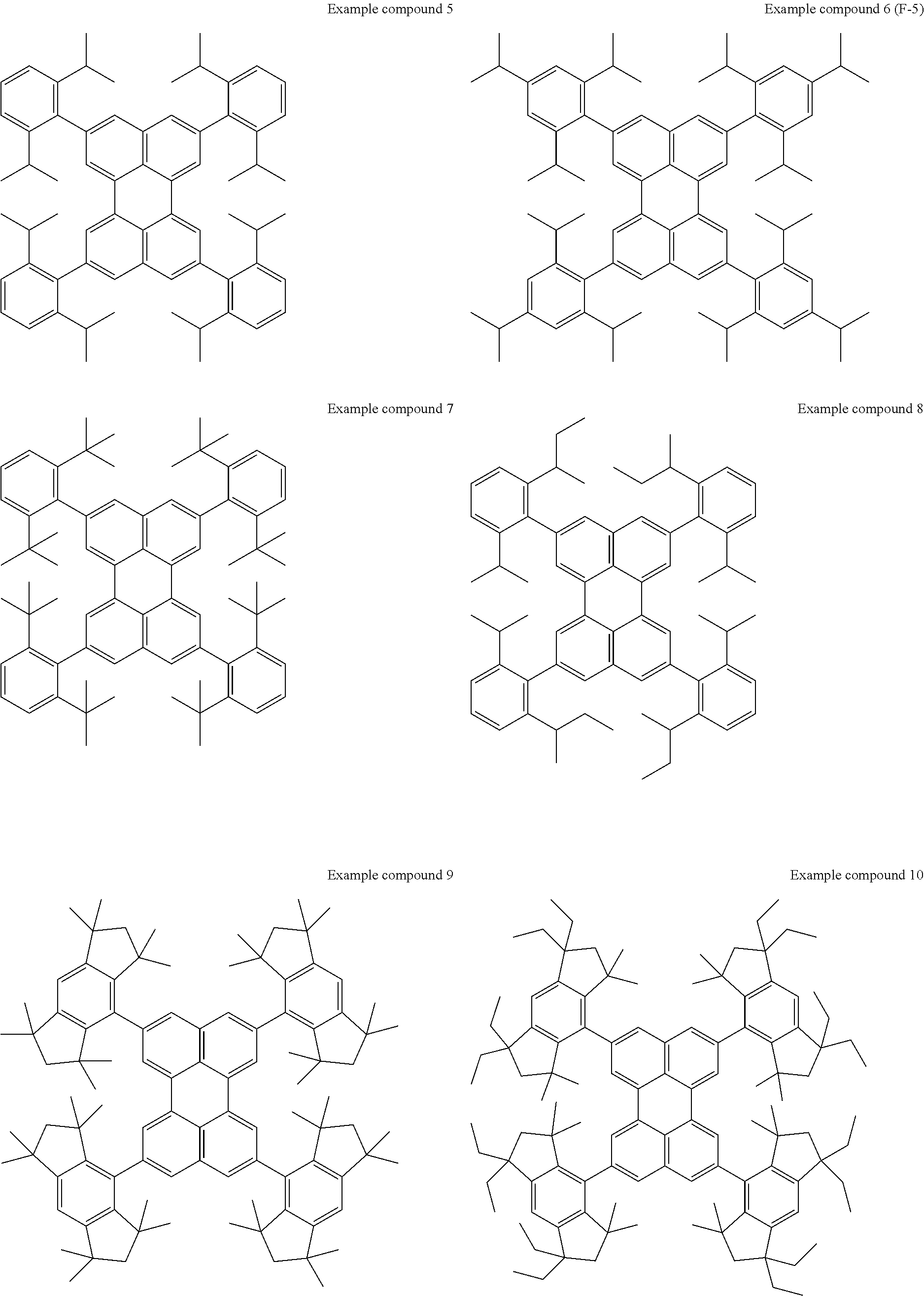

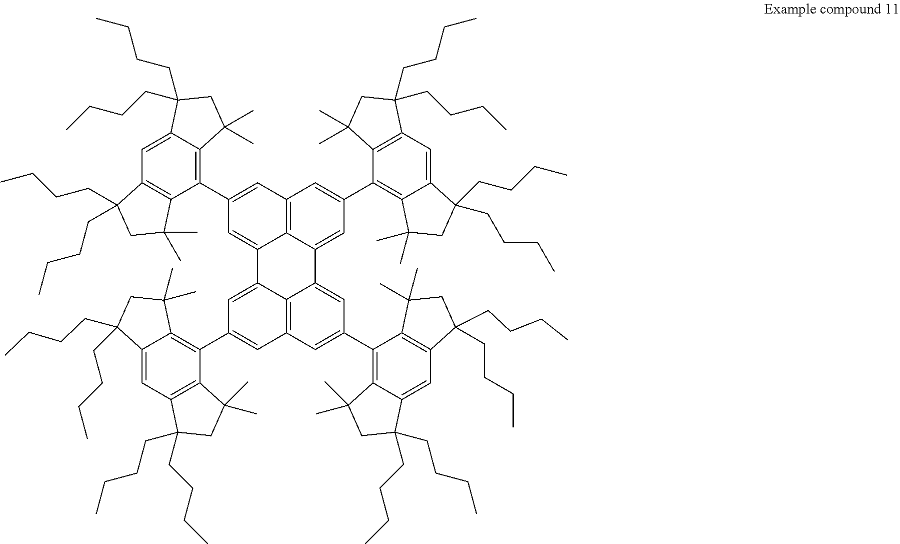 [SMILES: CCCCC1(CCCC)CC(C)(C)c2c1cc1c(c2-c2cc3cc(-c4c5c(cc6c4C(C)(C)CC6(CCCC)CCCC)C(CCCC)(CCCC)CC5(C)C)cc4c5cc(-c6c7c(cc8c6C(C)(C)CC8(CCCC)CCCC)C(CCCC)(CCCC)CC7(C)C)cc6cc(-c7c8c(cc9c7C(C)(C)CC9(CCCC)CCCC)C(CCCC)(CCCC)CC8(C)C)cc(c(c2)c34)c65)C(C)(C)CC1(CCCC)CCCC]

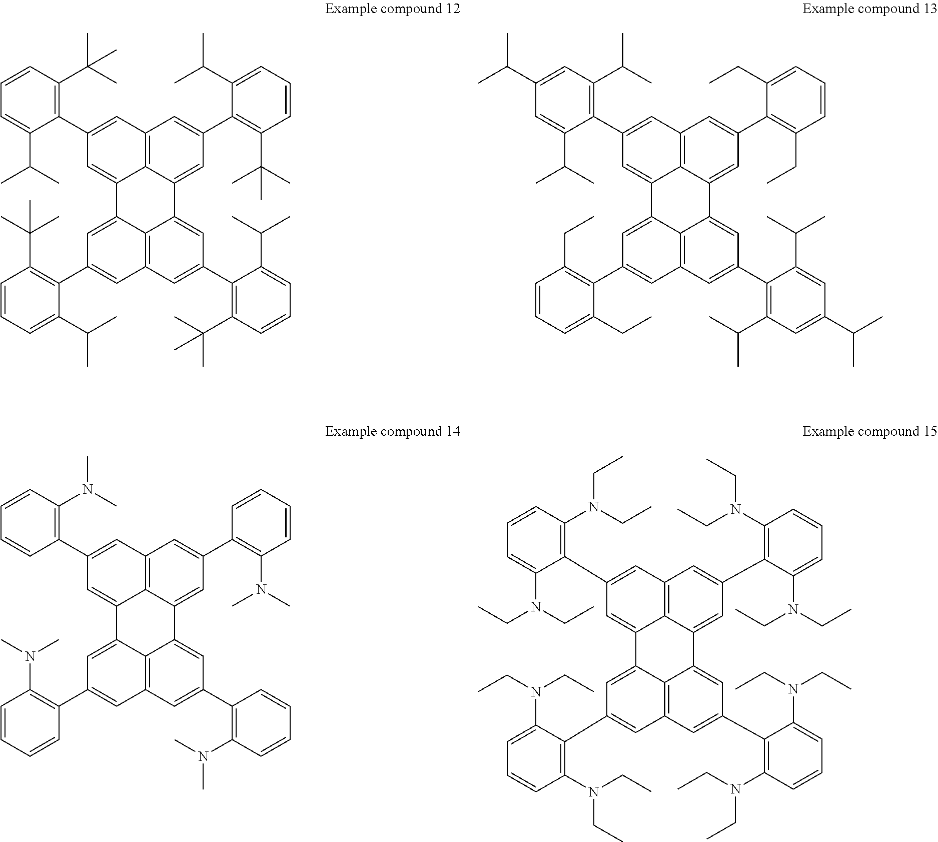

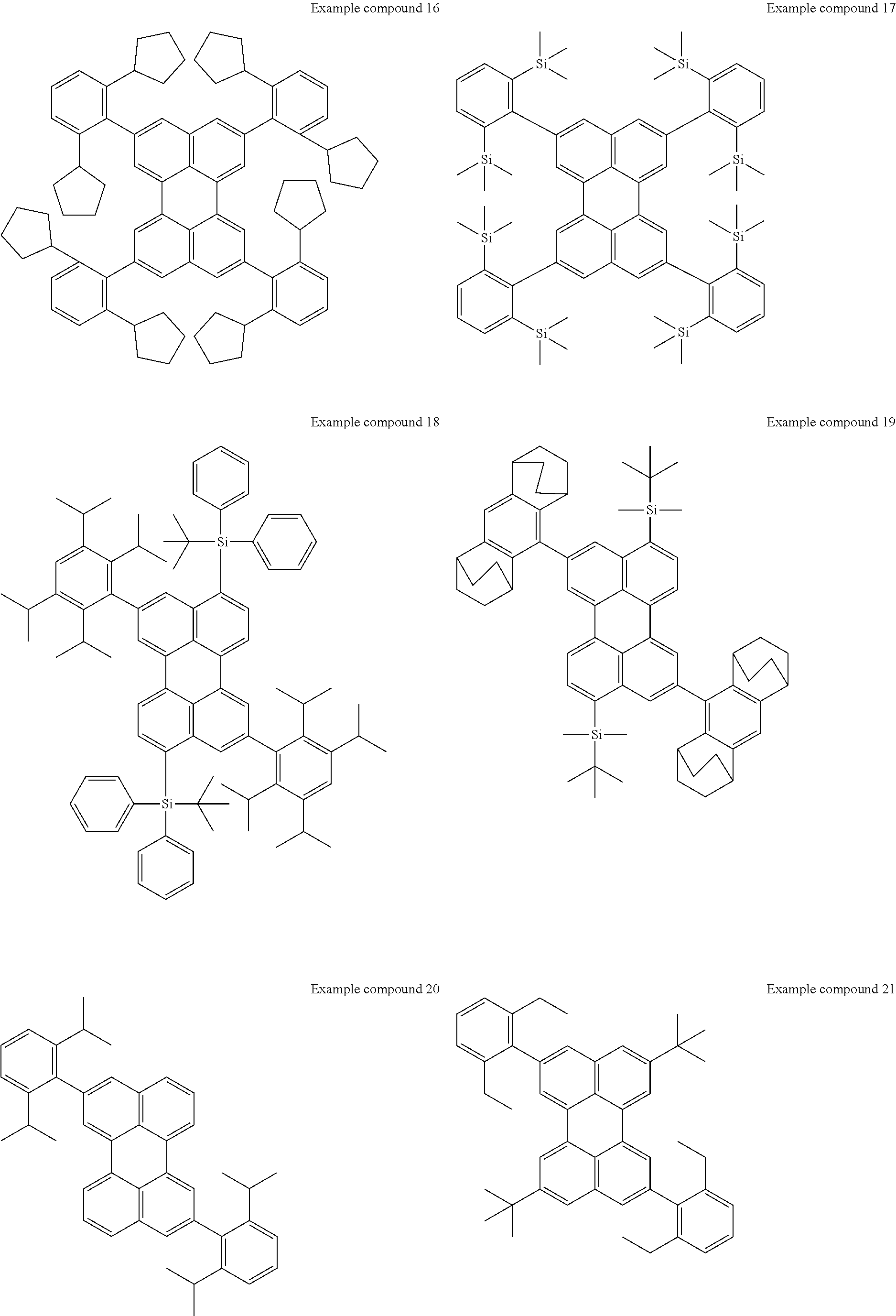

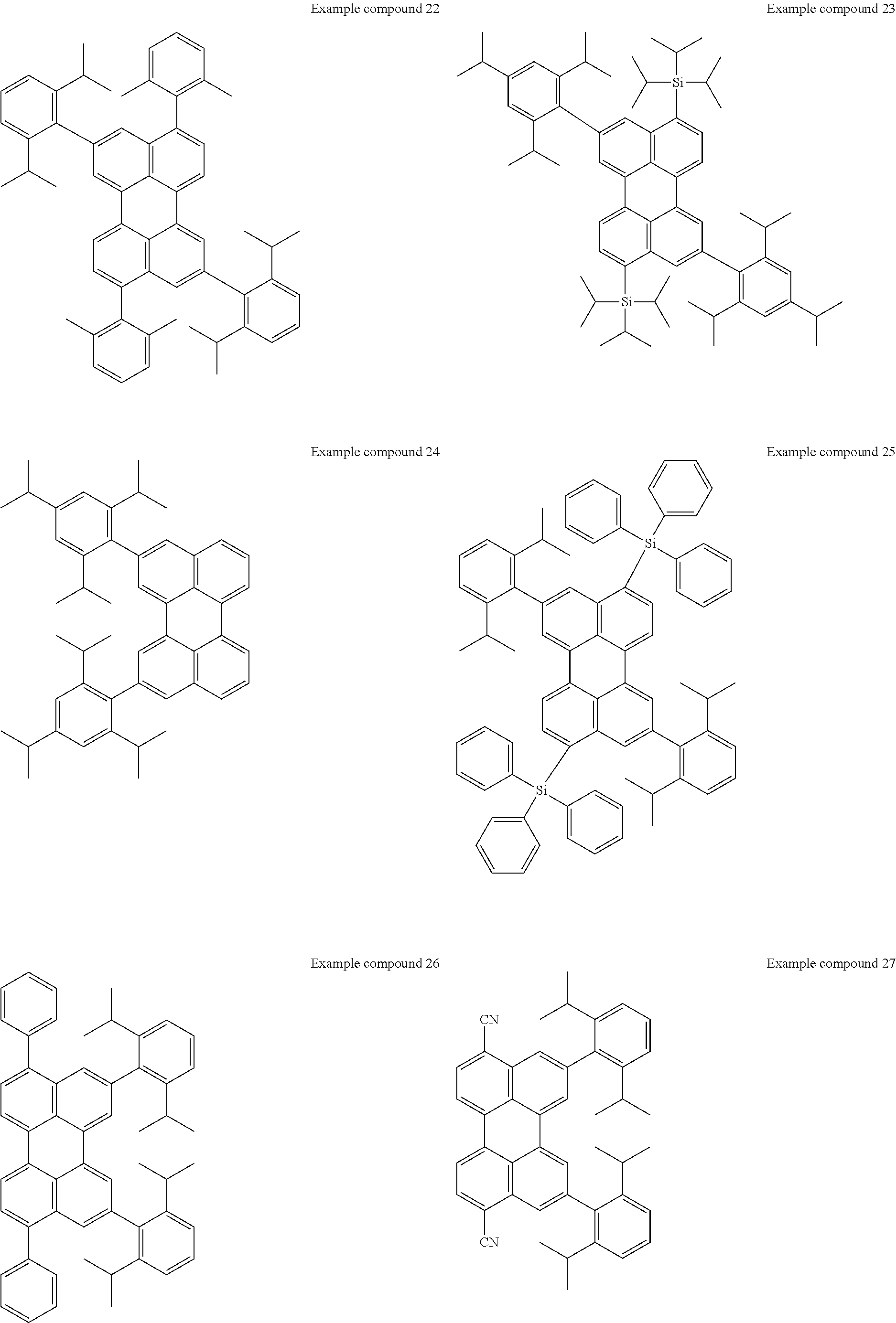

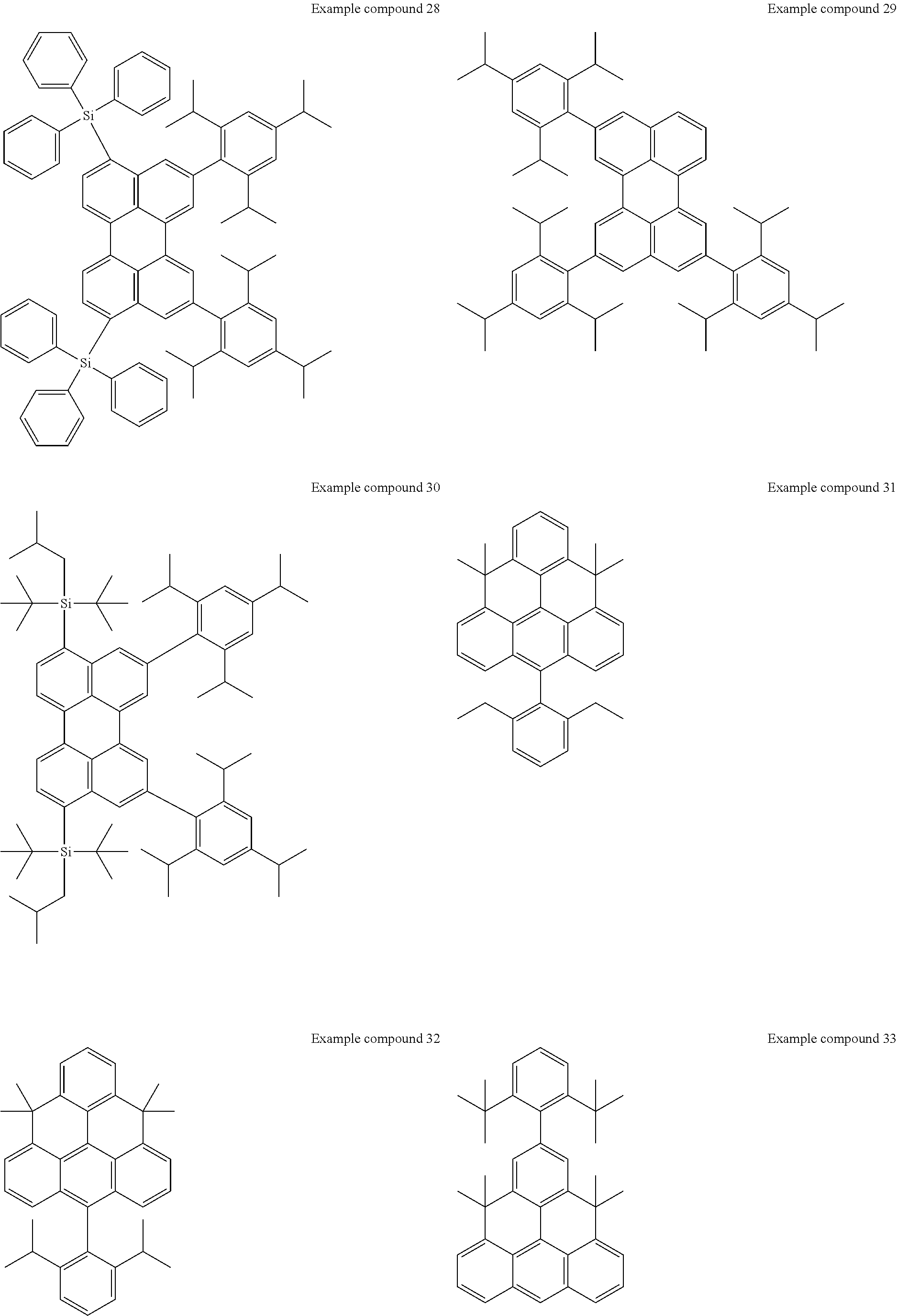

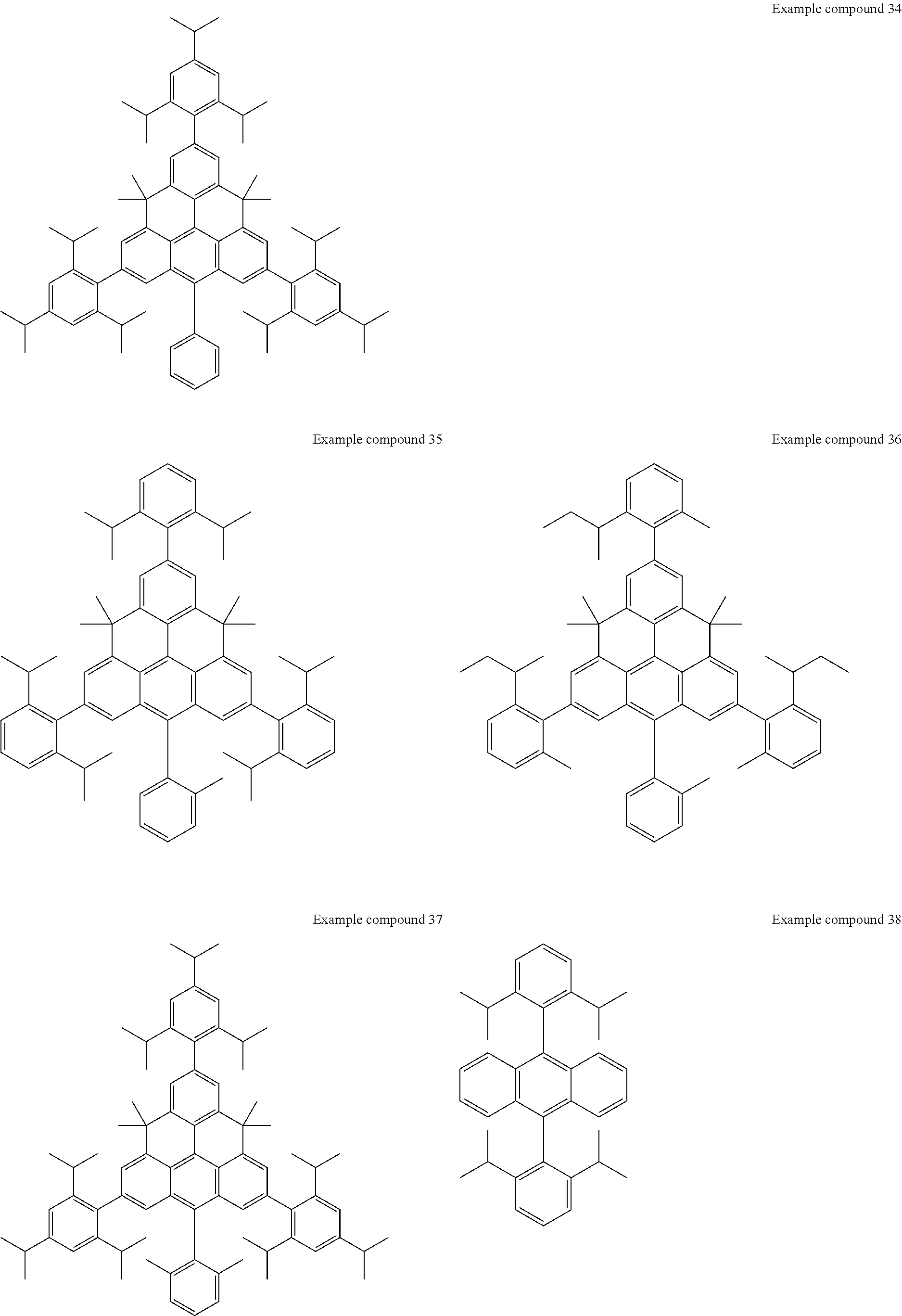

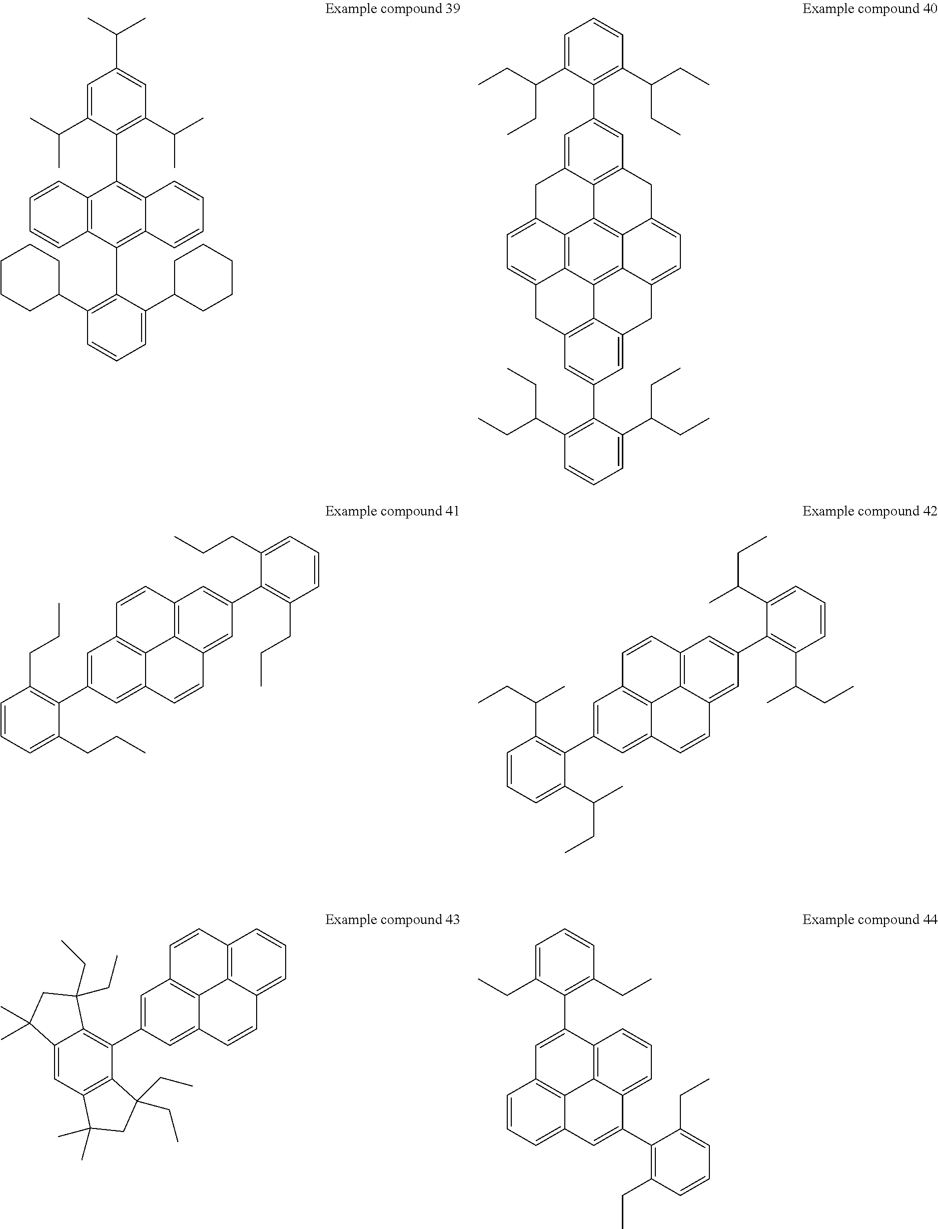

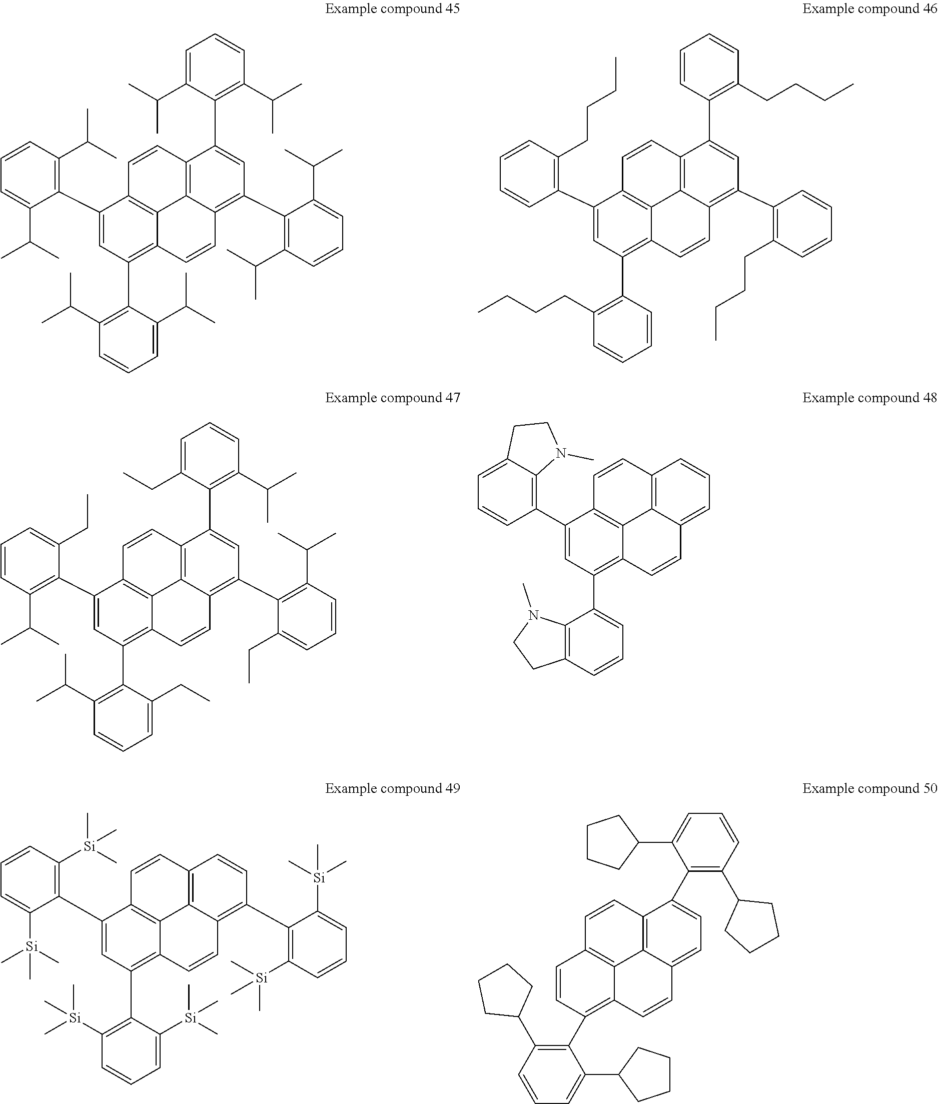

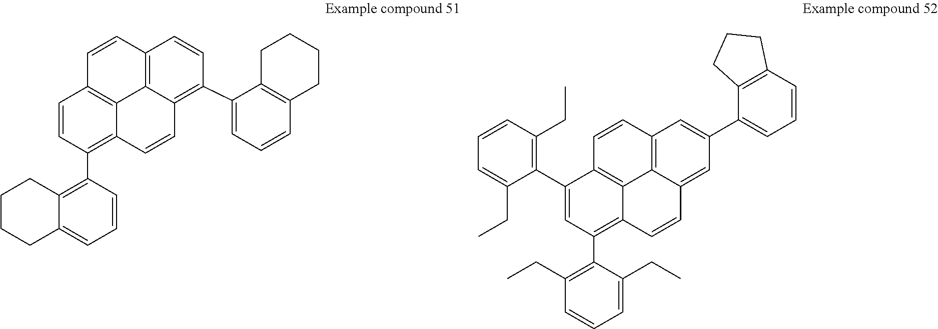

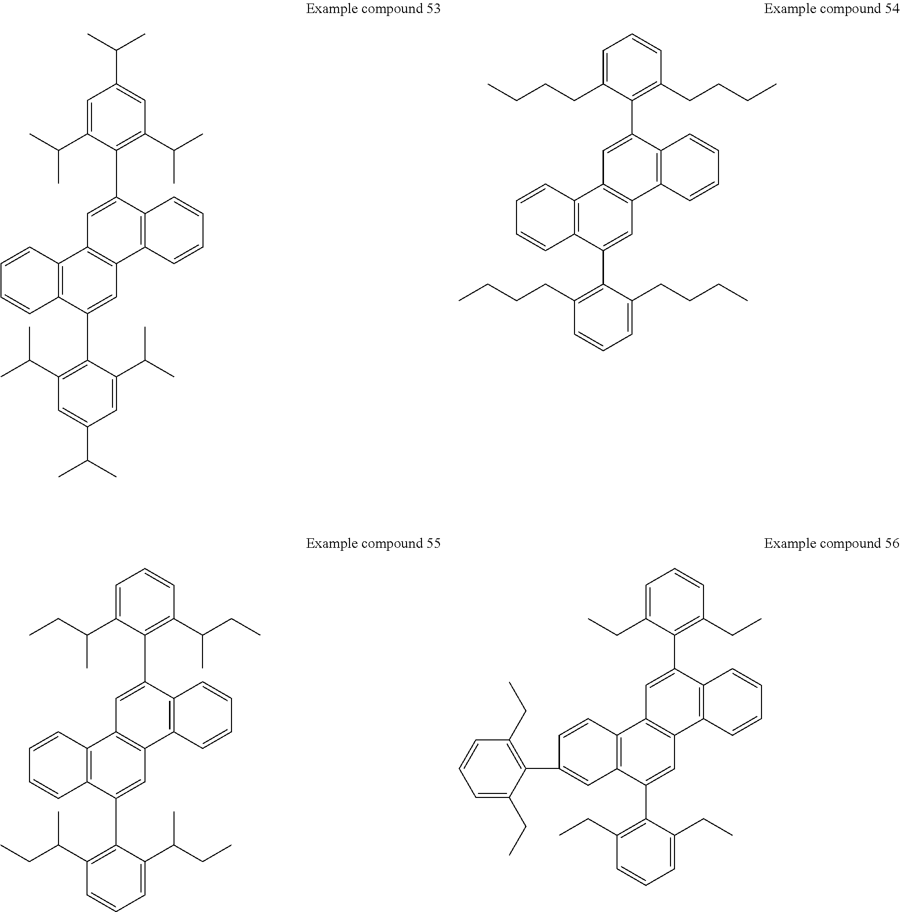

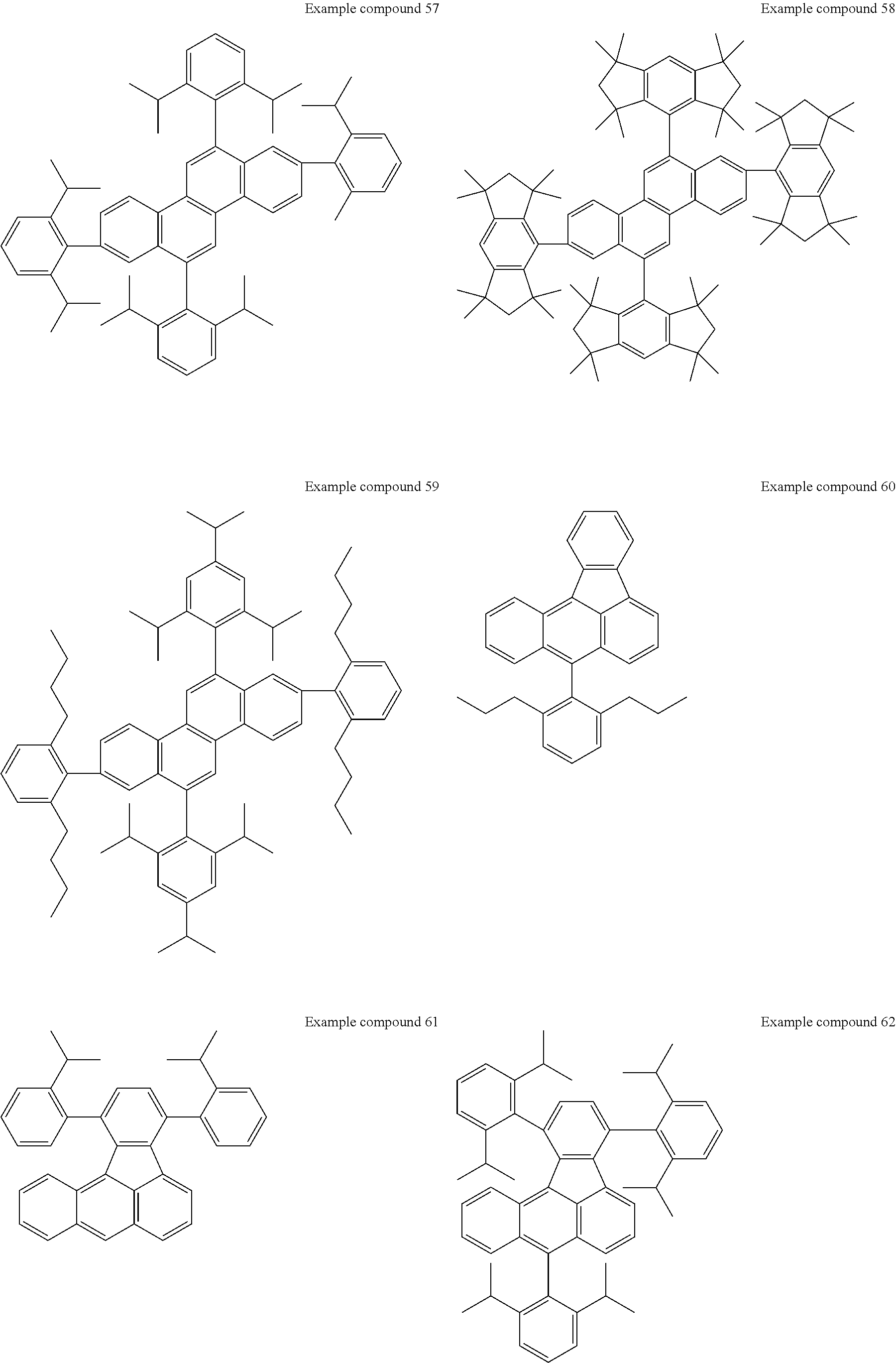

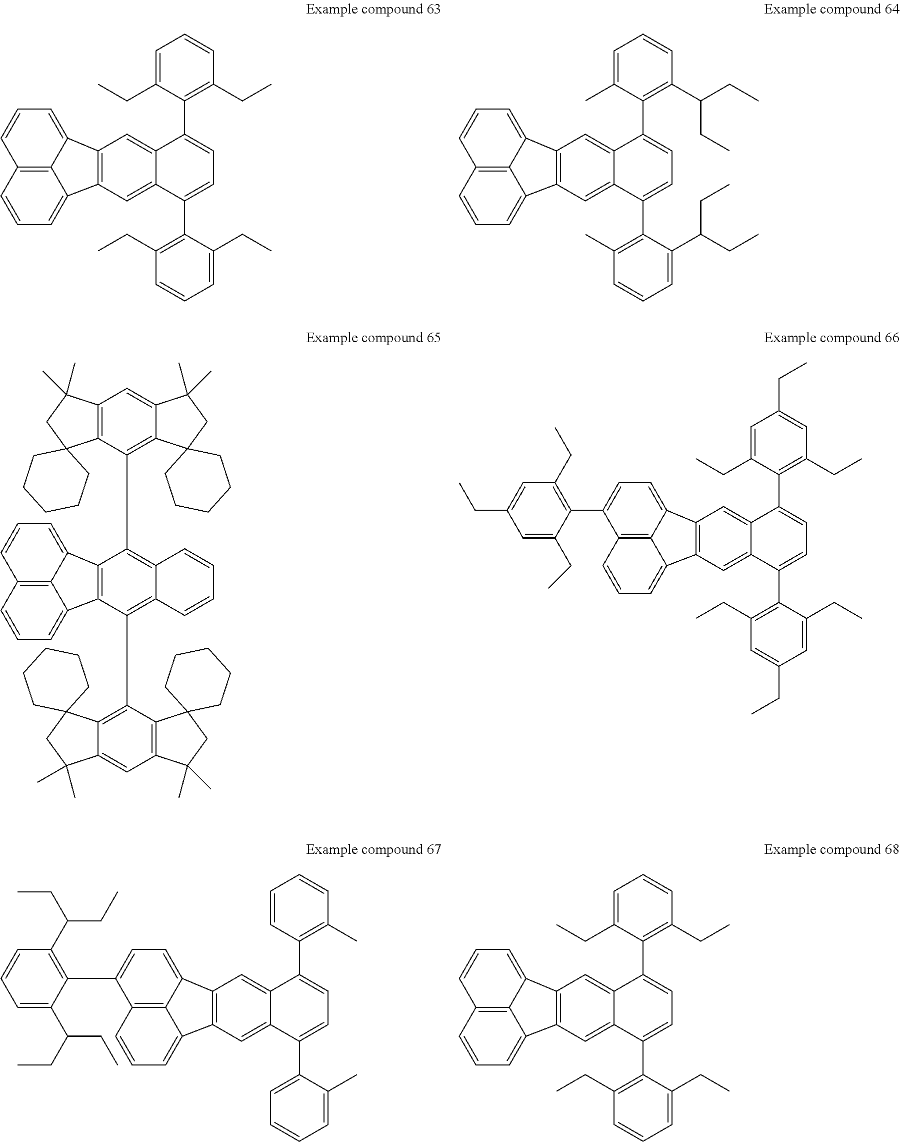

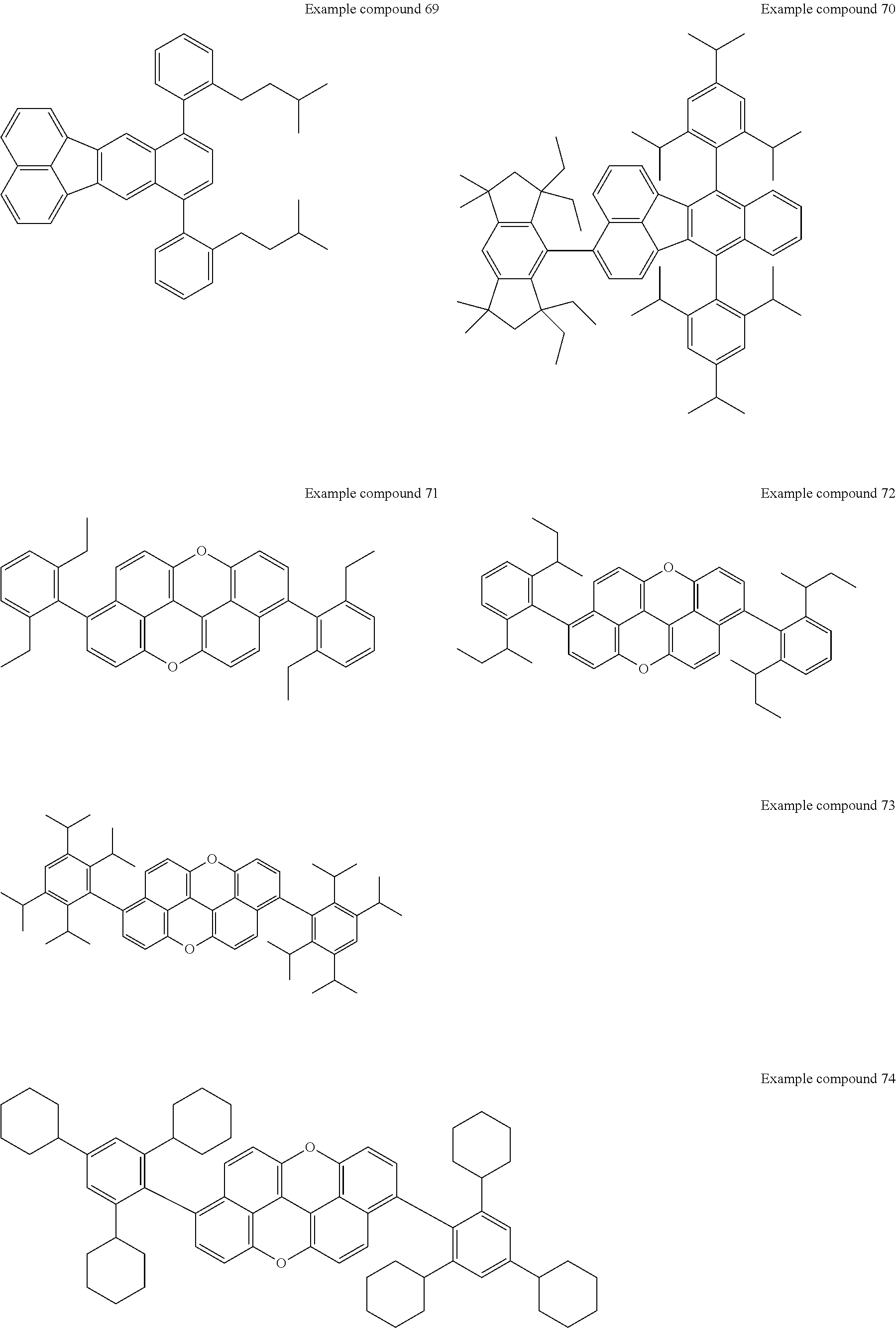

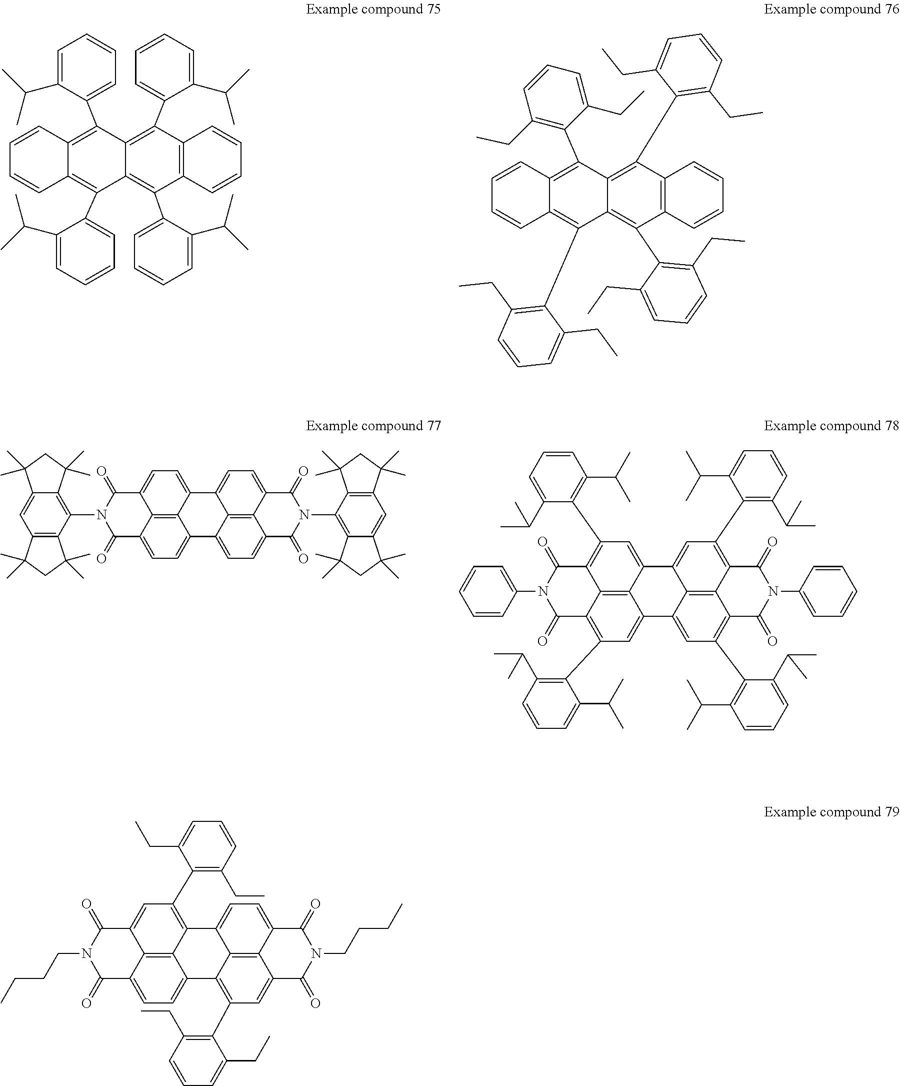

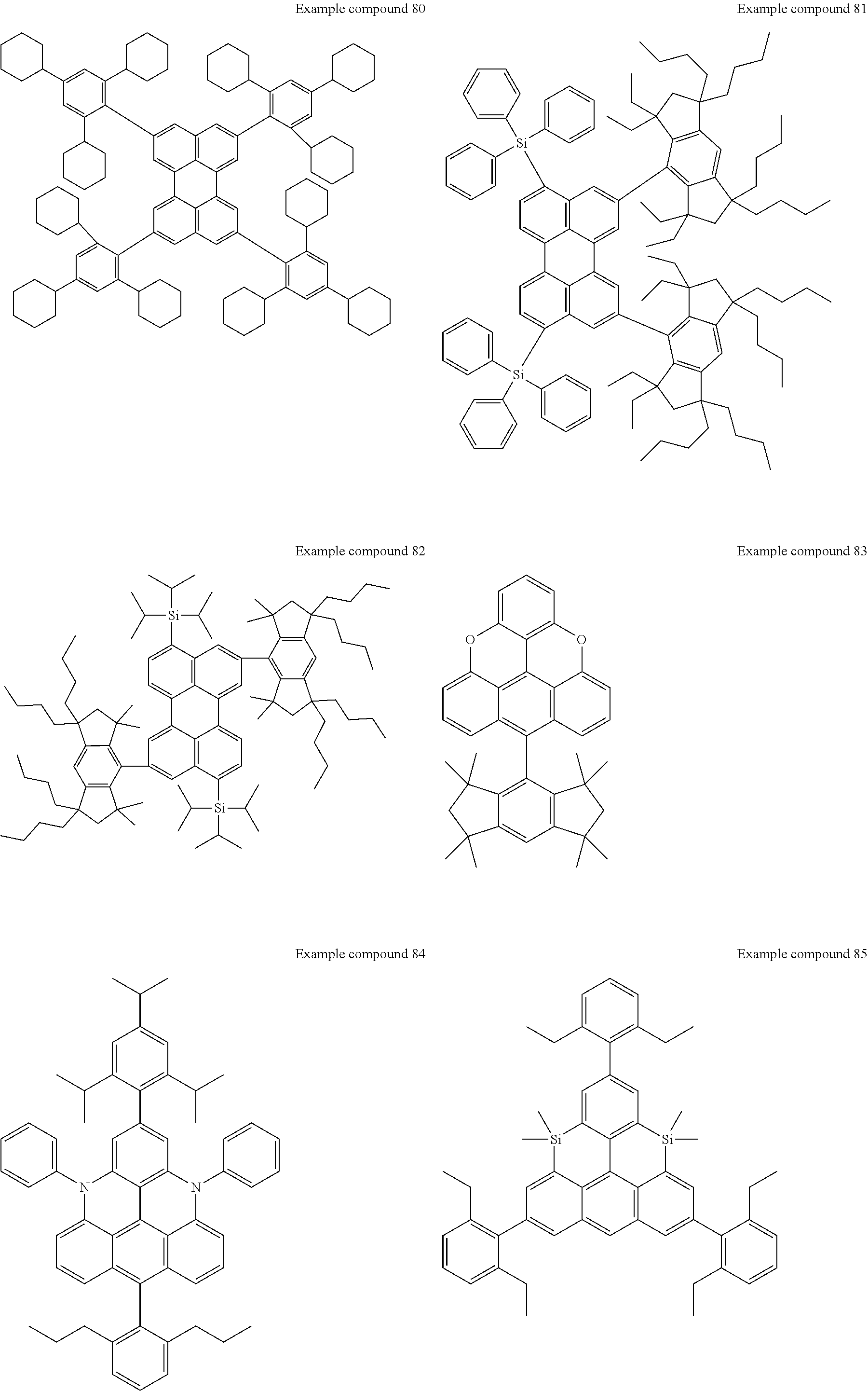

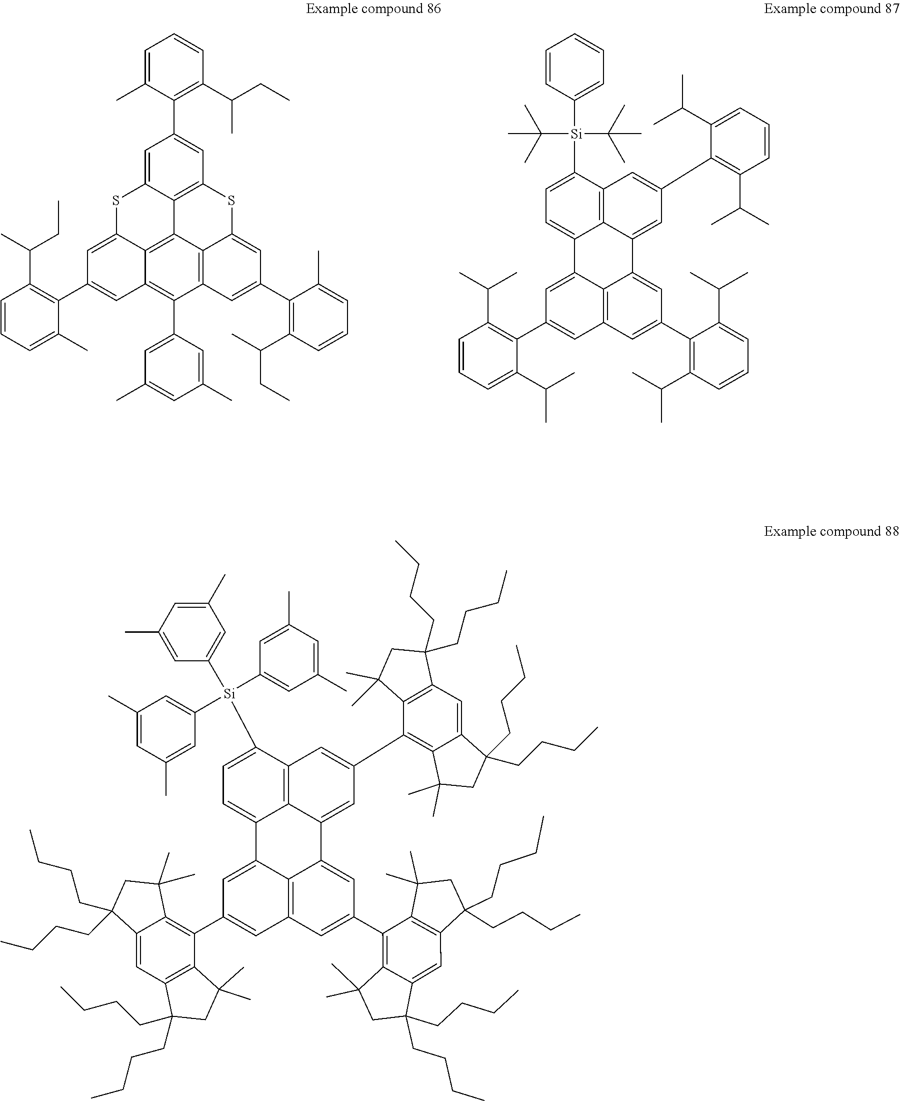

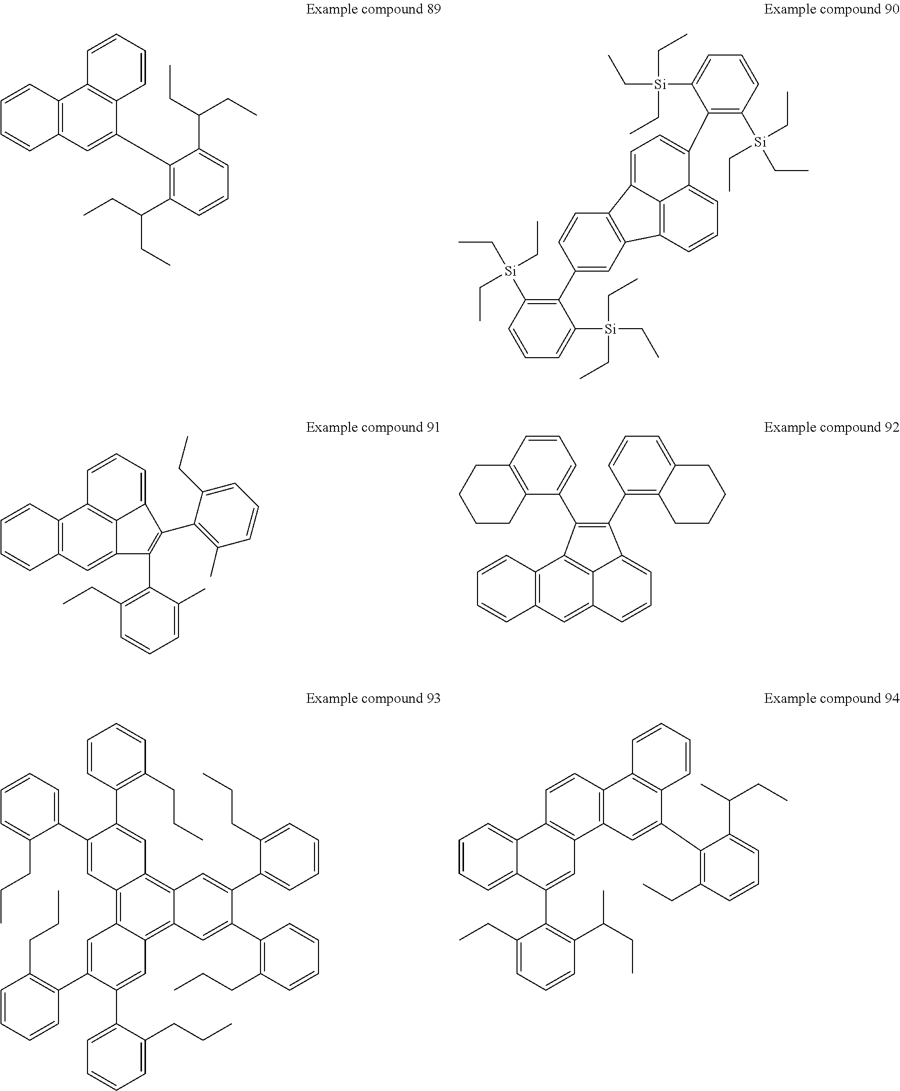

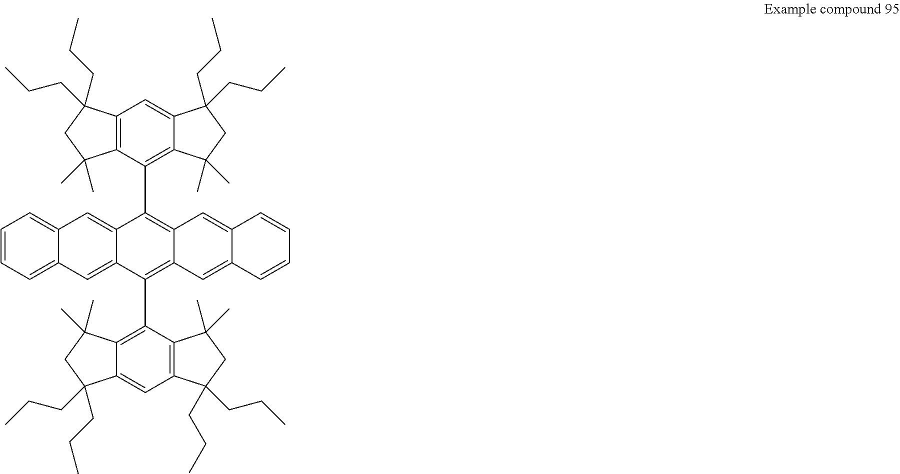 [SMILES: CCCC1(CCC)CC(C)(C)c2c1cc1c(c2-c2c3cc4ccccc4cc3c(-c3c4c(cc5c3C(C)(C)CC5(CCC)CCC)C(CCC)(CCC)CC4(C)C)c3cc4ccccc4cc23)C(C)(C)CC1(CCC)CCC]

It is also preferable that the phosphorescent metal complex and the fluorescent compound satisfy at least one of Expression (c) and Expression (d) from the viewpoint of providing an organic electroluminescent element capable of emitting light with high luminous efficiency and long lifetime.

$$P ( HOMO ) > FL ( HOMO ) \qquad Expression ( c )$$

In Expression (c), P(HOMO) represents a HOMO energy level of the phosphorescent metal complex, and FL(HOMO) represents a HOMO energy level of the fluorescent compound.

$$P ( LUMO ) < FL ( LUMO ) \qquad Expression ( d )$$

In Expression (d), P(LUMO) represents a LUMO energy level of the phosphorescent metal complex, and FL(LUMO) represents a LUMO energy level of the fluorescent compound.

By satisfying at least one of the above-mentioned Expressions (c) and (d), carrier recombination is facilitated on the luminescent metal complex and light can be emitted with higher efficiency.

### <HOMO and LUMO>

LUMO is the lowest unoccupied molecular orbital of a compound. And, the LUMO energy level is energy that stabilizes electrons in the vacuum level falling into the LUMO of the compound and it is defined by the energy when the vacuum level is set to zero.

HOMO is the highest occupied molecular orbital of a compound. And the HOMO energy level is defined as a value obtained by multiplying the energy required to move electrons in HOMO to the vacuum level by −1.

In the present invention, the values of the HOMO energy level and the LUMO energy level are determined by Gaussian 98, a software for calculating the molecular orbital (Gaussian 98, Revision A. 11.4, M. J. Frisch, et al, Gaussian, Inc., Pittsburgh PA, 2002). It is defined as a value (converted to eV unit) calculated by performing structural optimization using B3LYP/6-31G* for the fluorescent material and B3LYP/LanL2DZ for the luminescent metal complex. The correlation between the calculated value and the experimental value obtained by this method is high as the background where this calculated value is valid.

### <Organic Functional Layer Containing Phosphorescent Metal Complex and Fluorescent Compound>

The organic electroluminescent device of the present invention is characterized by including an organic functional layer containing the phosphorescent metal complex and the fluorescent compound.

The organic functional layer containing the phosphorescent metal complex and the fluorescent compound according to the present invention functions as a light emitting layer, this layer provides a place for electrons and holes injected from the electrode or adjacent layer to recombine and to emit light via the exciton. The light emitting portion may be within the layer of the organic functional layer or the interface between the organic functional layer and the adjacent layer.

In the organic functional layer containing the phosphorescent metal complex and the fluorescent compound, phosphorescence emission from the excited phosphorescent compound and fluorescence emission from the fluorescent compound are performed (when there is no fluorescence sensitization). In addition, when there is fluorescence sensitization, energy is transferred from the phosphorescent metal complex to the fluorescent compound to cause fluorescent light to be emitted from the fluorescent compound. It is presumed that the phosphorescent metal complex functions as a sensitizer for making fluorescence emission function.

In the organic functional layer containing the phosphorescent metal complex and the fluorescent compound, the mass ratio of the phosphorescent metal complex and the fluorescent compound to be contained is not particularly limited, but from the viewpoint of luminous efficiency, it is preferable that the phosphorescent metal complex is contained in the range of 1 to 50 mass parts with respect to 1 mass part of the fluorescent compound.

The organic functional layer containing the phosphorescent metal complex and the fluorescent compound according to the present invention may be a single layer or a plurality of layers. In the case of having a plurality of organic functional layers, the phosphorescent metal complex and the fluorescent compound may be contained in different layers, respectively.

When the phosphorescent metal complex and the fluorescent compound are contained in different layers, phosphorescence and fluorescence can be emitted from the respective layers. In the case of fluorescence sensitization, it is presumed that energy transfer occurs from a layer containing a phosphorescent metal complex to a layer containing a fluorescent compound and the fluorescence emission from a fluorescent compound is increased.

The total thickness of the organic functional layers is not particularly limited. From the viewpoint of achieving homogeneity of the film to be formed and preventing application of unnecessary high voltage at the time of light emission and improvement of stability of luminescent color with respect to driving current, it is preferable to adjust in the range of 2 to 5000 nm, more preferably in the range of 2 to 500 nm, and further preferably in the range of 5 to 200 nm.

In the present invention, the thickness of each organic functional layer is preferably adjusted in the range of 2 to 1000 nm, more preferably adjusted in the range of 2 to 200 nm, further preferably in the range of 3 to 150 nm.

The organic functional layer according to the present invention contains the aforementioned phosphorescent metal complex (core-shell type dopant) and a fluorescent compound.

However, the organic functional layer according to the present invention may further contain a host compound described below or other dopant within a range of not hindering the effect of the present invention.

Further, a combination of a plurality of phosphorescent metal complexes and fluorescent compounds may be used in the present invention. In this way, arbitrary luminescent color can be obtained.

Color of light emitted by an organic EL element or a compound of the present invention is specified as follows. In FIG. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via Spectroradiometer CS-1000 (produced by Konica Minolta, Inc.) are applied to the CIE chromaticity coordinate, whereby the color is specified.

In the present invention, it is also preferable that one or a plurality of organic functional layers contain a plurality of light emitting dopants having different luminescent colors and to emit white light.

The combination of luminescent dopants that produces white is not specifically limited. It may be cited, for example, combinations of: blue and orange; and blue, green and red.

It is preferable that “white” in the organic EL element of the present invention exhibits chromaticity in the CIE 1931 Color Specification System at 1,000 cd/m² in the region of x=0.39±0.09 and y=0.38±0.08, when measurement is done to 2-degree viewing angle front luminance via the aforesaid method.

### <Host Compound>

A host compound (hereinafter, it may be called simply “host”) used in the present invention is a compound which mainly plays a role of injecting or transporting a charge in the organic functional layer (hereinafter, it may be called “a light emitting layer”). In an organic EL element, an emission from the host compound itself is substantially not observed.

Preferably, the host compound is a compound exhibiting a phosphorescent emission yield of less than 0.1 at a room temperature (25° C.), more preferably a compound exhibiting a phosphorescent emission yield of less than 0.01.

It is preferable that the excited energy level of the host compound is higher than the excited energy level of the phosphorescent metal complex contained in the same layer.

Host compounds may be used singly or may be used in combination of two or more compounds. By using a plurality of host compounds, it is possible to adjust transfer of charge, thereby it is possible to achieve an organic EL element of high efficiency.

A host compound used in the present invention is not specifically limited. A known compound previously used in an organic EL element may be used. It may be a compound having a low molecular weight, or a polymer having a high molecular weight. Further, it may be a compound having a reactive group such as a vinyl group or an epoxy group.

As a known host compound, preferably, it has a hole transporting ability or an electron transporting ability, as well as preventing elongation of an emission wavelength. In addition, from the viewpoint of stably driving an organic EL element at high temperature, it is preferable that a host compound has a high glass transition temperature (Tg) of 90° C. or more, more preferably, has a Tg of 120° C. or more.

Here, a glass transition temperature (Tg) is a value obtained using DSC (Differential Scanning Colorimetry) based on the method in conformity to JIS-K-7121.

The host compound according to the present invention is preferably a compound having a structure represented by the following Formula (HA) or Formula (HB).

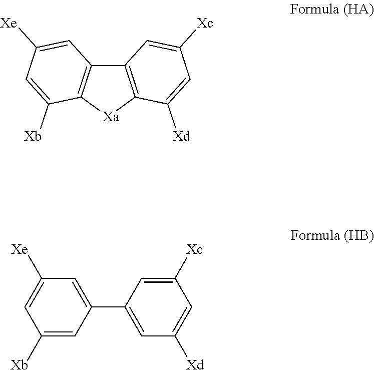

In Formula (HA) and Formula (HB), Xa represents O or S. Xb, Xc, Xd and Xe each independently represent a hydrogen atom, a substituent or a group having a structure represented by the following Formula (HC). At least one of Xb, Xc, Xd and Xe represents a group having a structure represented by the following Formula (HC), and at least one of groups having a structure represented by the following Formula (HC). It is preferred that Ar represents a carbazolyl group.

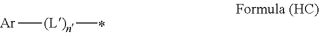

In Formula (HC), L′ represents a divalent linking group derived from an aromatic hydrocarbon ring or an aromatic heterocyclic ring. n represents an integer of 0 to 3, and when n is 2 or more, plural L's may be the same or different. A symbol * represents a linking site with Formula (HA) or Formula (HB). Ar represents a group having a structure represented by the following Formula (HD).

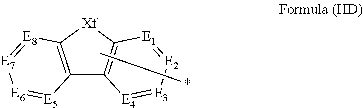

In Formula (HD), Xf represents N(R′), O or S. E₁ to E₈ represents C(R″) or N. R′ and R″ represent a hydrogen atom, a substituent or a linking site with L′ in Formula (HC). A symbol * represents a linking site with L′ in Formula (HC).

In the compound having a structure represented by the Formula (HA), at least two of Xb, Xc, Xd and Xe are preferably represented by the general formula (HC), more preferably Xc is represented by Formula (HC), and Ar in Formula (HC) represents a carbazolyl group which may have a substituent.

As the substituents represented by Xb, Xc, Xd and Xe in the Formulas (HA) and (HB) and the substituents represented by R′ and R″ in Formula (HD), it may be cited the same substituents which may be held by the ring Z₁ and the ring Z₂ in Formula (DP).

Examples of the aromatic hydrocarbon ring represented by L′ in Formula (HC) include: a benzene ring, a p-chlorobenzene ring, a mesitylene ring, a toluene ring, a xylene ring, a naphthalene ring, an anthracene ring, an azulene ring, an acenaphthene ring, a fluorene ring, a phenanthrene ring, an indene ring, a pyrene ring, and a biphenyl ring.

Examples of the aromatic heterocyclic ring represented by L′ in Formula (HC) include: a furan ring, a thiophene ring, a pyridine ring, a pyridazine ring, a pyrimidine ring, a pyrazine ring, a triazole ring, an imidazole ring, a pyrazole ring, a thiazole ring, a quinazoline ring, a carbazole ring, a carboline ring, a diazacarbazole ring (indicating a ring structure in which an arbitral carbon atom constituting the carboline ring is replaced with a nitrogen atom), and a phthalazine ring.

Specific examples of the host compound according to the present invention include compounds applicable to the present invention besides the compound having the structure represented by Formula (HA) or Formula (HB), but the present invention is not particularly limited to these compounds.

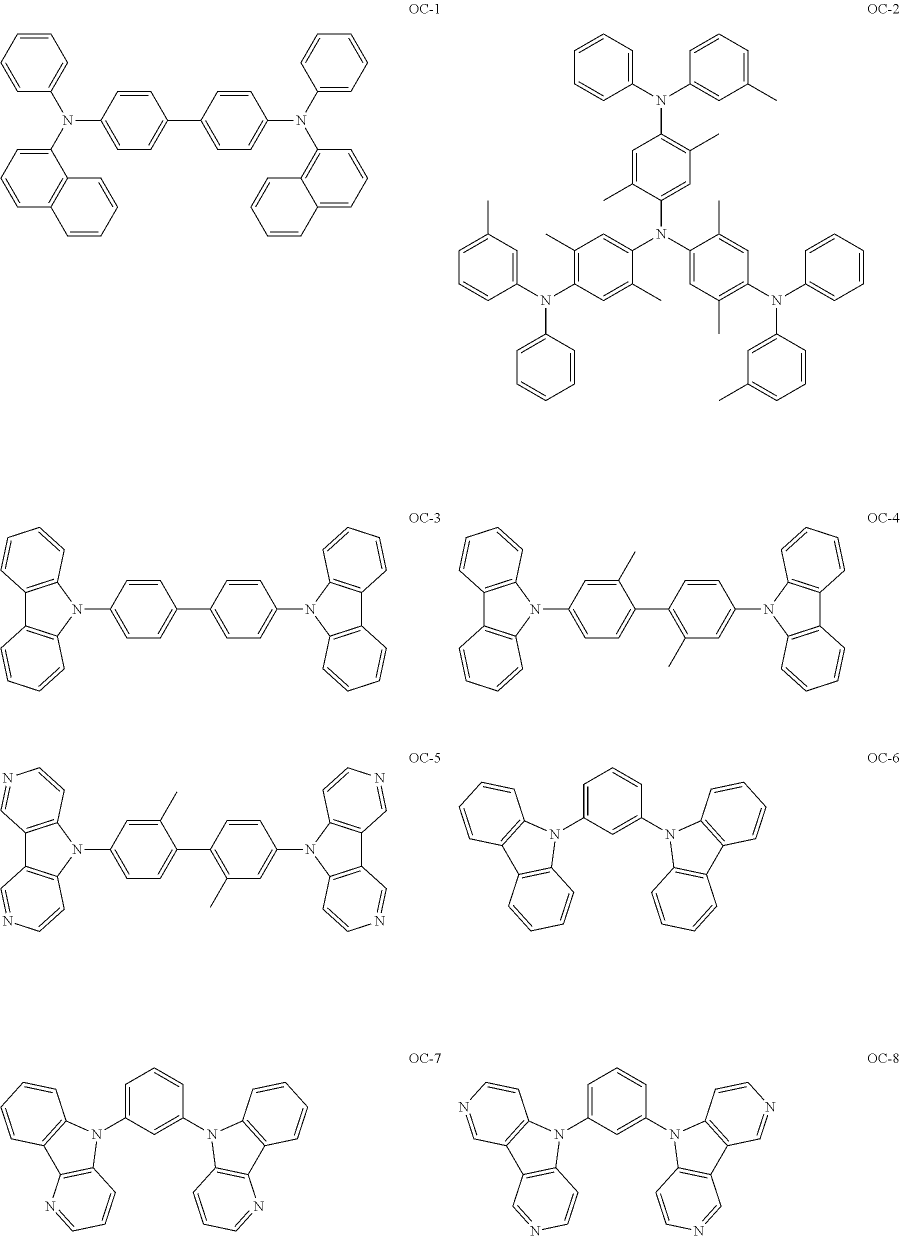

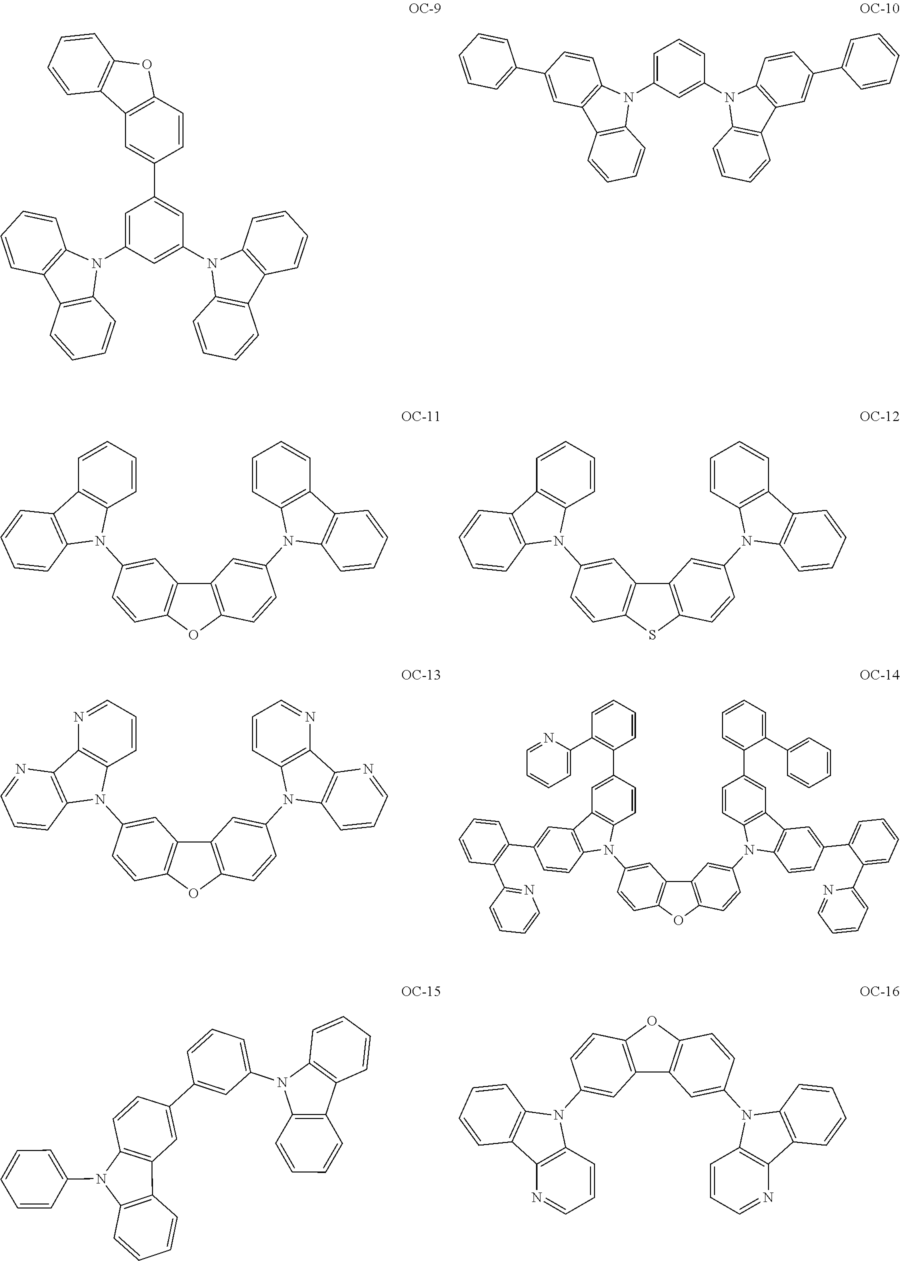

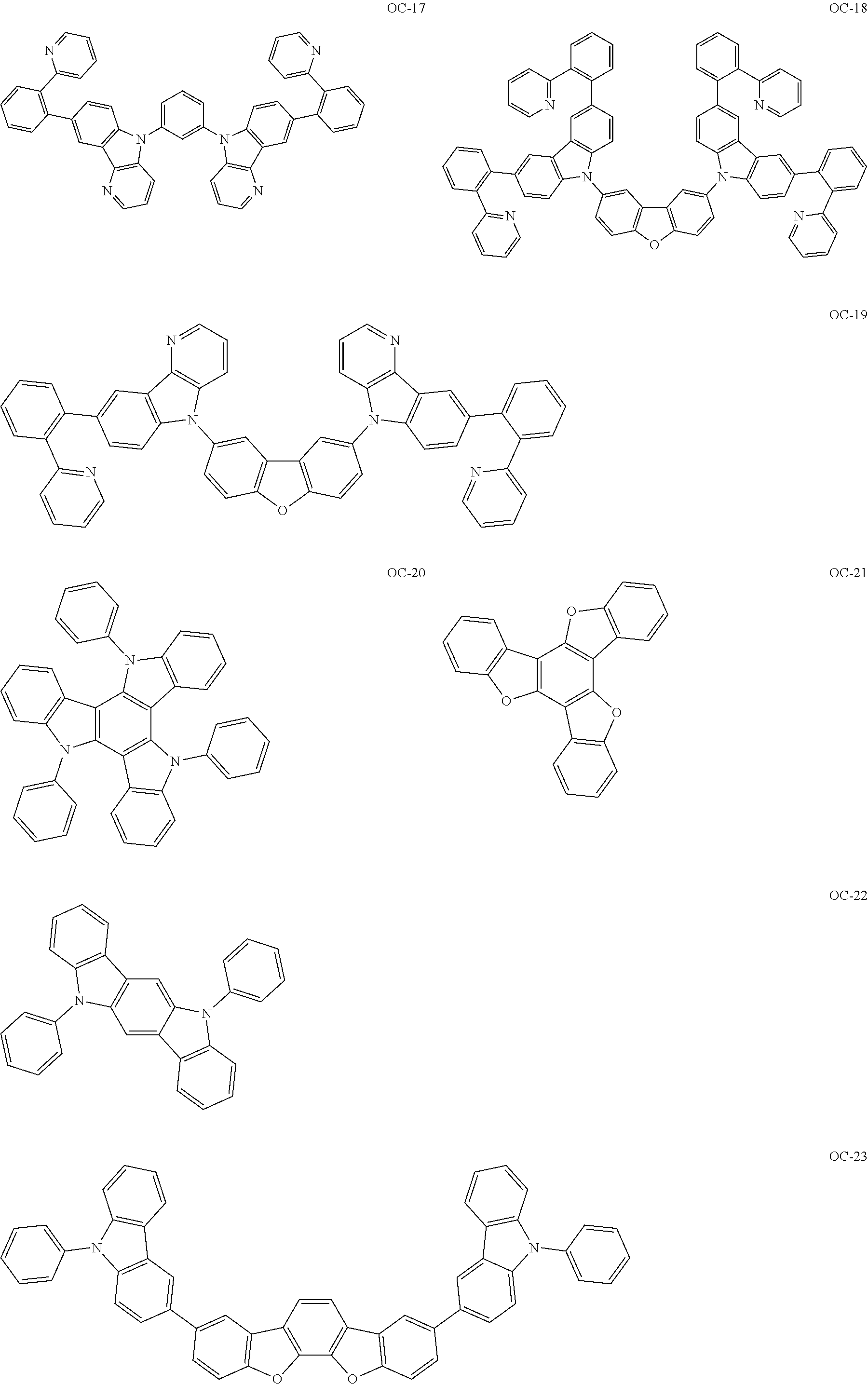

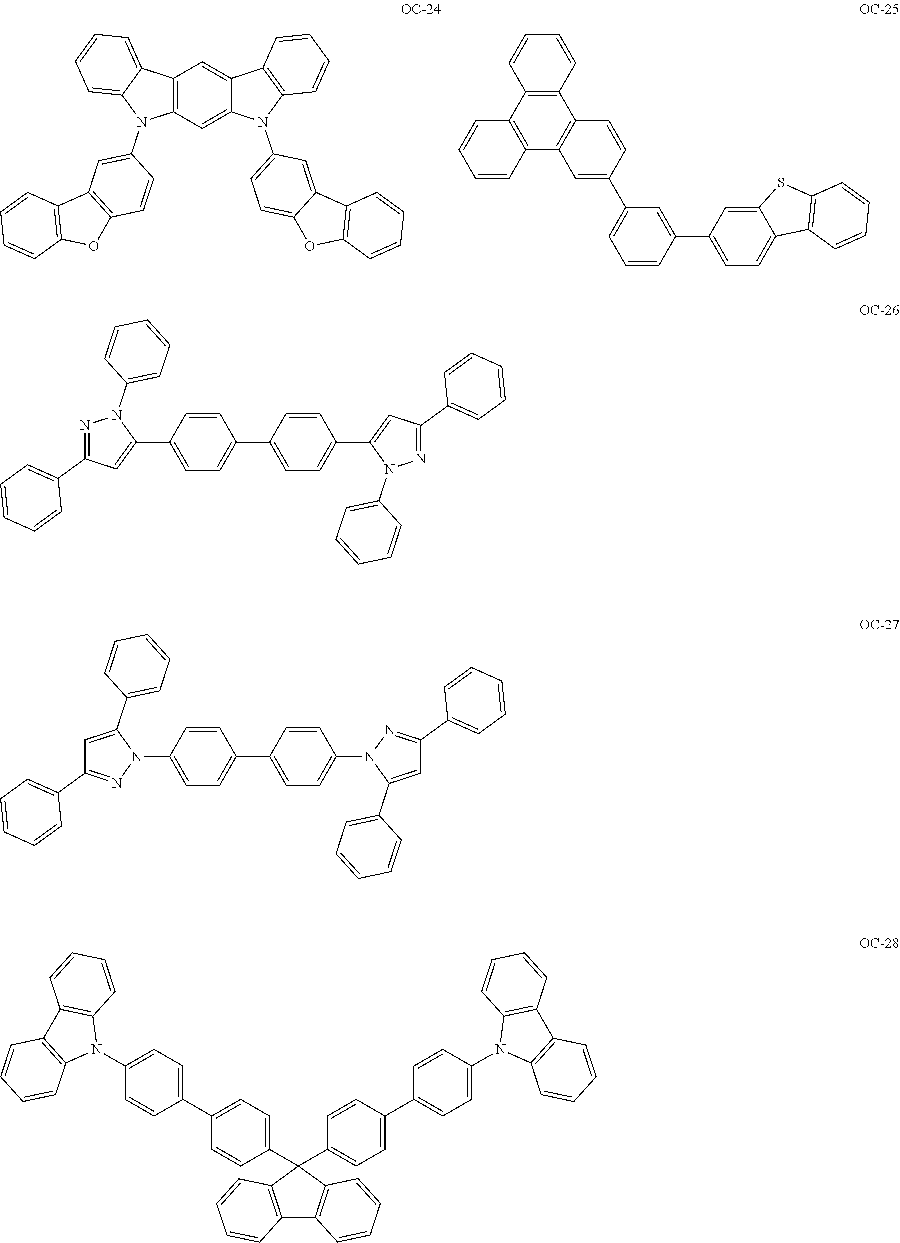 [SMILES: c1ccc2c(c1)oc1ccc(-n3c4ccccc4c4cc5c6ccccc6n(-c6ccc7oc8ccccc8c7c6)c5cc43)cc12 ; c1cc(-c2ccc3c(c2)sc2ccccc23)cc(-c2ccc3c4ccccc4c4ccccc4c3c2)c1 ; c1ccc(-c2cc(-c3ccc(-c4ccc(-c5cc(-c6ccccc6)nn5-c5ccccc5)cc4)cc3)n(-c3ccccc3)n2)cc1 ; c1ccc(-c2cc(-c3ccccc3)n(-c3ccc(-c4ccc(-n5nc(-c6ccccc6)cc5-c5ccccc5)cc4)cc3)n2)cc1 ; c1ccc2c(c1)-c1ccccc1C2(c1ccc(-c2ccc(-n3c4ccccc4c4ccccc43)cc2)cc1)c1ccc(-c2ccc(-n3c4ccccc4c4ccccc43)cc2)cc1]

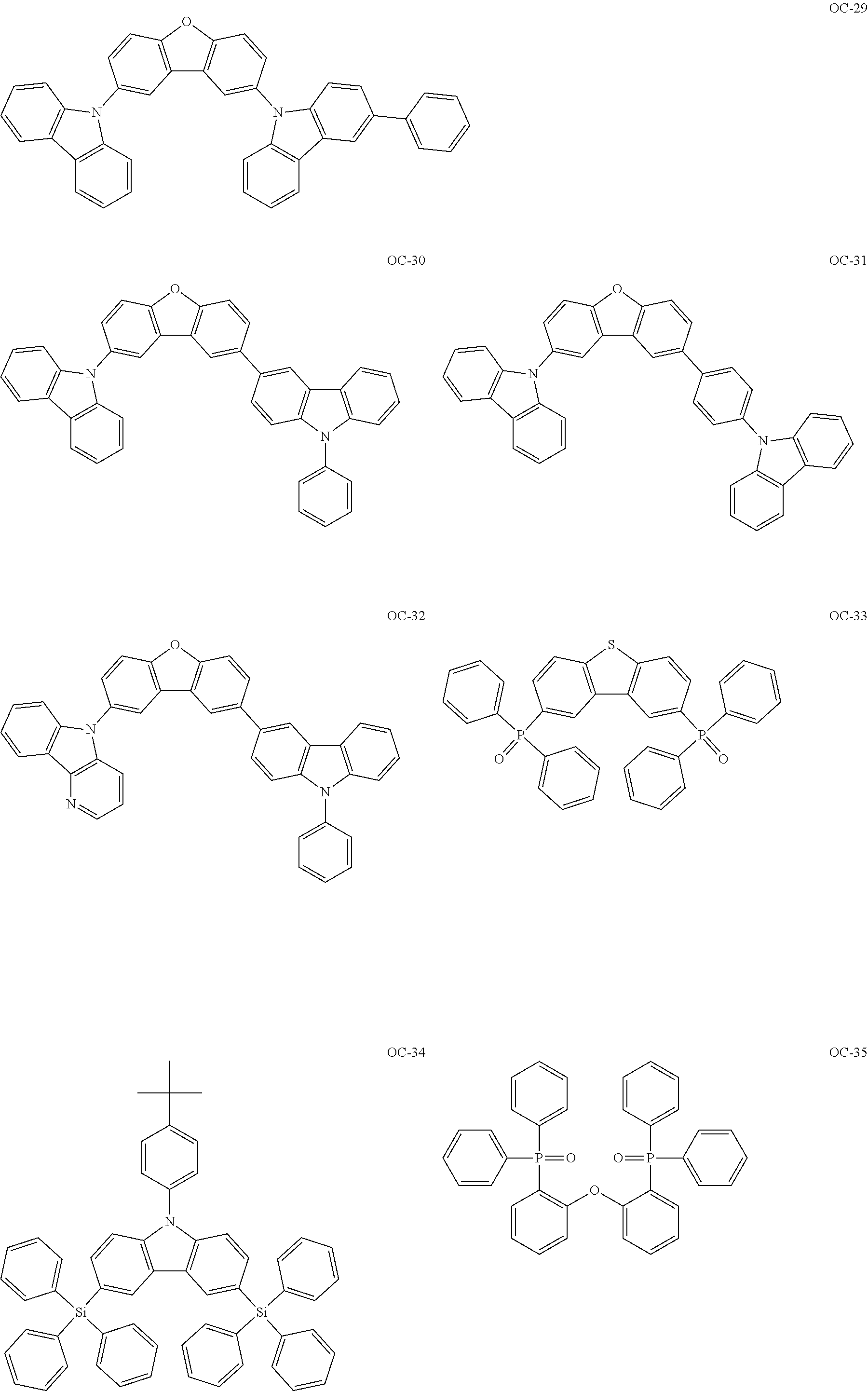

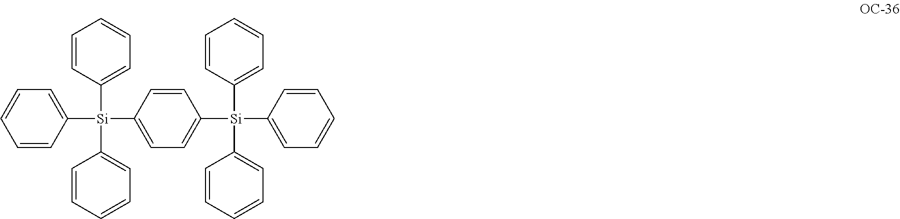 [SMILES: c1ccc([Si](c2ccccc2)(c2ccccc2)c2ccc([Si](c3ccccc3)(c3ccccc3)c3ccccc3)cc2)cc1]

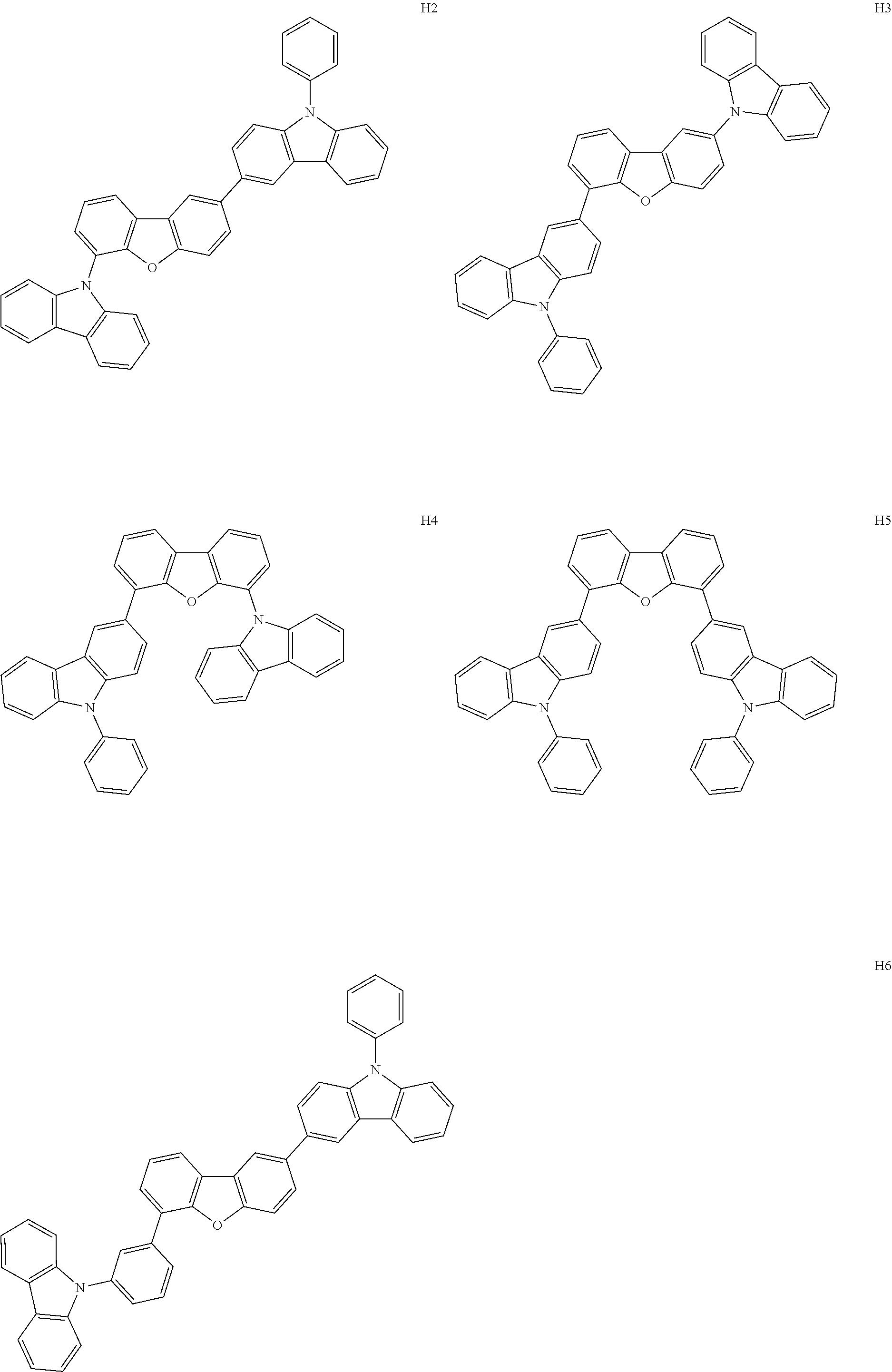 [SMILES: c1ccc(-n2c3ccccc3c3cc(-c4ccc5oc6c(-n7c8ccccc8c8ccccc87)cccc6c5c4)ccc32)cc1 ; c1ccc(-n2c3ccccc3c3cc(-c4cccc5c4oc4ccc(-n6c7ccccc7c7ccccc76)cc45)ccc32)cc1 ; c1ccc(-n2c3ccccc3c3cc(-c4cccc5c4oc4c(-n6c7ccccc7c7ccccc76)cccc45)ccc32)cc1 ; c1ccc(-n2c3ccccc3c3cc(-c4cccc5c4oc4c(-c6ccc7c(c6)c6ccccc6n7-c6ccccc6)cccc45)ccc32)cc1 ; c1ccc(-n2c3ccccc3c3cc(-c4ccc5oc6c(-c7cccc(-n8c9ccccc9c9ccccc98)c7)cccc6c5c4)ccc32)cc1]

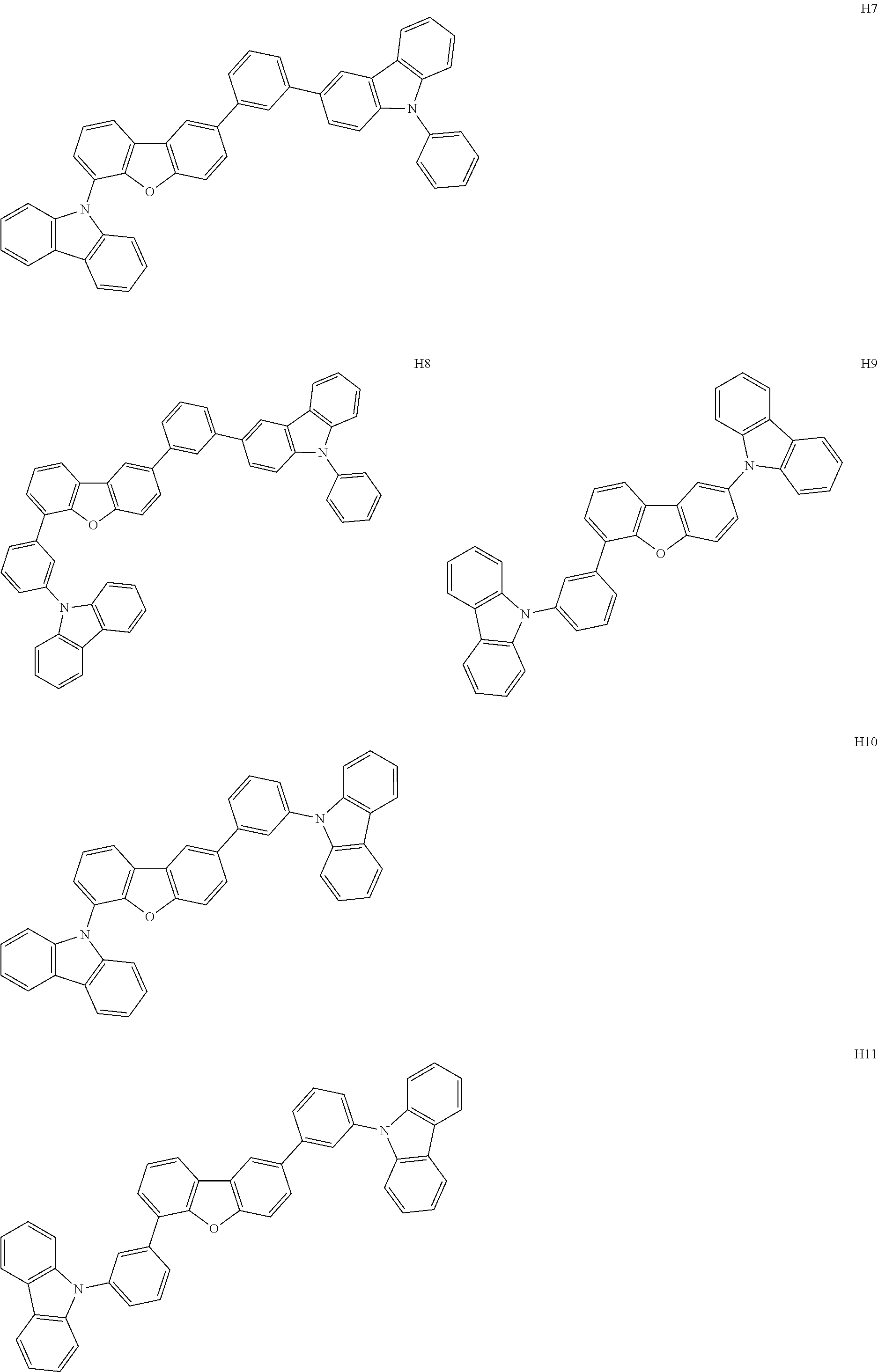 [SMILES: c1ccc(-n2c3ccccc3c3cc(-c4cccc(-c5ccc6oc7c(-n8c9ccccc9c9ccccc98)cccc7c6c5)c4)ccc32)cc1 ; c1ccc(-n2c3ccccc3c3cc(-c4cccc(-c5ccc6oc7c(-c8cccc(-n9c%10ccccc%10c%10ccccc%109)c8)cccc7c6c5)c4)ccc32)cc1 ; c1cc(-c2cccc3c2oc2ccc(-n4c5ccccc5c5ccccc54)cc23)cc(-n2c3ccccc3c3ccccc32)c1 ; c1cc(-c2ccc3oc4c(-n5c6ccccc6c6ccccc65)cccc4c3c2)cc(-n2c3ccccc3c3ccccc32)c1 ; c1cc(-c2ccc3oc4c(-c5cccc(-n6c7ccccc7c7ccccc76)c5)cccc4c3c2)cc(-n2c3ccccc3c3ccccc32)c1]

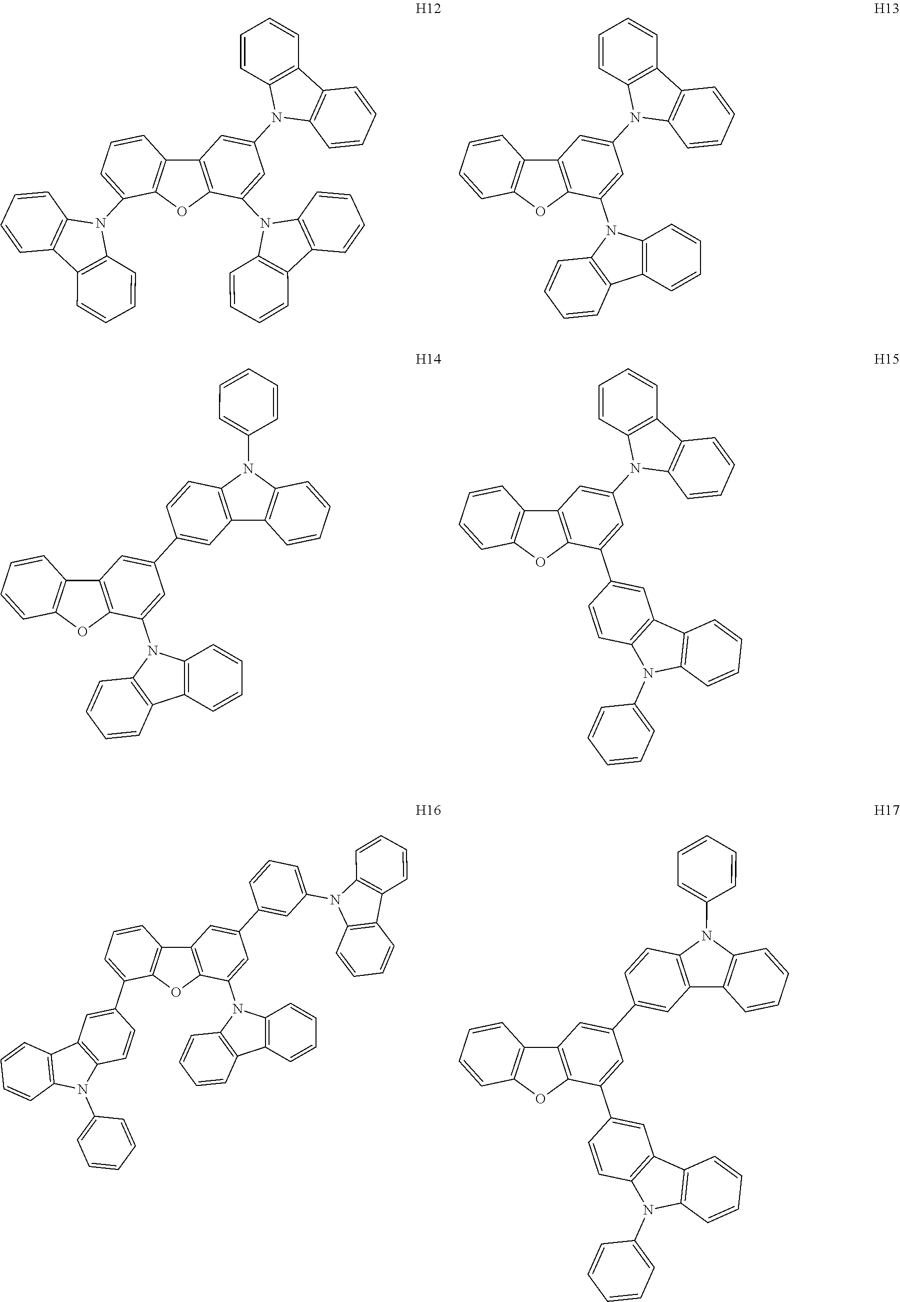

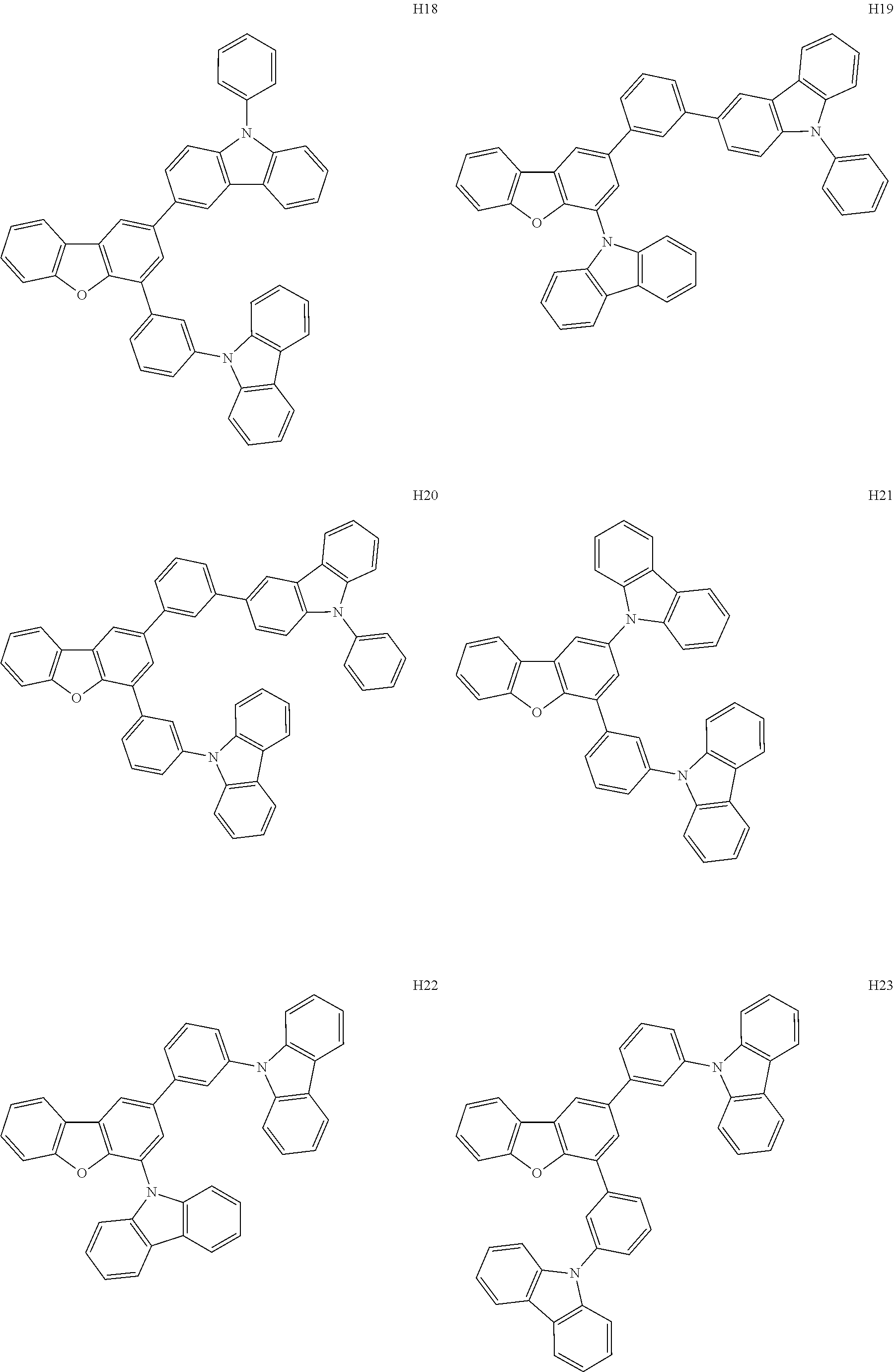

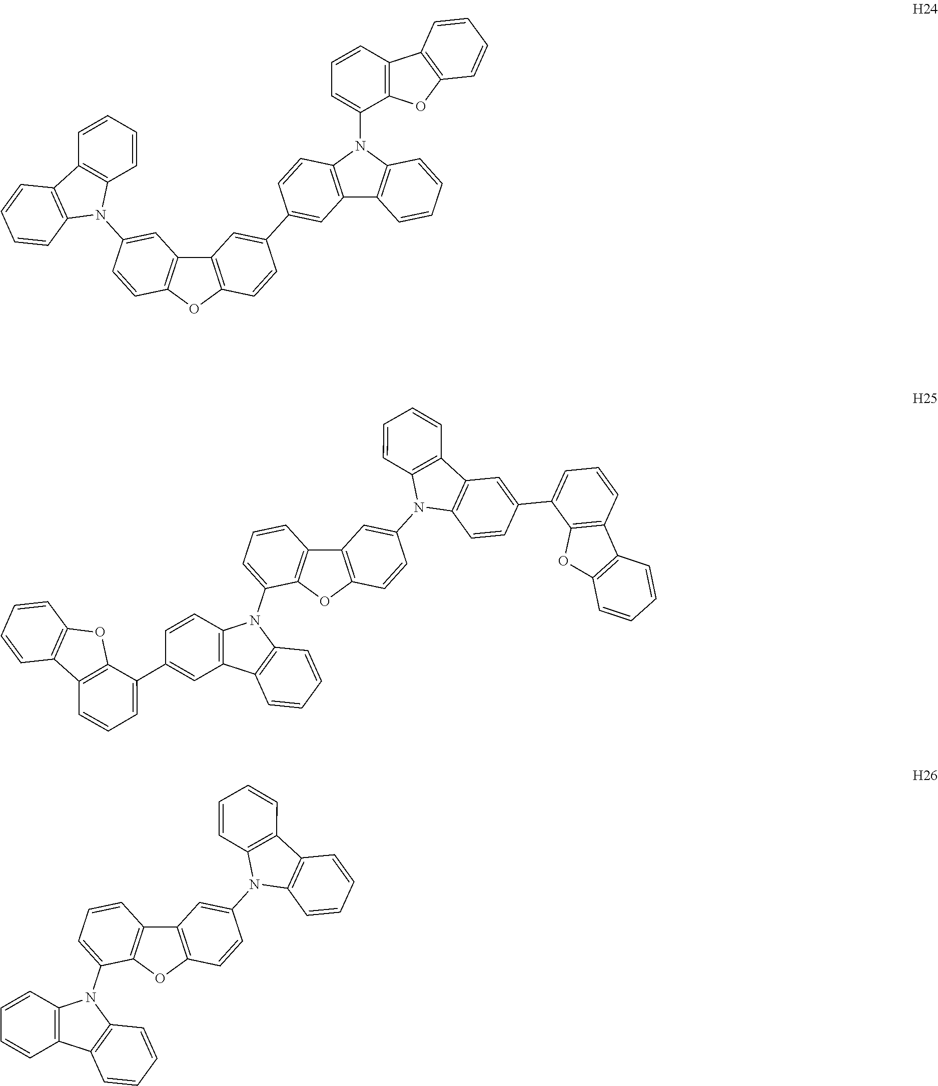 [SMILES: c1ccc2c(c1)oc1c(-n3c4ccccc4c4cc(-c5ccc6oc7ccc(-n8c9ccccc9c9ccccc98)cc7c6c5)ccc43)cccc12 ; c1ccc2c(c1)oc1c(-c3ccc4c(c3)c3ccccc3n4-c3ccc4oc5c(-n6c7ccccc7c7cc(-c8cccc9c8oc8ccccc89)ccc76)cccc5c4c3)cccc12 ; c1cc(-n2c3ccccc3c3ccccc32)c2oc3ccc(-n4c5ccccc5c5ccccc54)cc3c2c1]

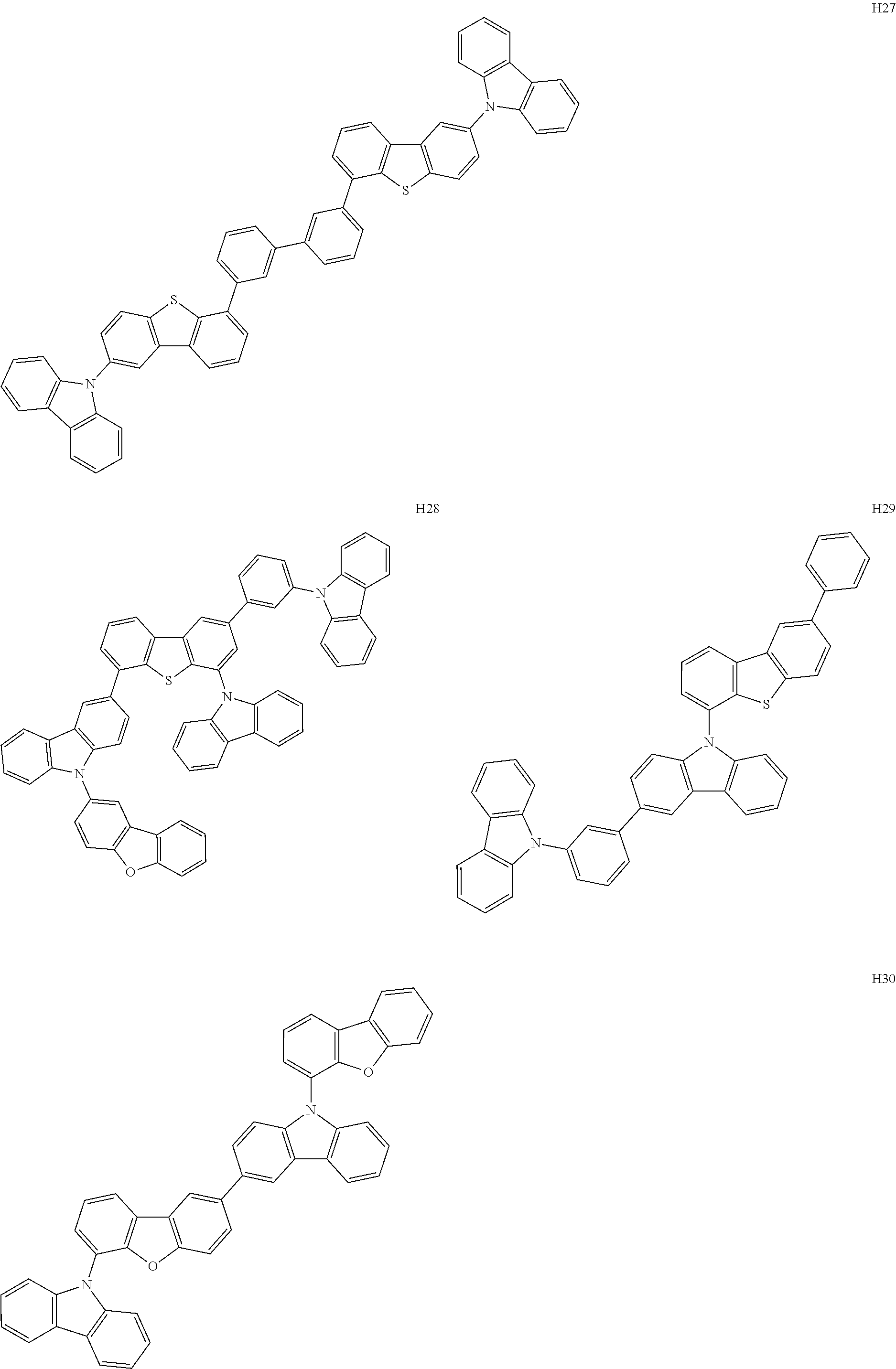 [SMILES: c1cc(-c2cccc(-c3cccc4c3sc3ccc(-n5c6ccccc6c6ccccc65)cc34)c2)cc(-c2cccc3c2sc2ccc(-n4c5ccccc5c5ccccc54)cc23)c1 ; c1cc(-c2cc(-n3c4ccccc4c4ccccc43)c3sc4c(-c5ccc6c(c5)c5ccccc5n6-c5ccc6oc7ccccc7c6c5)cccc4c3c2)cc(-n2c3ccccc3c3ccccc32)c1 ; c1ccc(-c2ccc3sc4c(-n5c6ccccc6c6cc(-c7cccc(-n8c9ccccc9c9ccccc98)c7)ccc65)cccc4c3c2)cc1 ; c1ccc2c(c1)oc1c(-n3c4ccccc4c4cc(-c5ccc6oc7c(-n8c9ccccc9c9ccccc98)cccc7c6c5)ccc43)cccc12]

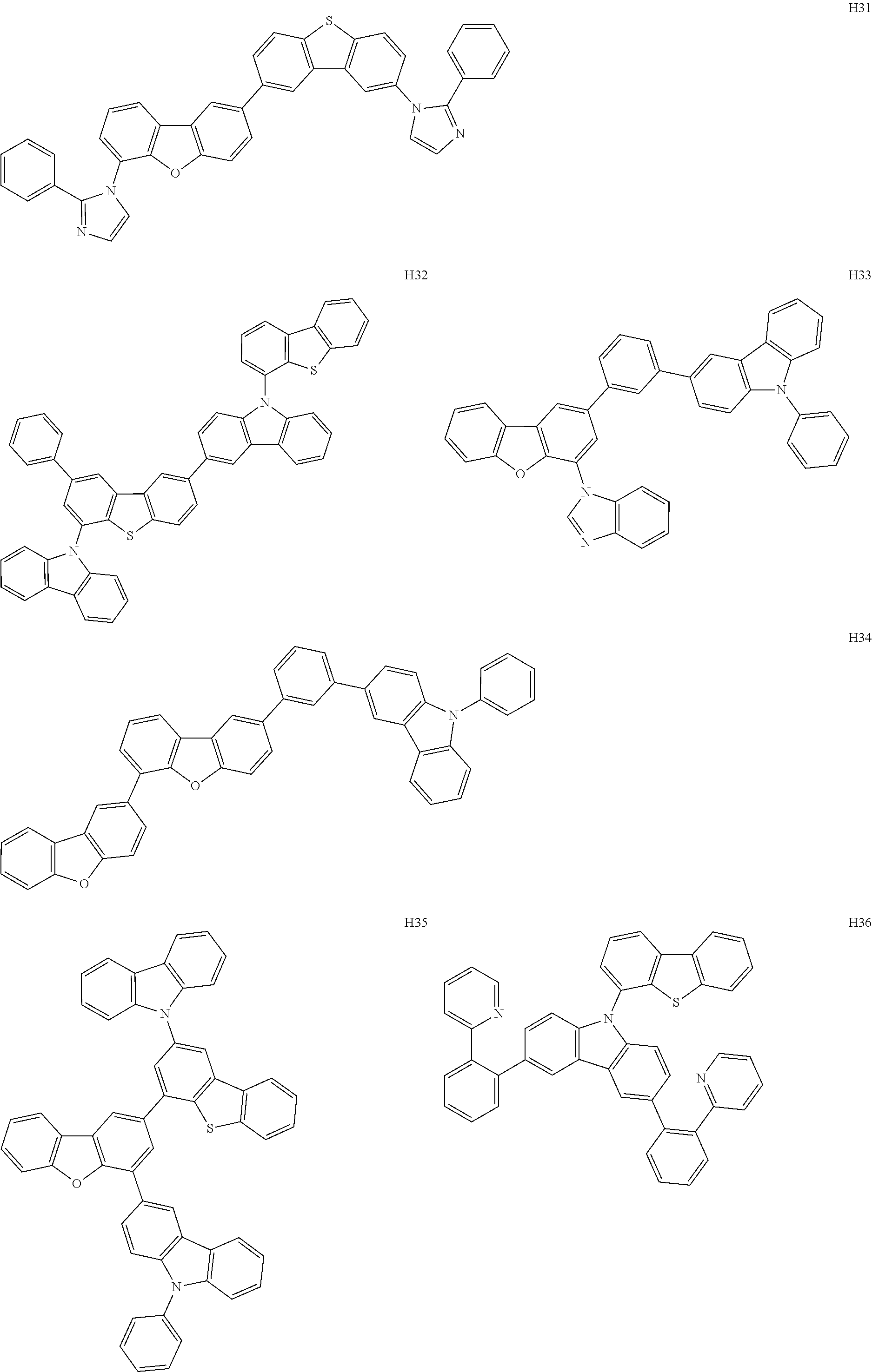

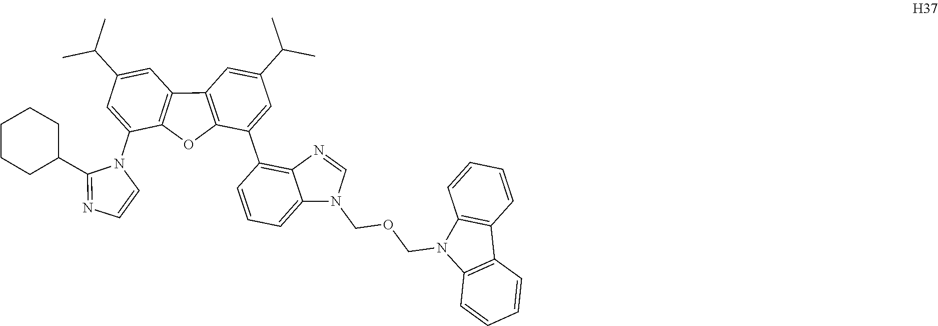 [SMILES: CC(C)c1cc(-c2cccc3c2ncn3COCn2c3ccccc3c3ccccc32)c2oc3c(-n4ccnc4C4CCCCC4)cc(C(C)C)cc3c2c1]

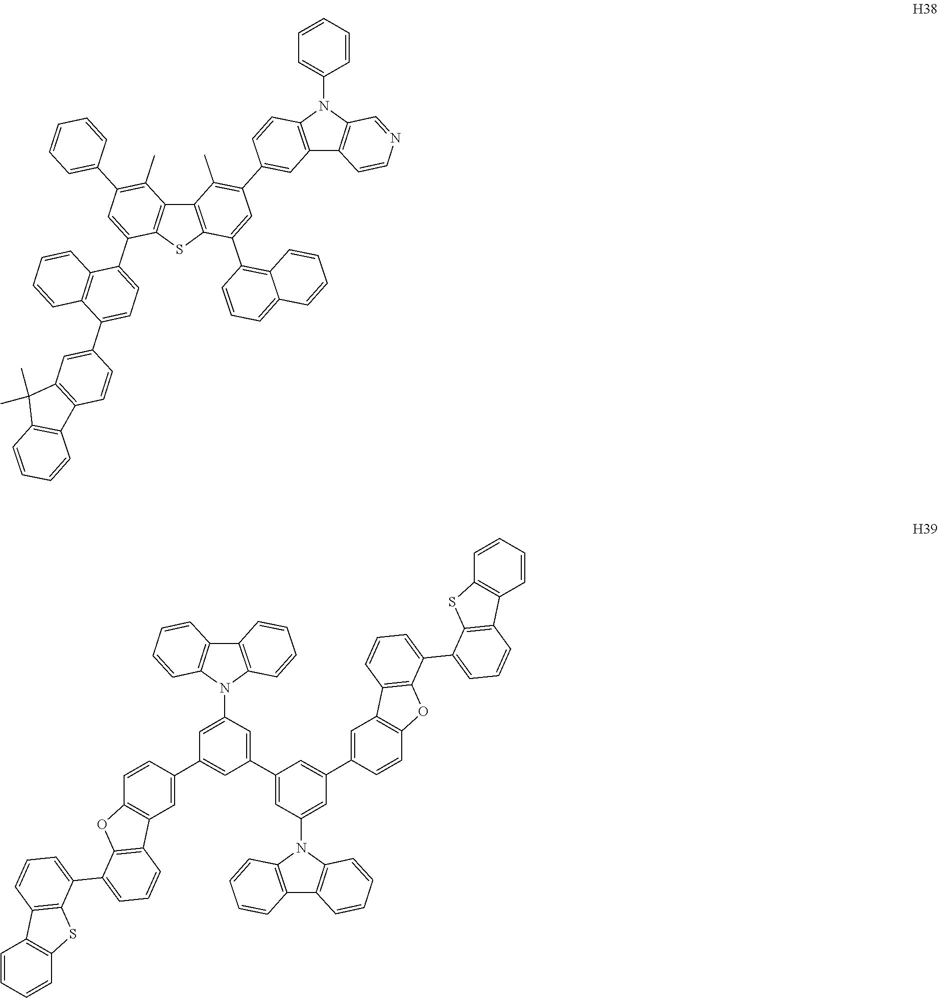 [SMILES: Cc1c(-c2ccc3c(c2)c2ccncc2n3-c2ccccc2)cc(-c2cccc3ccccc23)c2sc3c(-c4ccc(-c5ccc6c(c5)C(C)(C)c5ccccc5-6)c5ccccc45)cc(-c4ccccc4)c(C)c3c12 ; c1ccc2c(c1)sc1c(-c3cccc4c3oc3ccc(-c5cc(-c6cc(-c7ccc8oc9c(-c%10cccc%11c%10sc%10ccccc%10%11)cccc9c8c7)cc(-n7c8ccccc8c8ccccc87)c6)cc(-n6c7ccccc7c7ccccc76)c5)cc34)cccc12]

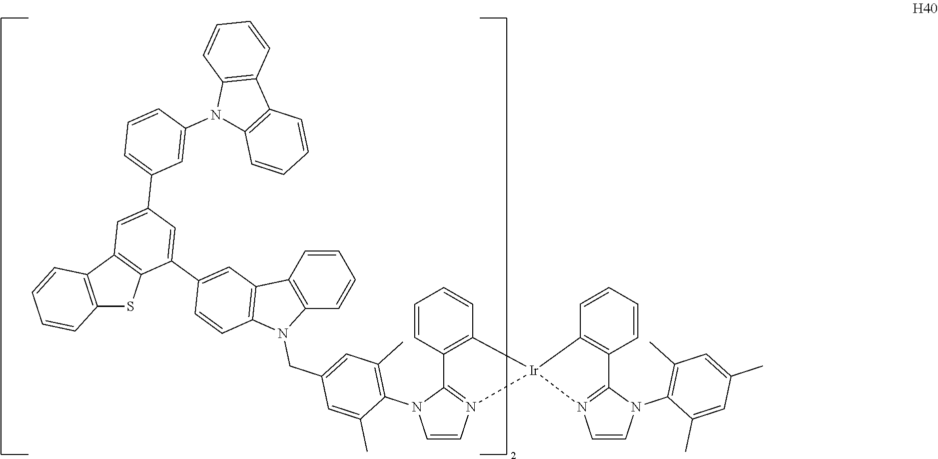

As specific examples of a known host compound used in an organic EL element of the present invention, the compounds described in the following Documents are cited. However, the present invention is not to them.

Japanese patent application publication (JP-A) Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837; US Patent Application Publication (US) Nos. 2003/0175553, 2006/0280965, 2005/0112407, 2009/0017330, 2009/0030202, 2005/0238919; WO 2001/039234, WO 2009/021126, WO 2008/056746, WO 2004/093 207, WO 2005/089025, WO 2007/063796, WO 2007/063754, WO 2004/107822, WO 2005/030900, WO 2006/114966, WO 2009/086028, WO 2009/003898, WO 2012/023947, JP-A2008-074939, JP-A2007-254297, and EP 2034538. Further, the compounds H-1 to H-230 described in paragraphs [0255] to [0293] of JP-A No. 2015-38941 can also be suitably used.

It is preferable that the host compound used in the present invention is contained within the range of 20 mass % or more in the organic functional layer from the viewpoint of suppression of aggregation of the phosphorescent complex and the fluorescent compound.

### <<Constitution Layers of Organic EL Element>>

Representative element constitutions used for an organic EL element of the present invention are as follows, however, the present invention is not limited to these.
(1) Anode/light emitting layer/cathode
(2) Anode/light emitting layer/electron transport layer/cathode
(3) Anode/hole transport layer/light emitting layer/cathode
(4) Anode/hole transport layer/light emitting layer/electron transport layer/cathode
(5) Anode/hole transport layer/light emitting layer/electron transport layer/electron injection layer/cathode
(6) Anode/hole injection layer/hole transport layer/light emitting layer/electron transport layer/cathode
(7) Anode/hole injection layer/hole transport layer/(electron blocking layer/) light emitting layer/(hole blocking layer/) electron transport layer/electron injection layer/cathode

Among these, the embodiment (7) is preferably used. However, the present invention is not limited to this.

The light emitting layer of the present invention is composed of one or a plurality of layers. When a plurality of layers are employed, it may be placed a non-light emitting intermediate layer between the light emitting layers.

According to necessity, it may be provided with a hole blocking layer (it is also called as a hole barrier layer) or an electron injection layer (it is also called as a cathode buffer layer) between the light emitting layer and the cathode. Further, it may be provided with an electron blocking layer (it is also called as an electron barrier layer) or an hole injection layer (it is also called as an anode buffer layer) between the light emitting layer and the anode.

An electron transport layer according to the present invention is a layer having a function of transporting an electron. An electron transport layer includes an electron injection layer, and a hole blocking layer in a broad sense. Further, an electron transport layer unit may be composed of plural layers.

A hole transport layer according to the present invention is a layer having a function of transporting a hole. A hole transport layer includes a hole injection layer, and an electron blocking layer in a broad sense. Further, a hole transport layer unit may be composed of plural layers.

### (Tandem Structure)

An organic EL element of the present invention may be so-called a tandem structure element in which plural light emitting units each containing at least one light emitting are laminated.

A representative example of an element constitution having a tandem structure is as follows.

A node/first light emitting unit/second light emitting unit/third light emitting unit/cathode; and

A node/first light emitting unit/intermediate layer/second light emitting unit/intermediate layer/third light emitting unit/cathode.

Here, the above-described first light emitting unit, second light emitting unit, and third light emitting unit may be the same or different. It may be possible that two light emitting units are the same and the remaining one light emitting unit is different.

In addition, the third light emitting unit may not be provided. Otherwise, a further light emitting unit or a further intermediate layer may be provided between the third light emitting unit and the electrode.

The plural light emitting units each may be laminated directly or they may be laminated through an intermediate layer. Examples of an intermediate layer are: an intermediate electrode, an intermediate conductive layer, a charge generating layer, an electron extraction layer, a connecting layer, and an intermediate insulating layer. Known composing materials may be used as long as it can form a layer which has a function of supplying an electron to an adjacent layer to the anode, and a hole to an adjacent layer to the cathode.

Examples of a material used in an intermediate layer are: conductive inorganic compounds such as ITO (indium tin oxide), IZO (indium zinc oxide), ZnO₂, TiN, ZrN, HfN, TiO_{X}, VO_{X}, CuI, InN, GaN, CuAlO₂, CuGaO₂, SrCu₂O₂, LaB₆, RuO₂, and Al; a two-layer film such as Au/Bi₂O₃; a multi-layer film such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerene such as C₆₀; and a conductive organic layer such as oligothiophene, metal phthalocyanine, metal-free phthalocyanine, metal porphyrin, and metal-free porphyrin. The present invention is not limited to them.

Examples of a preferable constitution in the light emitting unit are the constitutions of the above-described (1) to (7) from which an anode and a cathode are removed. However, the present invention is not limited to them.

Examples of a tandem type organic EL element are described in: U.S. Pat. Nos. 6,337,492, 7,420,203, 7,473,923, 6,872,472, 6,107,734, 6,337,492, WO 2005/009087, JP-A 2006-228712, JP-A 2006-24791, JP-A 2006-49393, JP-A 2006-49394, JP-A 2006-49396, JP-A 2011-96679, JP-A 2005-340187, JP Patent 4711424, JP Patent 3496681, JP Patent 3884564, JP Patent 4213169, JP-A 2010-192719, JP-A 2009-076929, JP-A 2008-078414, JP-A 2007-059848, JP-A 2003-272860, JP-A 2003-045676, and WO 2005/094130. The constitutions of the elements and the composing materials are described in these documents, however, the present invention is not limited to them.

Each layer that constitutes an organic EL element of the present invention will be described in the following.

### <<Organic Functional Layer>>

Organic functional layers that constitute an organic EL element of the present invention contains at least a light emitting layer. An organic functional layer other than the light emitting layer, for example, a hole injection layer, a hole transport layer, a blocking layer, an electron transport layer, or an electron injection layer is provided, when it is required. Each organic functional layer is laminated in the order of anode/hole injection layer/hole transport layer/electron blocking layer/light emitting layer/hole blocking layer/electron transport layer/electron injection layer/cathode.

Each organic functional layer will be described in the following.

### <<Light Emitting Layer>>

A light emitting layer used in the present invention is a layer which provide a place of emitting light via an exciton produce by recombination of electrons and holes injected from an electrode or an adjacent layer. The light emitting portion may be either within the light emitting layer or at an interface between the light emitting layer and an adjacent layer thereof.

The light emitting layer contains, as an organic compound, a host compound and a luminescent material (light emitting dopant).

In the light emitting layer containing the host compound and the luminescent material, arbitrary luminescent color can be obtained by appropriately adjusting the luminescence wavelength and type of the luminescent material.

The light emitting layer according to the present invention is formed by including the phosphorescent metal complex (core-shell type dopant) and the above-described fluorescent light emitting compound in any one of the light emitting layers.

However, as long as the effect of the present invention is not hindered, a phosphorescent light emitting dopant other than the core-shell type dopant may be further used for the light emitting layer according to the present invention. In addition, the above-described host compound can be used.

The total thickness of the light emitting layer is not particularly limited, but from the viewpoint of achieving homogeneity of the film to be formed and preventing application of unnecessary high voltage at the time of light emission and improvement of stability of luminescent color with respect to driving current, it is preferable to adjust in the range of 2 nm to 5 μm, more preferably in the range of 2 nm to 500 nm, and further preferably in the range of 5 to 200 nm.

In the present invention, the thickness of each light emitting layer is preferably adjusted in the range of 2 nm to 1 μm, more preferably adjusted in the range of 2 to 200 nm, further preferably in the range of 3 to 150 nm.

The light emitting layer used in the present invention may be a single layer or a plurality of layers.

In the present invention, it is also preferable that one or more light emitting layers (for example, a blue light emitting layer, a green light emitting layer, and a red light emitting layer) exhibit white light emission.

There is no particular limitation on the combination of luminescent dopants exhibiting white color, but a combination of blue and orange, and a combination of blue, green and red can be cited.

The light emitting layer according to the present invention is formed by including the phosphorescent metal complex (core-shell type dopant) and the above-described fluorescent light emitting compound in any one layer of the light emitting layers.

However, as long as the effect of the present invention is not hindered, a phosphorescent light emitting dopant other than the core-shell type dopant may be further used for the light emitting layer according to the present invention. In addition, the aforementioned fluorescent compounds and host compounds can be used.

### <Usable Phosphorescent Dopant>

A phosphorescent dopant may be suitably selected and employed from the known materials used for a light emitting layer for an organic EL element.

Examples of a known phosphorescent dopant are compounds described in the following publications.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US 2006/835469, US 2006/0202194, US 2007/0087321, US 2005/0244673, Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US 2002/0034656, U.S. Pat. No. 7,332,232, US 2009/0108737, US 2009/0039776, U.S. Pat. Nos. 6,921,915, 6,687,266, US 2007/0190359, US 2006/0008670, US 2009/0165846, US 2008/0015355, U.S. Pat. Nos. 7,250,226, 7,396,598, US 2006/0263635, US 2003/0138657, US 2003/0152802, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US 2006/0251923, US 2005/0260441, U.S. Pat. Nos. 7,393,599, 7,534,505, 7,445,855, US 2007/0190359, US 2008/0297033, U.S. Pat. No. 7,338,722, US 2002/0134984, and U.S. Pat. No. 7,279,704, US 2006/098120, US 2006/103874, WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, JP-A 2012-069737, JP Application No. 2011-181303, JP-A 2009-114086, JP-A 2003-81988, JP-A 2002-302671 and JP-A 2002-363552.

### <<Electron Transport Layer>>

An electron transport layer of the present invention is composed of a material having a function of transferring an electron. It is only required to have a function of transporting an injected electron from a cathode to a light emitting layer.

A total layer thickness of the electron transport layer is not specifically limited, however, it is generally in the range of 2 nm to 5 μm, and preferably, it is in the range of 2 to 500 nm, and more preferably, it is in the range of 5 to 200 nm.

In an organic EL element, it is known that there occurs interference between the light directly taken from the light emitting layer and the light reflected at the electrode located at the opposite side of the electrode from which the light is taken out at the moment of taking out the light which is produced in the light emitting layer. When the light is reflected at the cathode, it is possible to use effectively this interference effect by suitably adjusting the total thickness of the electron transport layer in the range of 5 nm to 1 μm.

On the other hand, the voltage will be increased when the layer thickness of the electron transport layer is made thick. Therefore, especially when the layer thickness is large, it is preferable that the electron mobility in the electron transport layer is 1×10⁻⁵ cm²/Vs or more.

As a material used for an electron transport layer (hereinafter, it is called as “an electron transport material”), it is only required to have either a property of ejection or transport of electrons, or a barrier to holes. Any of the conventionally known compounds may be selected and they may be employed.

Cited examples thereof include: a nitrogen-containing aromatic heterocyclic derivative (a carbazole derivative, an azacarbazole derivative (a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative); a dibenzofuran derivative, a dibenzothiophene derivative, a silole derivative; and an aromatic hydrocarbon ring derivative (a naphthalene derivative, an anthracene derivative and a triphenylene derivative).

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, a metal-free or metal phthalocyanine, or a compound whose terminal is substituted by an alkyl group or a sulfonic acid group, may be preferably utilized as an electron transport material. A distyryl pyrazine derivative, which is exemplified as a material for a light emitting layer, may be used as an electron transport material. Further, in the same manner as used for a hole injection layer and a hole transport layer, an inorganic semiconductor such as an n-type Si and an n-type SiC may be also utilized as an electron transport material.

A polymer material which is introduced these compounds in the polymer side-chain or a polymer main chain may be used.

In an electron transport layer according to the present invention, it is possible to employ an electron transport layer of a higher n property (electron rich) which is doped with impurities as a guest material. As examples of a dope material, listed are those described in each of JP-A Nos. 4-297076, 10-270172, 2000-196140, 2001-102175, as well as in J. Appl. Phys., 95, 5773 (2004).

Although the present invention is not limited thereto, preferable examples of a known electron transport material used in an organic EL element of the present invention are compounds described in the following publications.

U.S. Pat. Nos. 6,528,187, 7,230,107, US 2005/0025993, US 2004/0036077, US 2009/0115316, US 2009/0101870, US 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, JP-A 2010-251675, JP-A 2009-209133, JP-A 2009-124114, JP-A 2008-277810, JP-A 2006-156445, JP-A 2005-340122, JP-A 2003-45662, JP-A 2003-31367, JP-A 2003-282270, and WO 2012/115034.

Examples of a preferable electron transport material are: a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

An electron transport material may be used singly, or may be used in combination of plural kinds of compounds.

### <<Hole Blocking Layer>>

A hole blocking layer is a layer provided with a function of an electron transport layer in a broad meaning. Preferably, it contains a material having a function of transporting an electron, and having very small ability of transporting a hole. It will improve the recombination probability of an electron and a hole by blocking a hole while transporting an electron.

Further, a composition of an electron transport layer described above may be appropriately utilized as a hole blocking layer of the present invention when needed.

A hole blocking layer placed in an organic EL element of the present invention is preferably arranged at a location in the light emitting layer adjacent to the cathode side.

A thickness of a hole blocking layer according to the present invention is preferably in the range of 3 to 100 nm, and more preferably, in the range of 5 to 30 nm.

With respect to a material used for a hole blocking layer, the material used in the aforesaid electron transport layer is suitably used, and further, the material used as the aforesaid host compound is also suitably used for a hole blocking layer.

### <<Electron Injection Layer>>

An electron injection layer (it is also called as “a cathode buffer layer”) according to the present invention is a layer which is arranged between a cathode and a light emitting layer to decrease an operating voltage and to improve an emission luminance. An example of an electron injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

In the present invention, an electron injection layer is provided according to necessity, and as described above, it is placed between a cathode and a light emitting layer, or between a cathode and an electron transport layer.

An electron injection layer is preferably a very thin layer. The layer thickness thereof is preferably in the range of 0.1 to 5 nm depending on the materials used.

An election injection layer is detailed in JP-A

Nos. 6-325871, 9-17574, and 10-74586. Examples of a material preferably used in an election injection layer include: a metal such as strontium and aluminum; an alkaline metal compound such as lithium fluoride, sodium fluoride, or potassium fluoride; an alkaline earth metal compound such as magnesium fluoride; a metal oxide such as aluminum oxide; and a metal complex such as lithium 8-hydroxyquinolate (Liq). It is possible to use the aforesaid electron transport materials.

The above-described materials may be used singly or plural kinds may be used together in an election injection layer.

### <<Hole Transport Layer>>

In the present invention, a hole transport layer contains a material having a function of transporting a hole. A hole transport layer is only required to have a function of transporting a hole injected from an anode to a light emitting layer.

The total layer thickness of a hole transport layer of the present invention is not specifically limited, however, it is generally in the range of 5 nm to 5 μm, preferably in the range of 2 to 500 nm, and more preferably in the range of 5 nm to 200 nm.

A material used in a hole transport layer (hereinafter, it is called as “a hole transport material”) is only required to have any one of properties of injecting and transporting a hole, and a barrier property to an electron. A hole transport material may be suitably selected from the conventionally known compounds.

Examples of a hole transport material include:
a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer containing an aromatic amine in a side chain or a main chain, polysilane, and a conductive polymer or an oligomer (e.g., PEDOT:PSS, an aniline type copolymer, polyaniline and polythiophene).

Examples of a triarylamine derivative include: a benzidine type represented by α-NPD, a star burst type represented by MTDATA, a compound having fluorenone or anthracene in a triarylamine bonding core.

A hexaazatriphenylene derivative described in JP-A Nos. 2003-519432 and 2006-135145 may be also used as a hole transport material.

In addition, it is possible to employ an electron transport layer of a higher p property which is doped with impurities. As its example, listed are those described in each of JP-A Nos. 4-297076, 2000-196140, and 2001-102175, as well as in J. Appl. Phys., 95, 5773 (2004).

Further, it is possible to employ so-called p-type hole transport materials, and inorganic compounds such as p-type Si and p-type SiC, as described in JP-A No. 11-251067, and J. Huang et al. reference (Applied Physics Letters 80 (2002), p. 139). Moreover, an orthometal compounds having Ir or Pt as a center metal represented by Ir(ppy)₃ are also preferably used.

Although the above-described compounds may be used as a hole transport material, preferably used are: a triarylamine derivative, a carbazole derivative, an indolocarbazole derivative, an azatriphenylene derivative, an organic metal complex, a polymer or an oligomer incorporated an aromatic amine in a main chain or in a side chain.

Specific examples of a known hole transport material used in an organic EL element of the present invention are compounds in the aforesaid publications and in the following publications. However, the present invention is not limited to them.

Examples of the publication are: Appl. Phys. Lett. 69, 2160(1996), J. Lumin. 72-74, 985(1997), Appl. Phys. Lett. 78, 673(2001), Appl. Phys. Lett. 90, 183503(2007), Appl. Phys. Lett. 51, 913(1987), Synth. Met. 87, 171(1997), Synth. Met. 91, 209(1997), Synth. Met. 111, 421(2000), SID Symposium Digest, 37, 923(2006), J. Mater. Chem. 3, 319(1993), Adv. Mater. 6, 677(1994), Chem. Mater. 15, 3148(2003), US 2003/0162053, US 2002/0158242, US 2006/0240279, US 2008/0220265, U.S. Pat. No. 5,061,569, WO 2007/002683, WO 2009/018009, EP 650955, US 2008/0124572, US 2007/0278938, US 2008/0106190, US 2008/0018221, WO 2012/115034, JP-A 2003-519432, JP-A 2006-135145, and U.S. patent application Ser. No. 13/585,981.

A hole transport material may be used singly or may be used in combination of plural kinds of compounds.

### <<Electron Blocking Layer>>

An electron blocking layer is a layer provided with a function of a hole transport layer in a broad meaning. Preferably, it contains a material having a function of

transporting a hole, and having very small ability of transporting an electron. It will improve the recombination probability of an electron and a hole by blocking an electron while transporting a hole.

Further, a composition of a hole transport layer described above may be appropriately utilized as an electron blocking layer of an organic EL element when needed.

An electron blocking layer placed in an organic EL element is preferably arranged at a location in the light emitting layer adjacent to the anode side.

A thickness of an electron blocking layer is preferably in the range of 3 to 100 nm, and more preferably, it is in the range of 5 to 30 nm.

With respect to a material used for an electron blocking layer, the material used in the aforesaid hole transport layer is suitably used, and further, the material used as the aforesaid host compound is also suitably used for an electron blocking layer.

### <<Hole Injection Layer>>

A hole injection layer (it is also called as “an anode buffer layer”) is a layer which is arranged between an anode and a light emitting layer to decrease an operating voltage and to improve an emission luminance. An example of a hole injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

A hole injection layer of the present invention is provided according to necessity, and as described above, it is placed between an anode and a light emitting layer, or between an anode and a hole transport layer.

A hole injection layer is also detailed in JP-A Nos. 9-45479, 9-260062 and 8-288069. As materials used in the hole injection layer, it is cited the same materials used in the aforesaid hole transport layer.

Among them, preferable materials are: a phthalocyanine derivative represented by copper phthalocyanine; a hexaazatriphenylene derivative described in JP-A Nos. 2003-519432 and 2006-135145; a metal oxide represented by vanadium oxide; a conductive polymer such as amorphous carbon, polyaniline (or called as emeraldine) and polythiophene; an orthometalated complex represented by tris(2-phenylpyridine) iridium complex; and a triarylamine derivative.

The above-described materials used in a hole injection layer may be used singly or plural kinds may be co-used.

### <<Other Additive>>

The above-described organic layer of the present invention may further contain other additive. Other additive may be added to the composition as an additive or may be contained as impurities of the constituent material.

Examples of an ingredient are: halogen elements such as bromine, iodine and chlorine, and a halide compound; and a compound, a complex and a salt of an alkali metal, an alkaline earth metal and a transition metal such as Pd, Ca and Na.

Although a content of an ingredient may be arbitrarily decided, preferably, it is 1,000 ppm or less based on the total mass of the layer containing the ingredient, more preferably, it is 500 ppm or less, and still more preferably, it is 50 ppm or less.

In order to improve a transporting property of an electron or a hole, or to facilitate energy transport of an exciton, the content of the ingredient is not necessarily within these range, and other range of content may be used.

### <<Anode>>

As an anode of an organic EL element, a metal having a large work function (4 eV or more, preferably, 4.5 eV or more), an alloy, and a conductive compound and a mixture thereof are utilized as an electrode substance.

Specific examples of an electrode substance are: metals such as Au, and an alloy thereof; transparent conductive materials such as CuI, indium tin oxide (ITO), SnO₂, and ZnO. Further, a material such as IDIXO (In₂O₃—ZnO), which may form an amorphous and transparent electrode, may also be used.

As for an anode, these electrode substances may be made into a thin layer by a method such as a vapor deposition method or a sputtering method; followed by making a pattern of a desired form by a photolithography method. Otherwise, when the requirement of pattern precision is not so severe (about 100 μm or more), a pattern may be formed through a mask of a desired form at the time of layer formation with a vapor deposition method or a sputtering method using the above-described material.

Alternatively, when a coatable substance such as an organic conductive compound is employed, it is possible to employ a wet film forming method such as a printing method or a coating method. When emitted light is taken out from the anode, the transmittance is preferably set to be 10% or more. A sheet resistance of the anode is preferably a few hundred Ω/sq or less.

Further, although a layer thickness of the anode depends on a material, it is generally selected in the range of 10 nm to 1 μm, and preferably in the range of 10 to 200 nm.

### <<Cathode>>

As a cathode, a metal having a small work function (4 eV or less) (it is called as an electron injective metal), an alloy, a conductive compound and a mixture thereof are utilized as an electrode substance. Specific examples of the aforesaid electrode substance includes: sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal. Among them, with respect to an electron injection property and durability against oxidation, preferable are: a mixture of election injecting metal with a second metal which is stable metal having a work function larger than the electron injecting metal. Examples thereof are: a magnesium/silver mixture, a magnesium/aluminum mixture, a magnesium/indium mixture, an aluminum/aluminum oxide (Al₂O₃) mixture, a lithium/aluminum mixture and aluminum.

A cathode may be made by using these electrode substances with a method such as a vapor deposition method or a sputtering method to form a thin film. A sheet resistance of the cathode is preferably a few hundred Ω/sq or less. A layer thickness of the cathode is generally selected in the range of 10 nm to 5 μm, and preferably in the range of 50 to 200 nm.

In order to transmit emitted light, it is preferable that one of an anode and a cathode of an organic EL element is transparent or translucent for achieving an improved luminescence.

Further, after forming a layer of the aforesaid metal having a thickness of 1 to 20 nm on the cathode, it is possible to prepare a transparent or translucent cathode by providing with a conductive transparent material described in the description for the anode thereon. By applying this process, it is possible to produce an element in which both an anode and a cathode are transparent.

### <<Support Substrate>>

A support substrate which may be used for an organic EL element of the present invention is not specifically limited with respect to types such as glass and plastics. Hereinafter, the support substrate may be also called as substrate body, substrate, substrate substance, or support. They may be transparent or opaque. However, a transparent support substrate is preferable when the emitting light is taken from the side of the support substrate. Support substrates preferably utilized includes such as glass, quartz and transparent resin film. A specifically preferable support substrate is a resin film capable of providing an organic EL element with a flexible property.

Examples of a resin film include: polyesters such as polyethylene terephthalate (PET) and polyethylene naphthalate (PEN), polyethylene, polypropylene, cellophane, cellulose esters and their derivatives such as cellulose diacetate, cellulose triacetate (TAC), cellulose acetate butyrate, cellulose acetate propionate (CAP), cellulose acetate phthalate, and cellulose nitrate, polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluororesin, Nylon, polymethyl methacrylate, acrylic resin, polyallylates and cycloolefin resins such as ARTON (trade name, made by JSR Co. Ltd.) and APEL (trade name, made by Mitsui Chemicals, Inc.).

On a surface of a resin film, it may be formed a film incorporating an inorganic or an organic compound or a hybrid film incorporating both compounds. Such a gas barrier layer is provided for the purpose of suppressing intrusion of substances causing deterioration of elements such as moisture and oxygen.

As materials that form a barrier film, employed may be those which retard penetration of moisture and oxygen, which deteriorate the element. For example, it is possible to employ silicon oxide, silicon dioxide, and silicon nitride. Further, in order to improve the brittleness of the aforesaid film, it is more preferable to achieve a laminated layer structure of inorganic layers and organic layers. The laminating order of the inorganic layer and the organic layer is not particularly limited, but it is preferable that both are alternatively laminated a plurality of times.

Barrier film forming methods are not particularly limited. Examples of employable methods include a vacuum deposition method, a sputtering method, a reactive sputtering method, a molecular beam epitaxy method, a cluster ion beam method, an ion plating method, a plasma polymerization method, a plasma CVD method, a laser CVD method, a thermal CVD method, and a coating method. Of these, specifically preferred is a method employing an atmospheric pressure plasma polymerization method, described in JP-A No. 2004-68143.

Examples of opaque support substrates include metal plates such aluminum or stainless steel films, opaque resin substrates, and ceramic substrates.

An external extraction quantum efficiency of light emitted by the organic EL element of the present invention is preferably 1% or more at a room temperature, but is more preferably 5% or more.

External extraction quantum efficiency (%)=(Number of photons emitted by the organic EL element to the exterior/Number of electrons fed to organic EL element)×100.

Further, it may be used simultaneously a color hue improving filter such as a color filter, or it may be used simultaneously a color conversion filter which convert emitted light color from the organic EL element to multicolor by employing fluorescent materials.

### <<Sealing>>

As sealing means employed in the present invention, listed may be, for example, a method in which sealing members, electrodes, and a support substrate are subjected to adhesion via adhesives. The sealing members may be arranged to cover the display region of an organic EL element, and may be a concave plate or a flat plate. Neither transparency nor electrical insulation is limited.

Specifically listed are glass plates, polymer plate-films, metal plate-films. Specifically, it is possible to list, as glass plates, soda-lime glass, barium-strontium containing glass, lead glass, aluminosilicate glass, borosilicate glass, barium borosilicate glass, and quartz. Further, listed as polymer plates may be polycarbonate, acryl, polyethylene terephthalate, polyether sulfide, and polysulfone. As a metal plate, listed are those composed of at least one metal selected from the group consisting of stainless steel, iron, copper, aluminum magnesium, nickel, zinc, chromium, titanium, molybdenum, silicon, germanium, and tantalum, or alloys thereof.

In the present invention, since it is possible to achieve a thin organic EL element, it is preferable to employ a polymer film or a metal film. Further, it is preferable that the polymer film has a water vapor permeability (WVTR) of 0.001×1 g/(m²·day) determined by the method based on JIS K 7129-1992 and an oxygen permeability (OTR) of 0.001×1 mL/(m²·day·atm) determined by the method based on JIS K 7126-1987, and. More preferably, the polymer film has WVTR in the range of 0.01×1 g/(m²·day) and OTR in the range of 0.01×1 mL/(m² day·atm).

Conversion of the sealing member into concave is carried out by employing a sand blast process or a chemical etching process.

In practice, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type UV curable epoxy resin adhesives.

In addition, since an organic EL element is occasionally deteriorated via a thermal process, preferred are those which enable adhesion and curing between a room temperature and 80° C. Further, desiccating agents may be dispersed into the aforesaid adhesives. Adhesives may be applied onto sealing portions via a commercial dispenser or printed on the same in the same manner as screen printing.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film. In this case, as materials that form the aforesaid film may be those which exhibit functions to retard penetration of moisture or oxygen which results in deterioration. For example, it is possible to employ silicon oxide, silicon dioxide, and silicon nitride.

Still further, in order to improve brittleness of the aforesaid film, it is preferable that a laminated layer structure is formed, which is composed of these inorganic layers and layers composed of organic materials. Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method.

It is preferable to inject a gas phase and a liquid phase material of inert gases such as nitrogen or argon, and inactive liquids such as fluorinated hydrocarbon or silicone oil into the space between the space formed with the sealing member and the display region of the organic EL element. Further, it is possible to form vacuum in the space. Still further, it is possible to enclose hygroscopic compounds in the interior of the space.

Examples of a hygroscopic compound include: metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). In sulfates, metal halides, and perchlorates, suitably employed are anhydrides. For sulfate salts, metal halides and perchlorates, suitably used are anhydrous salts.

### <<Protective Film and Protective Plate>>

On the aforesaid sealing film which interposes the organic layer and faces the support substrate or on the outside of the aforesaid sealing film, a protective or a protective plate may be arranged to enhance the mechanical strength of the element. Specifically, when sealing is achieved via the aforesaid sealing film, the resulting mechanical strength is not always high enough, therefore it is preferable to arrange the protective film or the protective plate described above. Usable materials for these include glass plates, polymer plate-films, and metal plate-films which are similar to those employed for the aforesaid sealing. However, from the viewpoint of reducing weight and thickness, it is preferable to employ a polymer film.

### <<Improving Method of Light Extraction>>

It is generally known that an organic EL element emits light in the interior of the layer exhibiting the refractive index (being about 1.6 to 2.1) which is greater than that of air, whereby only about 15% to 20% of light generated in the light emitting layer is extracted. This is due to the fact that light incident to an interface (being an interlace of a transparent substrate to air) at an angle of 0 which is at least critical angle is not extracted to the exterior of the element due to the resulting total reflection, or light is totally reflected between the transparent electrode or the light emitting layer and the transparent substrate, and light is guided via the transparent electrode or the light emitting layer, whereby light escapes in the direction of the element side surface.

Means to enhance the efficiency of the aforesaid light extraction include, for example: a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A No. 63-314795), a method in which a reflection surface is formed on the side of the element (JP-A No. 1-220394), a method in which a flat layer of a middle refractive index is introduced between the substrate and the light emitting body and an antireflection film is formed (JP-A No. 62-172691), a method in which a flat layer of a refractive index which is equal to or less than the substrate is introduced between the substrate and the light emitting body (JP-A No. 2001-202827), and a method in which a diffraction grating is formed between the substrate and any of the layers such as the transparent electrode layer or the light emitting layer (including between the substrate and the outside) (JP-A No. 11-283751).

In the present invention, it is possible to employ these methods while combined with the organic EL element of the present invention. Of these, it is possible to appropriately employ the method in which a flat layer of a refractive index which is equal to or less than the substrate is introduced between the substrate and the light emitting body and the method in which a diffraction grating is formed between any layers of a substrate, and a transparent electrode layer and a light emitting layer (including between the substrate and the outside space).

By combining these means, the present invention enables the production of elements which exhibit higher luminance or excel in durability.

When a low refractive index medium having a thickness, greater than the wavelength of light is formed between the transparent electrode and the transparent substrate, the extraction efficiency of light emitted from the transparent electrode to the exterior increases as the refractive index of the medium decreases.

As materials of the low refractive index layer, listed are, for example, aerogel, porous silica, magnesium fluoride, and fluorine based polymers. Since the refractive index of the transparent substrate is commonly about 1.5 to 1.7, the refractive index of the low refractive index layer is preferably approximately 1.5 or less. More preferably, it is 1.35 or less.

Further, thickness of the low refractive index medium is preferably at least two times of the wavelength in the medium. The reason is that, when the thickness of the low refractive index medium reaches nearly the wavelength of light so that electromagnetic waves escaped via evanescent enter into the substrate, effects of the low refractive index layer are lowered.

The method in which the interface which results in total reflection or a diffraction grating is introduced in any of the media is characterized in that light extraction efficiency is significantly enhanced. The above method works as follows. By utilizing properties of the diffraction grating capable of changing the light direction to the specific direction different from diffraction via so-called Bragg diffraction such as primary diffraction or secondary diffraction of the diffraction grating, of light emitted from the light entitling layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive index. The reason is as follows. Since light emitted in the light emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced.

However, by changing the refractive index distribution to a two-dimensional one, light, which travels to all directions, is diffracted, whereby the light extraction efficiency is enhanced.

A position to introduce a diffraction grating may be between any layers or in a medium (in a transparent substrate or a transparent electrode). However, a position near the organic light emitting layer, where light is generated, is preferable. In this case, the cycle of the diffraction grating is preferably from about ½ to 3 times of the wavelength of light in the medium. The preferable arrangement of the diffraction grating is such that the arrangement is two-dimensionally repeated in the form of a square lattice, a triangular lattice, or a honeycomb lattice.

### <<Light Collection Sheet>>

Via a process to arrange a structure such as a micro-lens array shape on the light extraction side of the organic EL element of the present invention or via combination with a so-called light collection sheet, light is collected in the specific direction such as the front direction with respect to the light emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 to 100 μm. When it is less than the lower limit, coloration occurs due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed may be, for example, A shaped stripes of an apex angle of 90 degrees and a pitch of 50 μm formed on a substrate, a shape in which the apex angle is rounded, a shape in which the pitch is randomly changed, and other shapes.

Further, in order to control the light radiation angle from the light emitting element, simultaneously employed may be a light diffusion plate-film. For example, it is possible to employ the diffusion film (LIGHT-UP), produced by Kimoto Co., Ltd.

<<Forming Method of Each Layer that Forms Organic EL Element>>

A method of forming each layer (a hole injection layer, a hole transport layer, an electron blocking layer, a light emitting layer, a hole blocking layer, an electron transport layer, and an electron injection layer) constituting the organic EL element used in the present invention will be described.

The forming method of each organic functional layer constituting the organic EL element used in the present invention is not particularly limited. They may be formed by using a known method such as a vacuum vapor deposition method and a wet method (it may be called as a wet process). Here, the organic functional layer is preferably a layer formed by a wet process. That is, it is preferable to prepare an organic EL element by a wet process. When an organic EL element is produced by a wet process, it is possible to obtain a uniform film (coating film) easily, and it is possible to produce effects such as difficulty in forming a pinhole. It should be noted that the film (coating film) here is in a state of being dried after coating by a wet process.

Examples of a wet process include: a spin coating method, a cast method, an inkjet method, a printing method, a die coating method, a blade coating method, a roll coating method, a spray coating method, a curtain coating method, and a LB method (Langmuir Blodgett method). From the viewpoint of getting a uniform thin layer with high productivity, preferable are method highly appropriate to a roll-to-roll method such as a die coating method, a roll coating method, an inkjet method, and a spray coating method.

Next, an organic material composition for producing an organic EL element of the present invention will be described.

Examples of a liquid medium to dissolve or to disperse materials according to the present invention include: ketones such as methyl ethyl ketone and cyclohexanone; aliphatic esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; organic solvents such as DMF and DMSO.

These will be dispersed with a dispersion method such as an ultrasonic dispersion method, a high shearing dispersion method and a media dispersion method.

A different film forming method may be applied to every organic layer. When a vapor deposition method is adopted for forming each layer, the vapor deposition conditions may be changed depending on the compounds used. Generally, the following ranges are suitably selected for the conditions, heating temperature of boat: 50 to 450° C., level of vacuum: 1×10⁻⁶ to 1×10⁻² Pa, vapor deposition rate: 0.01 to 50 mn/sec, temperature of substrate: −50 to 300° C., and layer thickness: 0.1 nm to 5 μm, preferably 5 to 200 nm.

From the viewpoint of the effect of the present invention, it is preferable that the organic material composition for producing the organic EL element of the present invention contains a phosphorescent metal complex and a fluorescent compound. It is preferable that the phosphorescent metal complex is a compound having a structure represented by Formula (1) and the phosphorescent metal complex satisfies the following Expression (a).

In addition, it is preferable that the organic material composition contains a phosphorescent metal complex and a fluorescent compound, the phosphorescent metal complex is a compound having a chemical structure represented by any one of the above-described Formulas (3) to (5), and the phosphorescent metal complex satisfies the above-described Expression (b).

Formation of each organic layer constituting the organic EL element of the present invention is preferably continuously carried out from a hole injection layer to a cathode with one time vacuuming. It may be taken out on the way, and a different layer forming method may be employed. In that case, the operation is preferably done under a dry inert gas atmosphere.

### <<Applications>>

It is possible to employ the organic EL element of the present invention as display devices, displays, and various types of light emitting sources.

Examples of light emitting sources include: lighting apparatuses (home lighting and car lighting), clocks, backlights for liquid crystals, sign advertisements, signals, light sources of light memory media, light sources of electrophotographic copiers, light sources of light communication processors, and light sources of light sensors. The present invention is not limited to them. It is especially effectively employed as a backlight of a liquid crystal display device and a lighting source.

If needed, the organic EL element of the present, invention may undergo patterning via a metal mask or an ink-jet printing method during film formation. When the patterning is carried out, only an electrode may undergo patterning, an electrode and a light emitting layer may undergo patterning, or all element layers may undergo patterning. During preparation of the element, it is possible to employ conventional methods.

### <<Display Device>>

Hereinafter, one example of a display device provided with an organic EL element of the present invention will be explained with reference to figures.

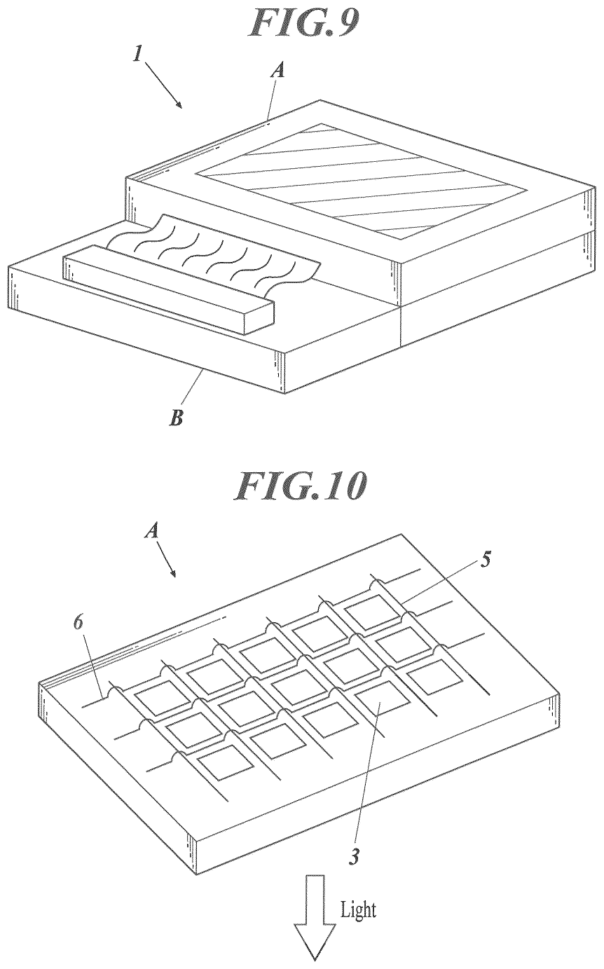

FIG. 9 is a schematic perspective drawing to show an example of a display device constituted of an organic EL element of the present invention. It displays image information by emission of an organic EL element. An example is a mobile phone.

As illustrated in FIG. 9, a display 1 is constituted of a display section A having plural number of pixels and a control section B which performs image scanning of the display section A based on image information.

The control section B, which is electrically connected to the display section A, sends a scanning signal and an image data signal to plural number of pixels based on image information from the outside and pixels of each scanning line

successively emit depending on the image data signal by a scanning signal to perform image scanning, whereby image information is displayed on the display section A.

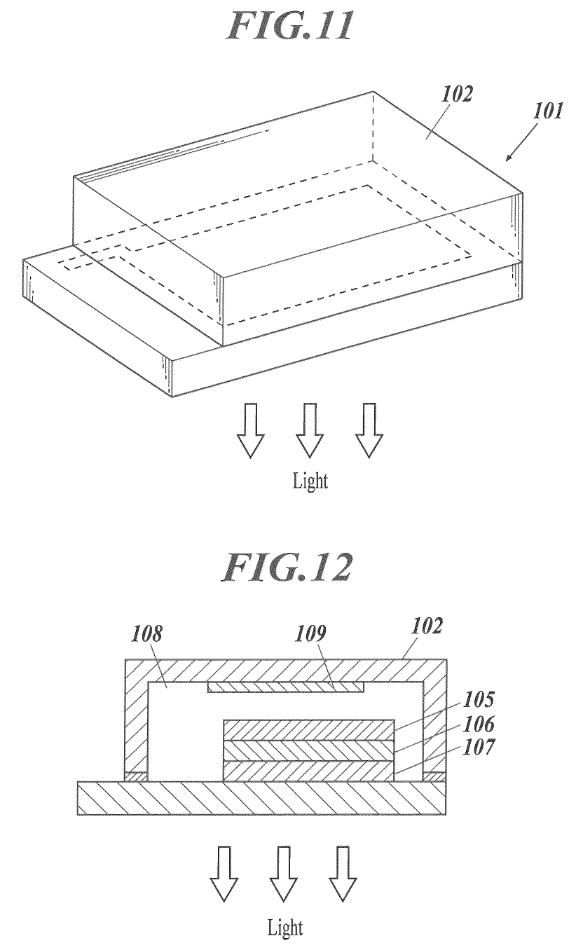

FIG. 10 is a schematic drawing of the display section A illustrated in FIG. 9.

The display section A is provided with a wiring part, which contains plural scanning lines 5 and data lines 6, and plural pixels 3 on a substrate.

Primary members of the display section A will be explained in the following.

In FIG. 10, it is illustrated the case that light emitted by a pixel 3 is taken out along a white arrow (downward). Scanning lines 5 and plural data lines 6 in a wiring part each are composed of a conductive material, and the scanning lines 5 and the data lines 6 are perpendicular in a grid form and are connected to the pixels 3 at the right-angled crossing points (details are not shown in the drawing).

The pixel 3 receives an image data from the data line 6 when a scanning signal is applied from the scanning line 5 and emits according to the received image data.

A full-color display device is achieved by appropriately arranging pixels each having an emission color in a red region, in a green region, and in a blue region, being placed side by side on the same substrate.

### <<Lighting Device>>

It will be described one of the embodiments of a lighting device provided with an organic EL element of the present invention.

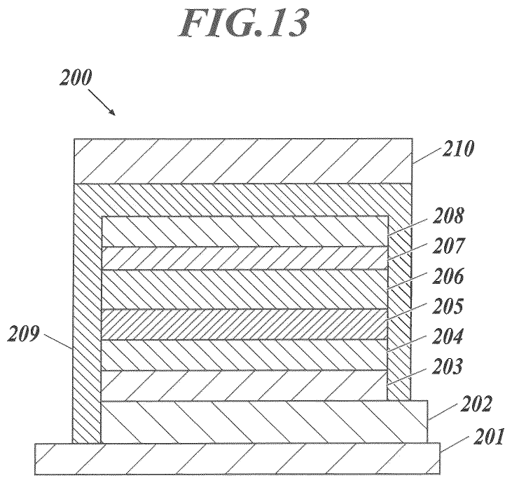

The non-light emitting surface of the organic EL element of the present invention was covered with a glass case, and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was superimposed on the aforesaid cathode to be brought into close contact with the aforesaid transparent support substrate, and curing and sealing were carried out via exposure of UV radiation onto the glass substrate side, whereby the lighting device shown in FIG. 11 and FIG. 12 was formed.

FIG. 11 is a schematic view of a lighting device. An organic EL element 101 of the present invention is covered with a glass cover 102 (incidentally, sealing by the glass cover was carried out in a globe box under nitrogen ambience (under air ambience of high purity nitrogen gas at a purity of at least 99.999%) so that the organic EL Element 101 was not brought into contact with atmosphere.

FIG. 12 is a cross-sectional view of a lighting device. In FIG. 12, 105 represents a cathode, 106 represents an organic EL layer, and 107 represents a glass substrate having a transparent electrode. Further, the interior of glass cover 102 is filled with nitrogen gas 108 and a water catching agent 109 is provided.

FIG. 13 is a cross-sectional view of a lighting device having an organic EL element produced by a wet process with a coating liquid using a flexible support substrate 201. As indicated in FIG. 13, an organic EL element 200 according to a preferred embodiment of the present invention has a flexible support substrate 201. An anode 202 is formed on the flexible support substrate 201, various organic functional layers indicated below are formed on the anode 202, and a cathode 208 is formed on the organic functional layer. The organic functional layers include, for example, a hole injection layer 203, a hole transport layer 204, a light emitting layer 205, an electron transport layer 206, and an electron injection layer 207. In addition, a hole blocking layer and an electron blocking layer may be ay be included. The anode 202, the organic functional layer, and the cathode 208 on the flexible support substrate 201 are sealed with a flexible sealing member 210 via a sealing adhesive 209.

The embodiments to which the present invention can be applied are not limited to the above-described embodiments, and can be appropriately changed without departing from the gist of the present invention.

For example, as an embodiment of the present invention, the following organic electroluminescence element may be used: an organic electroluminescent element comprising a light emitting layer between an anode and a cathode, wherein the light emitting layer contains a phosphorescence-emitting compound (phosphorescent metal complex) and a fluorescent compound; an emission spectrum of the phosphorescent compound and an absorption spectrum of the fluorescent compound have an overlap; the light emission-attenuation lifetime t of the light emitting layer single layer satisfies the following formula (A1); and an absolute quantum yield PLQE of the light emitting layer single layer satisfies the following expression (A2), and the phosphorescence emitting compound and the fluorescence emitting compound satisfy the following expression (A3) or the following expression (A4). Note that in a device using a conventional luminescent material alone, when driving an electric field under high luminance and high current density, in addition to an increase in roll-off (decrease in J₀) and an increase in the acceleration coefficient, the light emitting property is lowered, and further, the luminance half-life of the device is greatly reduced. In this embodiment, excitons generated by the phosphorescent compound are moved by Forster energy transfer to the fluorescent compound, so that the exciton may be instantaneously emitted as a light emission and may be deactivated, and furthermore, the roll-off suppression (increase in J₀) and increase in acceleration coefficient may be suppressed.

$$0 < τ / {τ}_{0} , \leq 0.7 \qquad Expression ( A1 )$$

$$0.6 \leq PLQE / {PLQE}_{0} \leq 1 \qquad Expression ( A2 )$$

$$HOMO ( F ) < HOMO ( P ) \qquad Expression ( A3 )$$

$$LUMO ( P ) < LUMO ( F ) \qquad Expression ( A4 )$$

τ: The light emission-attenuation lifetime of the light emitting layer single layer
τ₀: The light emission-attenuation lifetime of the single film of the phosphorescent compound
PLQE: Absolute quantum yield of the light emitting layer single layer
PLQE₀: Absolute quantum yield of the single film of the phosphorescent compound
HOMO(P) and LUMO(P): The highest occupied molecular orbital (HOMO) energy level and the lowest unoccupied molecular orbital (LUMO) energy level of the phosphorescent compound
HOMO(F) and LUMO(F): The highest occupied molecular orbital (HOMO) energy level and the lowest unoccupied molecular orbital (LUMO) energy level of the fluorescent compound

Note that the light emitting layer single layer refers to an evaluation thin film prepared as a spectrum measurement sample that includes a host compound, a phosphorescent compound, and a fluorescent compound. The specific production method of the thin film for evaluation will be described in detail in Examples.

The single film of the phosphorescent compound refers to a thin film containing the host compound and the phosphorescent compound among the evaluation films that contains the host compound, the phosphorescent compound and the fluorescent compound. Thus, the single film of the phosphorescent compound is a luminescent thin film for evaluation for evaluating τ/τ₀, φ/φ₀ according to the present invention without containing a fluorescent compound.

### Explanation of Expressions (A1) to (A4)

### Expression (A1)

It is known that the luminescent decay lifetime of the phosphorescent compound may be shortened by incorporating the phosphorescent compound and the fluorescent compound in the light emitting layer. A short emission-attenuation lifetime of the phosphorescent compound means that the triplet excitation energy of the phosphorescent compound is rapidly consumed.

The inventors of the present invention have found that the effect of lowering the acceleration coefficient of the luminance half-life of the organic EL element is noticeable when the reduction of the light emission decay lifetime (τ/τ₀) of the phosphorescent compound is 0.7 or less. In the present invention, as long as it is larger than 0, the smaller τ/τ₀ is, the better.

### Expression (A2)

Dexter type energy transfer occurs from the triplet excited state of the phosphorescent compound to the triplet excited state of the fluorescent compound by including the fluorescent compound in the phosphorescent compound. When Dexter type energy transfer occurs, the absolute quantum yield (that is, the absolute quantum yield PLQE of the light emitting layer single layer) decreases since it is deactivated by non-radiation from the triplet excited state of the fluorescent compound. However, in terms of the performance of the organic EL element, it is preferable that the absolute quantum yield PLQE of the light emitting layer single layer is high.

A practical phosphorescent compound has a high absolute quantum yield close to 100% (i.e., absolute quantum yield PLQE₀ of a single film of phosphorescent compound). Even when a fluorescent compound is added, it is desirable to suppress a decrease in absolute quantum yield due to Dexter type energy transfer and maintain a high absolute quantum yield. From the above viewpoint, when the PLQE/PLQE₀ is in the range of 0.6 to 1.0, the practical light emitting element performance may be more suitably maintained. Note that the maximum value of PLQE/PLQE₀ is 1 in the sense that PLQE₀ of phosphorescence alone is maintained (not reduced).

### Expression (A3) or Expression (A4)

When Expression (A3) or (A4) is satisfied, the charges do not directly recombine on the fluorescent compound and the decrease in the external extraction quantum efficiency (EQE) may be suppressed more preferably.

The light emission-attenuation lifetime may be measured by using a fluorescence lifetime measuring device (for example, a streak camera C4334 or a compact fluorescence lifetime measuring device C11367-03 (all manufactured by Hamamatsu Photonics K.K.)). Further, the light emission-attenuation lifetime to may be measured similarly for a thin film manufactured in the same manner as in the thin film in which the light emission-attenuation lifetime r is measured, except that the fluorescent compound is not contained.

LQE can be measured by using an absolute quantum yield measuring apparatus (for example, absolute quantum yield measuring apparatus C9920-02 (manufactured by Hamamatsu Photonics K.K.)). Further, the absolute quantum yield PLQE₀ may be measured similarly for a thin film manufactured in the same manner as in the thin film in which PLQE is measured, except that the fluorescent compound is not contained.

### EXAMPLES

Hereafter, the present invention will be described specifically by referring to examples, however, the present invention is not limited to them. In examples, the indication of “part” or “%” is used. Unless particularly mentioned, it represents “mass part” or “mass %”.

In the following, a thin film and an organic electroluminescent element according to the present invention will be described by exemplifying examples that satisfy the requirements of the present invention and comparative examples that do not.

### Reference Example 1

Prior to describing the present invention using Examples and Comparative Examples, first, in Reference Example 1, a phosphorescent metal complex assuming blue light emission is used, and the energy transfer rate (Kq) from the phosphorescent metal complex to the quenching substance was confirmed.

### <<Preparation of Evaluation Thin Film>>

A quartz substrate of 50 mm×50 mm having a thickness of 0.7 mm was subjected to ultrasonic washing with isopropyl alcohol, followed by drying with desiccated nitrogen gas, and was subjected to UV ozone washing for 5 minutes. The resulting transparent substrate was fixed to a substrate holder of a commercial vacuum deposition apparatus. In each of the vapor deposition heating boat of the vacuum vapor deposition apparatus, “a host”, “a phosphorescent metal complex”, or Q-1 as “a quenching substance” as indicated in Table 1 was filled so as to be an optimum amount for element fabrication.

After the inside of the vacuum deposition apparatus was evacuated to a degree of vacuum of 1×10⁻⁴ Pa, co-evaporation was performed so that the host, the phosphorescent metal complex and the quenching substance were 84 volume %, 15 volume %, and 1 volume %, respectively. In this way, a thin film for evaluation having a thickness of 30 nm was prepared.

### <Preparation of Comparative Thin Film>

The comparative thin film was prepared in the same manner as in the above “Preparation of Evaluation thin film” except that the quenching substance was not vapor-deposited (0 volume % of the quenching substance, the reduce amount of the quenching substance was changed with the host compound).

One comparative thin film was prepared for each evaluation thin film. (Specifically, the comparative thin film 1-1Ref was prepared without the quenching substance deposited on the evaluation thin film 1-1, and the comparative thin film 1-2Ref was prepared without the quenching substance deposited on the evaluation thin film 1-2.)

### <<Measurement of Luminescence Lifetime of Core-Shell Type Dopant>>

The luminescence lifetime (phosphorescence lifetime) of the luminescent metal complex of the evaluation thin film and the comparative thin film was determined by measuring transient PL characteristics. For measurement of transient PL characteristics, a compact fluorescence lifetime measuring device C11367-03 (manufactured by Hamamatsu Photonics K.K.) was used. The attenuation component was measured in TCC900 mode using a 340 nm LED as the excitation light source.

When the evaluation thin film 1-1 was measured in an oxygen-free state, the luminescence lifetime was 0.8 μs, whereas the luminescence lifetime of the comparative thin film 1-1-Ref was 1.6 μs. The quenching due to the energy transfer from the luminescent metal complex to the Q-1 occurs in part in the evaluation thin film 1-1 to which the quenching substance Q-1 is added. Therefore, it is inferred that the luminescence lifetime of the evaluation thin film 1-1 was shorter than the comparative thin film 1-1-Ref.

<Calculation of Energy Transfer Rate (Kq) from Phosphorescent Metal Complex to Quenching Substance>

The energy transfer rate (Kq) from the phosphorescent metal complex to the quenching substance was calculated based on the following numerical formula (SV2) obtained by modifying the above numerical formula (SV). The value of the luminescence lifetime (τ(with Quencher), hereinafter also referred to as “a light emission-attenuation lifetime”) of the luminescent metal complex of the evaluation thin film obtained by the above method and the value of luminescence lifetime of the luminescent metal complex of the comparative thin film (τ₀(without Quencher)) were substituting in the numerical formula (SV2) for calculation.

For the evaluation thin film, since the content of quenching substance is 1 volume %, 1 is substituted for [Q] and calculated.

$$\frac{PL ( with Quencher )}{PL 0 ( without Quencher )} = \frac{τ ( with Quencher )}{τ0 ( with Quencher )} = \frac{1}{1 + Kq \times [ Q ] \times τ0} \qquad Numerical formula ( SV2 )$$

In the numerical formula (SV2), PL (with Quencher) is the emission intensity in the presence of a quenching substance, PLO (without Quencher) is the emission intensity in the absence of a quenching substance, Kq is the energy transfer rate from the luminescent material to the quenching substance, [Q](=Kd×t) is the quenching substance concentration, Kd is the formation rate of the quenching substance due to aggregation and decomposition, t is the integrated excitation time by light or electric current, t is the phosphorescence lifetime of the luminescent material in the presence of a quenching substance, and to is the phosphorescence lifetime of the luminescent material in the absence of a quenching substance.

Kq of each evaluation thin film was calculated by the above method, and the relative ratio (Kq relative ratio) when Kq of the evaluation thin film 1-1 was set to be 1 was obtained.

<<Calculation of Vₐₗₗ/V_{core} Value>>

In calculating Vₐₗₗ/V_{core} value, Vₐₗₗ and V_{core} are as defined above. Then, Vₐₗₗ/V_{core} value was calculated by calculating Vₐₗₗ der Waals molecular volume of Vₐₗₗ and V_{core} by Winmostar (made by X-Ability Co., Ltd.) and dividing Vₐₗₗ by V_{core}.

For the various compounds used in the present examples ([Reference Example 1] to [Reference Example 5], and [Example 1] to [Example 8]), the following compounds were used in addition to the above-described compounds.

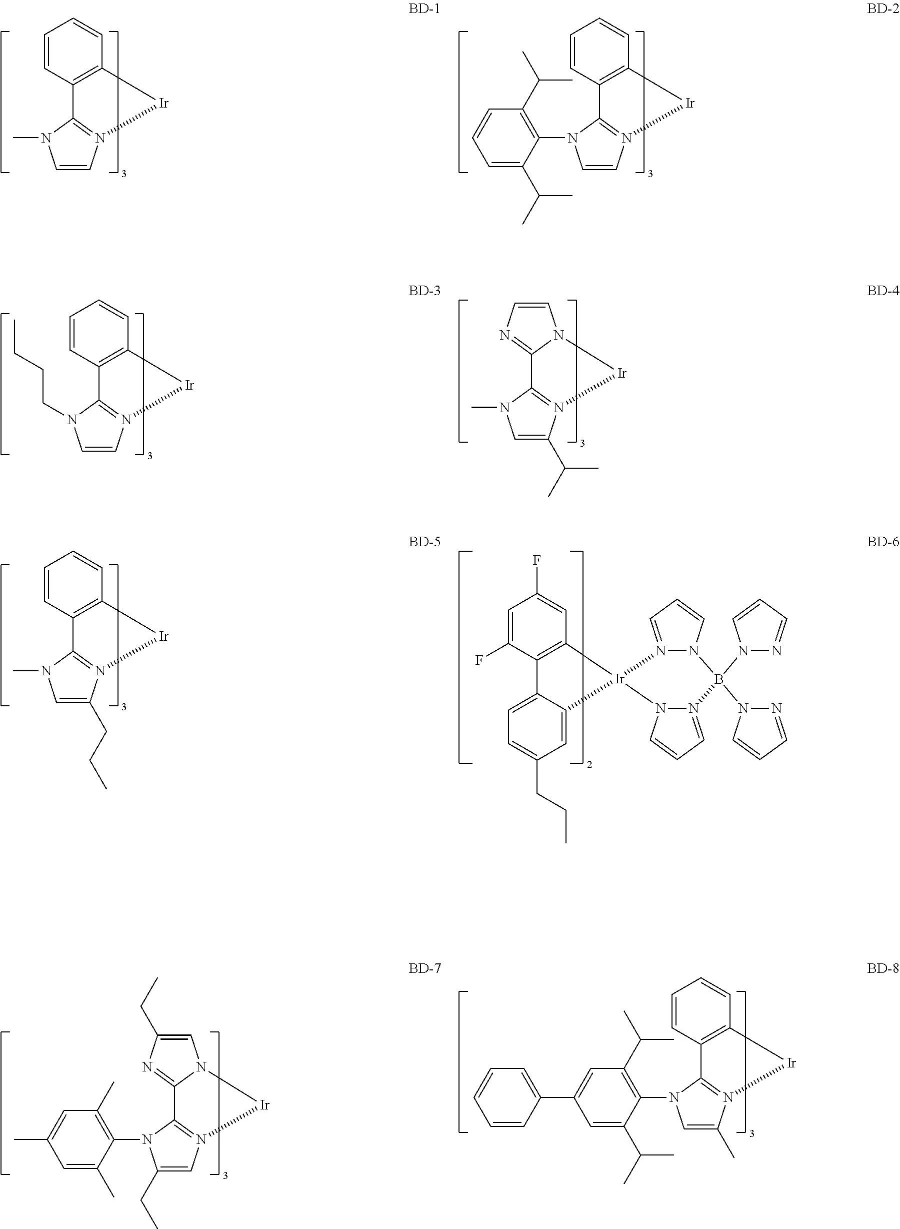

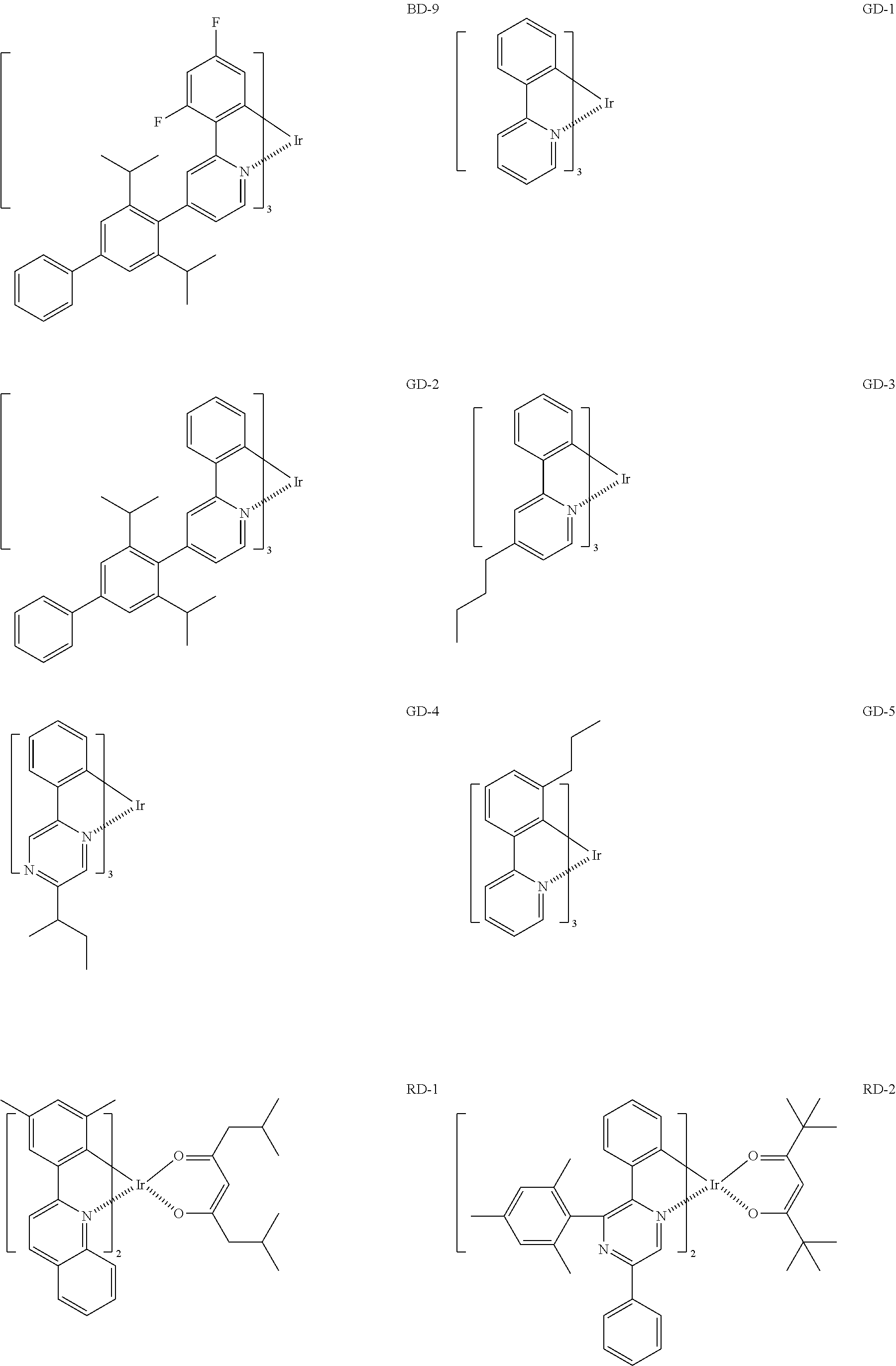

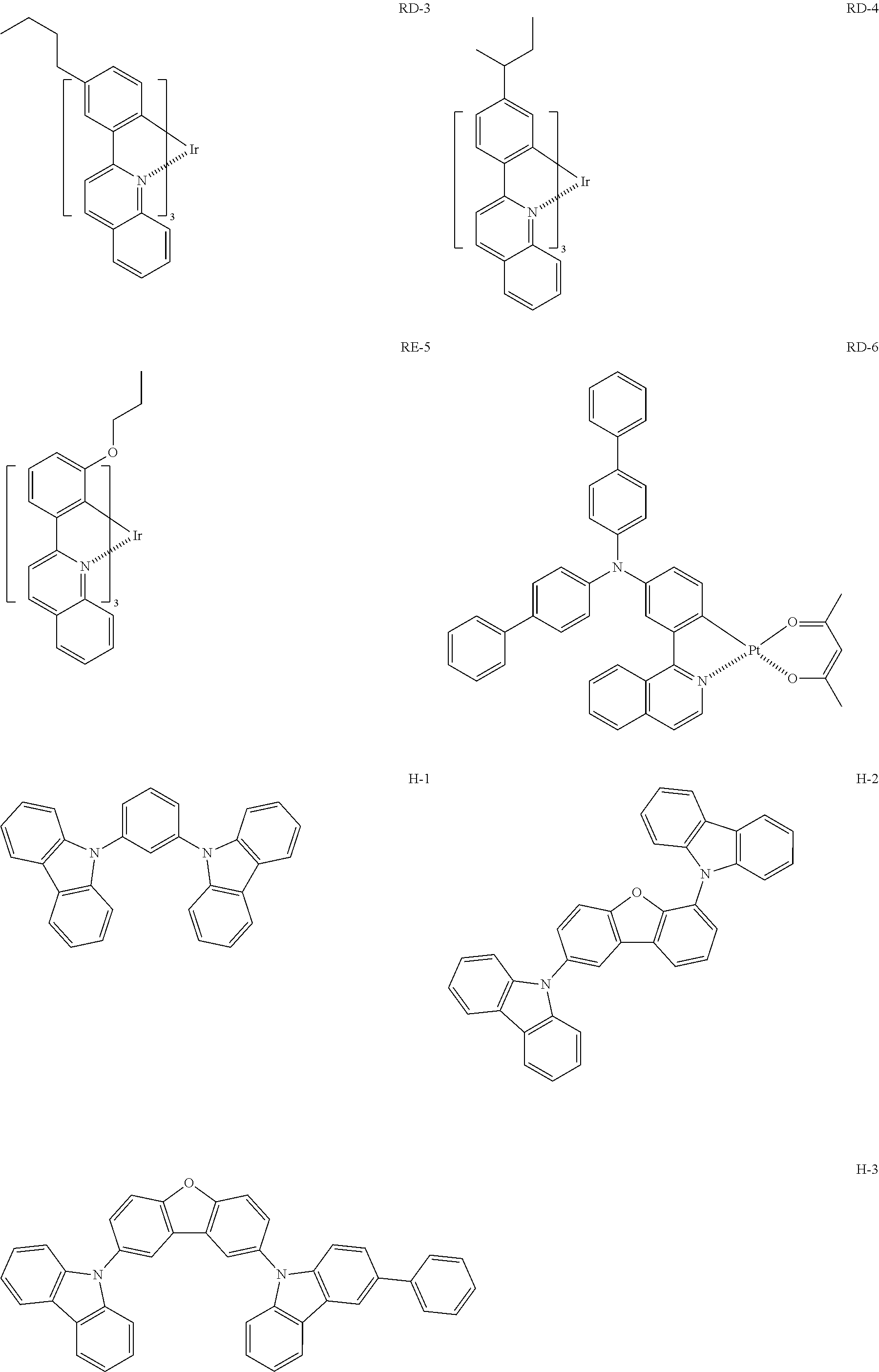

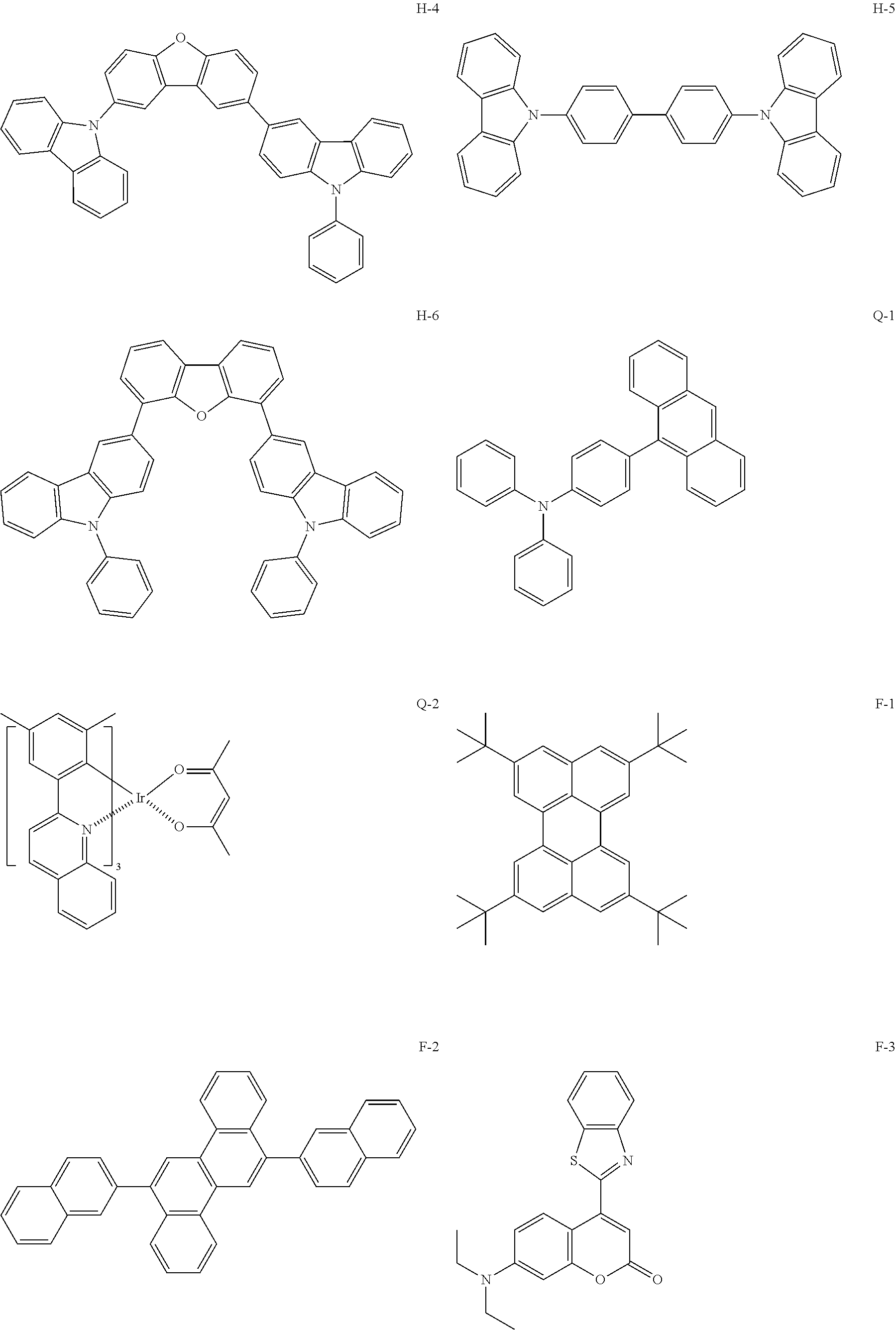

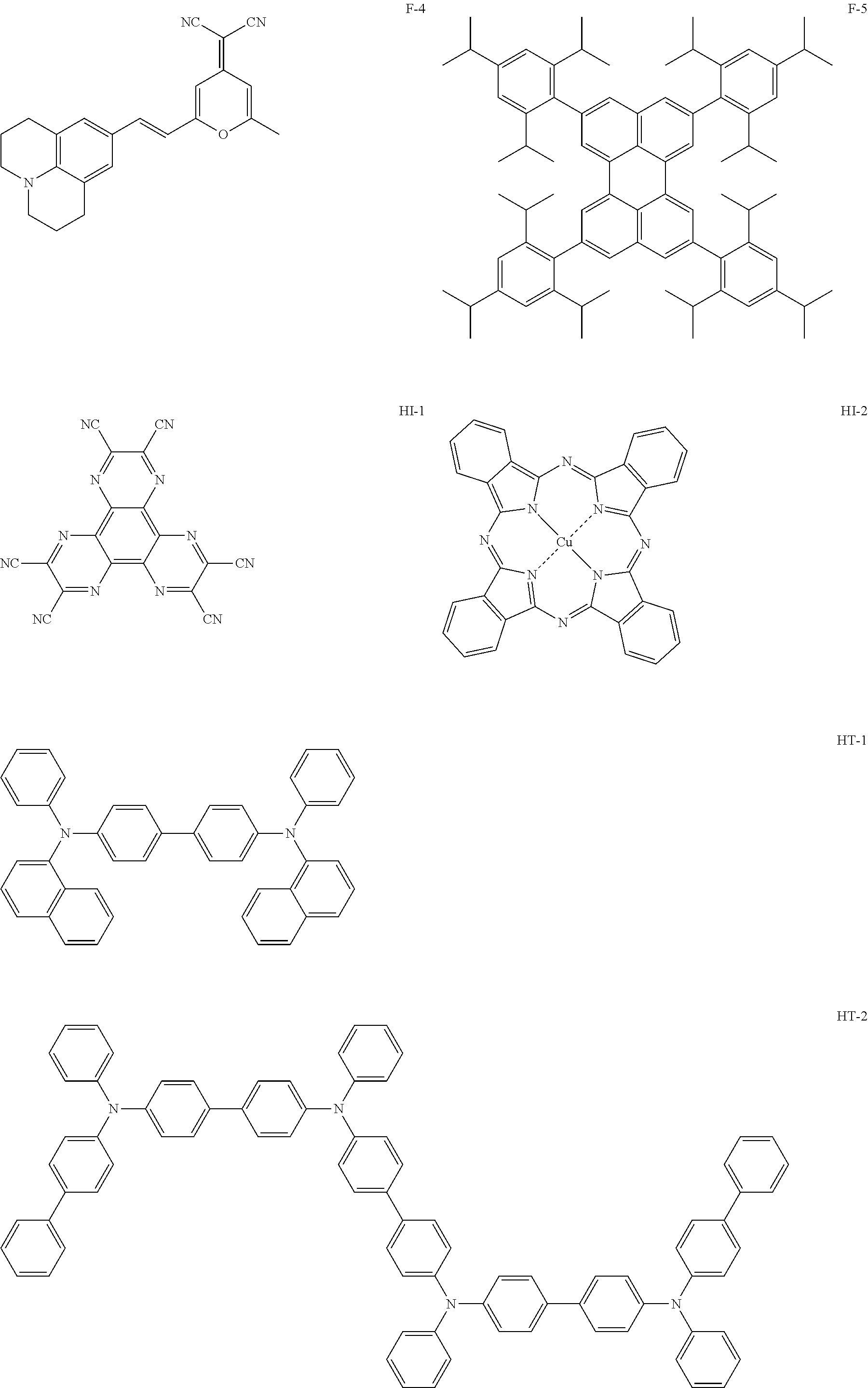

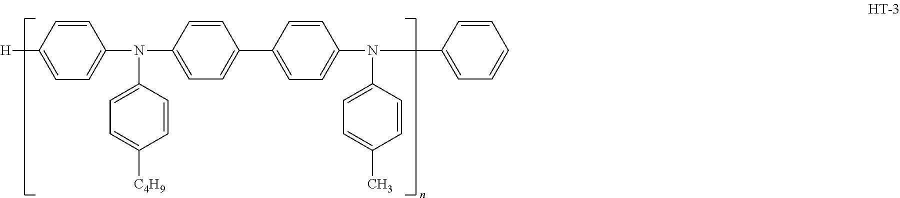

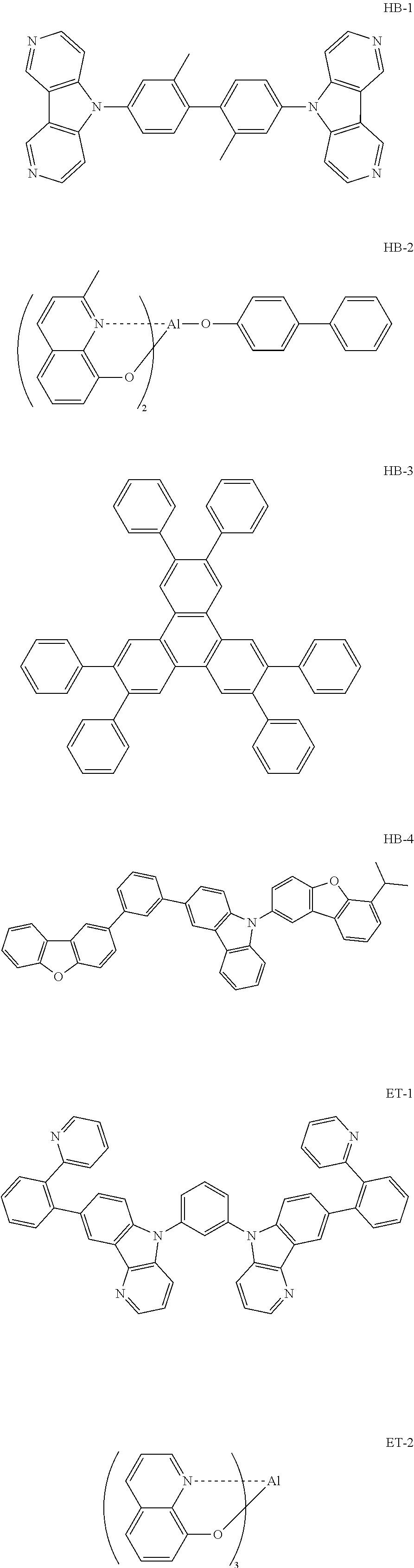

The results of each evaluation are listed in Table I below.

The host number and the dopant number in the table correspond to the numbers of the example compounds described above.

TABLE I

| | | Phosphorescent | | |
|---|---|---|---|---|
| Thin film | Host | metal | When Q-1 is added, | Vₐₗₗ/V_{core} |
| No. | No. | complex No. | Kq relative ratio | value |
| 1-1 | H-1 | BD-1 | 1.00 | 1.12 |
| 1-2 | H-1 | BD-2 | 1.06 | 2.15 |
| 1-3 | H-1 | BD-3 | 0.94 | 1.59 |
| 1-4 | H-1 | BD-4 | 0.92 | 1.53 |
| 1-5 | H-1 | BD-5 | 1.02 | 1.47 |
| 1-6 | H-1 | BD-6 | 0.99 | 1.40 |
| 1-7 | H-1 | BD-7 | 0.95 | 2.53 |
| 1-8 | H-1 | BD-8 | 0.91 | 2.78 |
| 1-9 | H-1 | BD-9 | 1.01 | 2.63 |
| 1-10 | H-1 | CD-1 | 0.76 | 2.70 |
| 1-11 | H-1 | CD-2 | 0.68 | 2.42 |
| 1-12 | H-1 | CD-3 | 0.71 | 2.52 |
| 1-13 | H-1 | CD-4 | 0.73 | 3.32 |
| 1-14 | H-1 | CD-5 | 0.62 | 2.30 |
| 1-15 | H-1 | CD-6 | 0.69 | 2.32 |
| 1-16 | H-1 | CD-7 | 0.70 | 2.09 |
| 1-17 | H-1 | CD-8 | 0.66 | 2.22 |

### Examination of Results: Reference Example 1

As indicated in Table I, for evaluation thin films 1-10 to 1-17, Vₐₗₗ/V_{core} of the dopant exceeds 2. In addition, they used a core-shell type phosphorescent metal complex having a chemical structure represented by Formula (1), Formula (3), Formula (4) or Formula (5) defined in the present invention. As a result, it was confirmed that the energy transfer from the luminescent metal complex to the quenching substance was suppressed and the Kq value (Kq relative ratio) was small.

### Reference Example 2

Next, in Reference Example 2, H-2 was used as a host. As in Reference Example 1, the energy transfer rate from the phosphorescent metal complex having the chemical structure represented by Formula (1) to the quenching substance was confirmed using a compound assumed to emit blue light.

### <Preparation of Evaluation Thin Film and Comparative Thin Film>

The evaluation thin film and the comparative thin film were prepared in the same manner as in Reference Example 1 except that “a host” and “a phosphorescent metal complex” indicated in Table II were used.

### <<Measurement and Calculation of Each Value>>

Measurement of the luminescent lifetime of the phosphorescent metal complex, calculation of the energy transfer rate (Kq relative ratio) from the phosphorescent metal complex to the quenching substance and calculation of Vₐₗₗ/V_{core} value were the same as in the case of Reference Example 1.

As for the Kq relative ratio, a relative ratio (Kq relative ratio) when Kq of the evaluation thin film 2-1 was set to be 1 was obtained. The evaluation results are listed in Table 11.

TABLE II

| | | Phosphorescent | | |
|---|---|---|---|---|
| Thin film | Host | metal | When Q-1 is added, | Vₐₗₗ/V_{core} |
| No. | No. | complex No. | Kq relative ratio | value |
| 2-1 | H-2 | BD-2 | 1.00 | 2.15 |
| 2-2 | H-2 | CD-1 | 0.79 | 2.70 |
| 2-3 | H-2 | CD-2 | 0.75 | 2.42 |
| 2-4 | H-2 | CD-3 | 0.77 | 2.52 |
| 2-5 | H-2 | CD-9 | 0.67 | 2.99 |
| 2-6 | H-2 | CD-10 | 0.65 | 2.29 |
| 2-7 | H-2 | CD-11 | 0.64 | 2.06 |
| 2-8 | H-2 | CD-12 | 0.62 | 3.34 |
| 2-9 | H-2 | CD-13 | 0.61 | 2.74 |
| 2-10 | H-2 | CD-14 | 0.66 | 2.15 |
| 2-11 | H-2 | CD-15 | 0.54 | 2.90 |
| 2-12 | H-2 | CD-16 | 0.51 | 2.41 |
| 2-13 | H-2 | CD-17 | 0.58 | 2.45 |
| 2-14 | H-2 | CD-18 | 0.49 | 2.75 |
| 2-15 | H-2 | CD-19 | 0.47 | 2.42 |
| 2-16 | H-2 | CD-20 | 0.50 | 2.58 |
| 2-17 | H-2 | CD-21 | 0.44 | 3.31 |
| 2-18 | H-2 | CD-22 | 0.52 | 2.82 |
| 2-19 | H-2 | CD-23 | 0.49 | 2.13 |
| 2-20 | H-2 | CD-24 | 0.42 | 2.64 |
| 2-21 | H-2 | CD-25 | 0.50 | 2.80 |
| 2-22 | H-2 | CD-26 | 0.51 | 2.42 |
| 2-23 | H-2 | CD-27 | 0.44 | 2.52 |

### Examination of Results: Reference Example 2

As indicated in Table II, for evaluation thin films 2-2 to 2-23, Vₐₗₗ/V_{core} of the phosphorescent metal complex exceeds 2. In addition, since they used a core-shell type phosphorescent metal complex according to the present invention, it was confirmed that a small Kq value (Kq relative ratio) was obtained by suppressing energy transfer from the luminescent metal complex to the quenching substance. In particular, when the evaluation thin film contained a compound in which L′ in Formula (2) was a non-conjugated linking group, or the evaluation thin film contained a compound in which the ligand represented by the ring Z₁ and the ring Z₂ having three or more substituents, it was confirmed that the evaluation thin film had a considerably small Kq value (Kq relative ratio).

### Reference Example 3

Next, in Reference Example 3, a compound assuming blue light emission was used, and the energy transfer rate from the phosphorescent metal complex (core-shell type dopant) according to the present invention to the quenching substance was confirmed.

### <<Preparation of Evaluation Thin Film and Comparative Thin Film>>

The evaluation thin film and the comparative thin film were prepared in the same manner as in Reference Example 1 except that “the host” and “the phosphorescent metal complex” indicated in Table III were used, Q-2 was used as “a quenching substance”, and the quenching substance was set to 0.1 volume % (the reduce amount of the quenching substance was changed with the host compound).

### <Measurement and Calculation of Each Value>

Measurement of the luminescent lifetime of the phosphorescent metal complex, calculation of the energy transfer rate (Kq relative ratio) from the phosphorescent metal complex to the quenching substance and calculation of Vₐₗₗ/V_{core} value were the same as in the case of Reference Example 1

As for the Kq relative ratio, a relative ratio (Kq relative ratio) when Kq of the evaluation thin film 3-1 was set to be 1 was obtained. The evaluation results are listed in Table III.

TABLE III

| | | Phosphorescent | | |
|---|---|---|---|---|
| Thin film | Host | metal | When Q-2 is added, | Vₐₗₗ/V_{core} |
| No. | No. | complex No. | Kq relative ratio | value |
| 3-1 | H-3 | BD-5 | 1.00 | 1.47 |
| 3-2 | H-3 | CD-4 | 0.73 | 3.32 |
| 3-3 | H-3 | CD-5 | 0.69 | 2.30 |
| 3-4 | H-3 | CD-7 | 0.69 | 2.09 |
| 3-5 | H-3 | CD-28 | 0.57 | 3.08 |
| 3-6 | H-3 | CD-29 | 0.52 | 2.41 |
| 3-7 | H-3 | CD-30 | 0.55 | 2.24 |
| 3-8 | H-3 | CD-31 | 0.51 | 2.51 |
| 3-9 | H-3 | CD-32 | 0.49 | 2.20 |
| 3-10 | H-3 | CD-33 | 0.51 | 2.43 |
| 3-11 | H-3 | CD-34 | 0.52 | 2.78 |
| 3-12 | H-3 | CD-35 | 0.49 | 2.76 |
| 3-13 | H-3 | CD-36 | 0.51 | 2.91 |
| 3-14 | H-3 | CD-37 | 0.50 | 2.43 |
| 3-15 | H-3 | CD-38 | 0.48 | 2.43 |
| 3-16 | H-3 | CD-39 | 0.49 | 2.39 |

### Examination of Results: Reference Example 3

As indicated in Table III, for evaluation thin films 3-2 to 3-16, Vₐₗₗ/V_{core} of the phosphorescent metal complex exceeds 2. In addition, since they used a phosphorescent metal complex according to the present invention (a core-shell type dopant), it was confirmed that a small Kq value (Kq relative ratio) was obtained by suppressing energy transfer from the phosphorescent metal complex to the quenching substance. In particular, when the evaluation thin film contained a compound in which the ligand represented by the ring Z₃ to the ring Z₈ having three or more substituents, it was confirmed that the evaluation thin film had a considerably small Kq value (Kq relative ratio).

### Reference Example 4

Next, in Reference Example 4, a compound assuming green light emission was used, and the energy transfer rate from the phosphorescent metal complex to the quenching substance was confirmed.

### <<Preparation of Evaluation Thin Film and Comparative Thin Film>>

The evaluation thin film and the comparative thin film were prepared in the same manner as in Reference Example 1 except that “a host” and “a phosphorescent metal complex” indicated in Table IV were used.

### <Measurement and Calculation of Each Value>

Measurement of the luminescent lifetime of the metal complex, calculation of the energy transfer rate (Kq relative ratio) from the phosphorescent metal complex to the quenching substance and calculation of Vₐₗₗ/V_{core} value were the same as in the case of Reference Example 1.

As for the Kq relative ratio, a relative ratio (Kq relative ratio) when Kq of the evaluation thin film 4-1 was set to be 1 was obtained. The evaluation results are listed in Table IV.

TABLE IV

| | | Phosphorescent | | |
|---|---|---|---|---|
| Thin film | Host | metal | When Q-1 is added, | Vₐₗₗ/V_{core} |
| No. | No. | complex No. | Kq relative ratio | value |
| 4-1 | H-4 | GD-1 | 1.00 | 1.00 |
| 4-2 | H-4 | GD-2 | 1.06 | 2.56 |
| 4-3 | H-4 | GD-3 | 0.89 | 1.44 |
| 4-4 | H-4 | GD-4 | 0.92 | 1.44 |
| 4-5 | H-4 | GD-5 | 1.02 | 1.30 |
| 4-6 | H-4 | CD-40 | 0.74 | 2.78 |
| 4-7 | H-4 | CD-41 | 0.75 | 2.20 |
| 4-8 | H-4 | CD-42 | 0.61 | 2.07 |
| 4-9 | H-4 | CD-43 | 0.63 | 2.94 |
| 4-10 | H-4 | CD-44 | 0.52 | 2.58 |
| 4-11 | H-4 | CD-45 | 0.51 | 2.64 |

### Examination of Results: Reference Example 4

As indicated in Table IV, for evaluation thin films 4-6 to 4-14, Vₐₗₗ/V_{core} of the phosphorescent metal complex exceeds 2. In addition, since they used a core-shell type phosphorescent metal complex having a chemical structure represented by the formula defined in the present invention, it was confirmed that a small Kq value (Kq relative ratio) was obtained as a thin film of green light emission by suppressing energy transfer from the phosphorescent metal complex to the quenching substance. In particular, when the evaluation thin film contained a compound in which L′ in Formula (2) was a non-conjugated linking group, or the evaluation thin film contained a compound in which the ligand represented by the ring Z₁ and the ring Z₂ having three or more substituents, it was confirmed that the evaluation thin film had a considerably small Kq value (Kq relative ratio).

### Reference Example 5

Next, in Reference Example 5, a compound assuming red light emission was used, and the energy transfer rate from the phosphorescent metal complex to the quenching substance was confirmed.

### <Preparation of Evaluation Thin Film and Comparative Thin Film>

The evaluation thin film and the comparative thin film were prepared in the same manner as in Reference Example 1 except that “the host” and “the phosphorescent metal complex” indicated in Table V were used.

### <Measurement and Calculation of Each Value>

Measurement of the luminescent lifetime of the phosphorescent metal complex, calculation of the energy transfer rate (Kq relative ratio) from the phosphorescent metal complex to the quenching substance and calculation of Vₐₗₗ/V_{core} value were the same as in the case of Reference Example 1.

As for the Kq relative ratio, a relative ratio (Kq relative ratio) when Kq of the evaluation thin film 5-1 was set to be 1 was obtained. The evaluation results are listed in Table V.

TABLE V

| | | Phosphorescent | | |
|---|---|---|---|---|
| Thin film | Host | metal | When Q-1 is added, | Vₐₗₗ/V_{core} |
| No. | No. | complex No. | Kq relative ratio | value |
| 5-1 | H-5 | RD-1 | 1.00 | 1.15 |
| 5-2 | H-5 | RD-2 | 1.01 | 2.24 |
| 5-3 | H-5 | RD-3 | 0.99 | 1.34 |
| 5-4 | H-5 | RD-4 | 0.97 | 1.33 |
| 5-5 | H-5 | RD-5 | 1.00 | 1.30 |
| 5-6 | H-5 | RD-6 | 0.97 | 1.77 |
| 5-7 | H-5 | CD-46 | 0.71 | 2.20 |
| 5-8 | H-5 | CD-47 | 0.68 | 2.27 |
| 5-9 | H-5 | CD-48 | 0.59 | 2.02 |
| 5-10 | H-5 | CD-49 | 0.57 | 2.08 |
| 5-11 | H-5 | CD-50 | 0.58 | 2.07 |

### Examination of Results: Reference Example 5

As indicated in Table V, for evaluation thin films 5-7 to 5-11, Vₐₗₗ/V_{core} of the phosphorescent metal complex exceeds 2. In addition, since they used a core-shell type phosphorescent metal complex having a chemical structure represented by the formula defined in the present invention, it was confirmed that a small Kq value (Kq relative ratio) was obtained as a thin film of red light emission by suppressing energy transfer from the phosphorescent metal complex to the quenching substance.

### Example 1

In Example 1, the characteristics of a white light illumination device (organic EL element) containing a green phosphorescent metal complex and a blue fluorescent compound were evaluated. Example 1 is an example in the case of no fluorescent sensitization.

### (Preparation of Lighting Device 1-1)

An anode was prepared by making patterning to a glass substrate having a thickness of 0.7 mm on which ITO (indium tin oxide) was formed with a thickness of 110 nm. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On the transparent support substrate thus prepared was applied a 70% solution of poly (3,4-ethylenedioxythiphene)-polystyrene sulfonate (PEDOT/PSS, Baytron P AI4083, made by Bayer AG.) diluted with water by using a spin coating method at 3,000 rpm for 30 seconds to form a film, and then it was dried at 130° C. for one hour. A hole injection-transport layer having a thickness of 30 nm was prepared. Then, the resulting transparent support substrate was fixed to a substrate holder of a commercial vacuum deposition apparatus. As a resistance heating boat for vapor deposition, a resistance heating boat made of molybdenum or tungsten was used.

Then, after reducing the pressure of a vacuum tank to 4×10⁻⁴ Pa, a green phosphorescent metal complex GD-1, a compound RD-3, a compound F-1 and a compound H-2 were co-deposited with a thickness of 80 nm so that the phosphorescent metal complex was 1 volume %, the compound RD-3 was 0.5 volume %, the compound F-1 was 15.5 volume %, and the compound H-2 was 83 volume % to form a light emitting layer (hereinafter abbreviated as EML). Subsequently, ET-1 was deposited with a thickness of 30 nm, whereby an electron transport layer was formed. Subsequently, 2 nm thick potassium fluoride (KF) was vapor deposited, and then, 150 nm thick aluminum was vapor deposited to form a cathode.

Subsequently, the non-light emitting surface of the prepared organic EL element was covered with a glass cover. Thus, a lighting device 1-1 was prepared.

The sealing operation with the glass cover was performed in a glove box (in an atmosphere of high purity nitrogen gas having a purity of 99.999% or more) in a nitrogen atmosphere without bringing the lighting device 1-1 into contact with the atmosphere.

Next, lighting devices 1-2 to 1-5 were prepared in the same manner as preparation of the lighting device 1-1, except that the phosphorescent metal complex of the lighting device 1-1 was changed to the phosphorescent metal complex indicated in Table VI.

For the prepared lighting devices 1-1 to 1-5, the half-time lifetime was measured as described below and the continuous driving stability was evaluated. In addition, the external extraction quantum efficiency was measured as described below, and the light emitting property was evaluated.

### <Half-Life>

The half-life was evaluated according to the following measurement method.

The prepared lighting device was driven with a constant electric current to give an initial luminance of 4,000 cd/m². The time required for decease in one half of the initial luminance was determined, and it was used as a scale for a half-life. The emission lifetime was represented as a relative value when the emission lifetime of the lighting device 1-1 was set to be 100.

When the value is larger, it indicates that the durability is better compared with the comparative sample.

### <External Extraction Quantum Efficiency (EQE)>

Each lighting device was allowed to emit light with a constant electric current of 2.5 mA/cm² at room temperature (at about 23° C.). The external extraction quantum efficiency (EQE) was determined by measuring the luminance (L0) (cd/m²) measured immediately after starting to emit light.

Here, the measurement of luminance was done with Spectroradiometer CS-2000 (produced by Konica Minolta Inc.). The external extraction quantum efficiency was represented by a relative value when the external quantum efficiency of the lighting device 1-1 was set to be 100.

TABLE VI

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 1-1 | GD-1 | 1.00 | 1.0 | 1.00 | 1.00 | Comparative |
| | | | | | | example |
| 1-2 | GD-5 | 1.02 | 1.2 | 1.01 | 1.30 | Comparative |
| | | | | | | example |
| 1-3 | CD-40 | 0.74 | 2.3 | 1.27 | 2.78 | Present |
| | | | | | | invention |
| 1-4 | CD-41 | 0.75 | 2.1 | 1.32 | 2.20 | Present |
| | | | | | | invention |
| 1-5 | CD-45 | 0.51 | 3.3 | 1.54 | 2.64 | Present |
| | | | | | | invention |

As indicated in Table VI, Vₐₗₗ/V_{core} of the phosphorescent metal complex exceeds 2. In addition, it was revealed that the lighting devices 1-3 to 1-5, which used a core-shell type phosphorescent metal complex having a chemical structure represented by the formula defined in the present invention, emitted white light with high efficiency and long lifetime. This is presumably because the thermal deactivation by the Dexter transfer from the green phosphorescent metal complex to the T₁ of the fluorescent material was suppressed and the green phosphorescence emission was performed efficiently.

### Example 2

Next, in Example 2, characteristics of a lighting device (organic EL element) that emits blue fluorescence were confirmed. Here, Examples 2 to 8 are examples in the case where there is fluorescence sensitization.

### <Preparation of Lighting Device for Evaluation>

An anode was prepared to a glass substrate of 50 mm×50 mm having a thickness of 0.7 mm on which ITO (indium tin oxide) was formed with a thickness of 150 nm. After performing pattering, the above transparent support substrate provided with the ITO transparent electrode was subjected to ultrasonic washing with isopropyl alcohol, followed by drying with desiccated nitrogen gas, and was subjected to UV ozone washing for 5 minutes. Then, the resulting transparent support substrate was fixed to a substrate holder of a commercial vacuum deposition apparatus.

In each of the resistance heating boats for vapor deposition in the vacuum vapor deposition apparatus, the constituent material of each layer was filled in an optimum amount for device fabrication. The resistance heating boat was made of molybdenum or tungsten.

After reducing the pressure to a vacuum degree of 1×10⁻⁴ Pa, the resistance heating boat containing HI-1 was energized and heated to deposit it on the ITO transparent electrode at a vapor deposition rate of 0.1 mn/sec to result in forming a hole injection layer having a thickness of 15 nm.

Next, HT-1 was vapor-deposited at a deposition rate of 0.1 mn/sec to form a hole transport layer having a thickness of 30 nm.

Subsequently, the resistance heating boats each containing H-1, the phosphorescent metal complex indicated in Table VII, and F-1 were energized and heated to obtain 84 volume % of the host, 15 volume % of the phosphorescent metal complex, 1 volume % of the fluorescent compound, respectively. Thus, a light emitting layer having a thickness of 40 nm was formed.

Next, HB-1 was vapor-deposited at a deposition rate of 0.1 mn/sec to form a first electron transport layer having a thickness of 5 nm. Further thereon, ET-1 was vapor-deposited at a deposition rate of 0.1 mn/sec to form a second electron transport layer having a thickness of 45 nm. Thereafter, lithium fluoride was evaporated to a layer thickness of 0.5 nm, and then aluminum was evaporated to a thickness of 100 nm to form a cathode. Thus, an organic EL element for evaluation was prepared.

After preparation of the organic EL element, a non-light emitting surface of the prepared organic EL element was covered with a glass cover under the atmosphere of high purity nitrogen gas of 99.999% or more. A glass substrate having a thickness of 300 μm was used as a sealing substrate. As a sealing material, an epoxy-based light curable adhesive (LUXTRACK LC0629B produced by Toagosei Co., Ltd,) was applied to the periphery of the glass substrate. The resulting one was superimposed on the cathode side to be brought into close contact with the transparent support substrate. Curing and sealing were carried out via exposure of UV radiation onto the glass substrate side, whereby the lighting devices 2-1 to 2-5 for evaluation having the constitution illustrated in FIG. 11 and FIG. 12 were formed.

With respect to the produced lighting devices 2-1 to 2-5, the half-life was measured in the same manner as in Example 1, and the continuous driving stability was evaluated. In addition, the external extraction quantum efficiency was measured and the light emitting property was evaluated. The half-life and the external extraction quantum efficiency were expressed as relative ratios with the values of the lighting device 2-1 being set to 1.

The evaluation results are listed in Table VII.

TABLE VII

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 2-1 | BD-2 | 1.00 | 1.0 | 1.00 | 2.15 | Comparative |
| | | | | | | example |
| 2-2 | CD-2 | 0.75 | 1.6 | 1.23 | 2.42 | Present |
| | | | | | | invention |
| 2-3 | CD-10 | 0.65 | 2.0 | 1.36 | 2.29 | Present |
| | | | | | | invention |
| 2-4 | CD-16 | 0.51 | 3.2 | 1.77 | 2.41 | Present |
| | | | | | | invention |
| 2-5 | CD-25 | 0.50 | 3.5 | 1.69 | 2.80 | Present |
| | | | | | | invention |

As indicated in Table VII, for the lighting devices 2-2 to 2-5 that emit blue fluorescence, Vₐₗₗ/V_{core} of the phosphorescent metal complex exceeds 2. In addition, it was revealed that the lighting devices 2-2 to 2-5, which used a core-shell type phosphorescent metal complex having a chemical structure represented by the formula defined in the present invention as a fluorescent sensitizer, emitted blue light with high efficiency and long lifetime.

### Example 3

Next, in Example 3, characteristics of lighting devices (organic EL elements) that included a plurality of organic functional layers and emit blue fluorescent light were confirmed.

### <Preparation of Lighting Device for Evaluation>

An anode was prepared to a glass substrate of 50 mm×50 mm having a thickness of 0.7 mm on which ITO (indium tin oxide) was formed with a thickness of 150 nm. After performing pattering, the above transparent support substrate provided with the ITO transparent electrode was subjected to ultrasonic washing with isopropyl alcohol, followed by drying with desiccated nitrogen gas, and was subjected to UV ozone washing for 5 minutes. Then, the resulting transparent support substrate was fixed to a substrate holder of a commercial vacuum deposition apparatus.

In each of the resistance heating boats for vapor deposition in the vacuum vapor deposition apparatus, the constituent material of each layer was filled in an optimum amount for device fabrication. The resistance heating boat was made of molybdenum or tungsten.

After reducing the pressure to a vacuum degree of 1×10⁻⁴ Pa, the resistance heating boat containing HI-2 was energized and heated to deposit it on the ITO transparent electrode at a vapor deposition rate of 0.1 mn/sec to result in forming a hole injection layer having a thickness of 10 nm.

Next, HT-2 was vapor-deposited at a deposition rate of 0.1 mn/sec to form a hole transport layer having a thickness of 30 nm.

Subsequently, the resistance heating boats each containing H-2 and F-2 were energized and heated to obtain 99 volume % of the host and 1 volume % of the fluorescent compound, respectively. Thus, a first organic functional layer having a thickness of 10 nm was formed. Then, H-2 and the phosphorescent metal complex indicated in Table VIII were co-deposited to obtain 85 volume % and 15 volume %, respectively. Thus, a second organic functional layer having a thickness of 20 nm was formed.

Next, HB-2 was vapor-deposited at a deposition rate of 0.1 mn/sec to form a first electron transport layer having a thickness of 5 nm. Further thereon, ET-2 was vapor-deposited at a deposition rate of 0.1 mn/sec to form a second electron transport layer having a thickness of 45 nm. Thereafter, lithium fluoride was evaporated to a layer thickness of 0.5 nm, and then aluminum was evaporated to a thickness of 100 nm to form a cathode. Thus, an organic EL element for evaluation was prepared.

After preparation of the organic EL element, a non-light emitting surface of the prepared organic EL element was covered with a glass cover under the atmosphere of high purity nitrogen gas of 99.999% or more. A glass substrate having a thickness of 300 μm was used as a sealing substrate. As a sealing material, an epoxy-based light curable adhesive (LUXTRACK LC0629B produced by Toagosei Co., Ltd,) was applied to the periphery of the glass substrate. The resulting one was superimposed on the cathode side to be brought into close contact with the transparent support substrate. Curing and sealing were carried out via exposure of UV radiation onto the glass substrate side, whereby the lighting devices for evaluation having the constitution illustrated in FIG. 11 and FIG. 12 were formed.

### <Evaluation of Continuous Driving Stability (Half-Life) and Light Emitting Property (External Extraction Quantum Efficiency)>

Evaluation of the continuous driving stability (half-life) and the light emitting property (external extraction quantum efficiency) was carried out by the same way as in Example 1.

For each lighting device for evaluation, relative ratios were obtained when the half-life and the external extraction quantum efficiency (EQE) of the lighting device for evaluation 3-1 were set to be 1. The evaluation results are listed in Table VIII.

TABLE VIII

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 3-1 | BD-2 | 1.00 | 1.0 | 1.00 | 2.15 | Comparative |
| | | | | | | example |
| 3-2 | CD-4 | 0.73 | 1.6 | 1.31 | 3.32 | Present |
| | | | | | | invention |
| 3-3 | CD-7 | 0.69 | 1.8 | 1.38 | 2.09 | Present |
| | | | | | | invention |
| 3-4 | CD-35 | 0.49 | 3.0 | 1.69 | 2.76 | Present |
| | | | | | | invention |
| 3-5 | CD-38 | 0.48 | 3.1 | 1.65 | 2.43 | Present |
| | | | | | | invention |

As indicated in Table VIII, for the lighting devices 3-2 to 3-5 that emit blue fluorescence, Vₐₗₗ/V_{core} of the phosphorescent metal complex exceeds 2. In addition, since the lighting devices 3-2 to 3-5 used a core-shell type phosphorescent metal complex having a chemical structure represented by the formula defined in the present invention as a fluorescent sensitizer, it was revealed that even the lighting devices having a fluorescent compound and a phosphorescent metal complex contained in separate layers emitted blue light with high efficiency and long lifetime.

### Example 4

Next, in Example 4, characteristics of a lighting device (organic EL element) that emits blue fluorescence were confirmed.

### <Preparation of Lighting Device for Evaluation>

An anode was prepared to a glass substrate of 50 mm×50 mm having a thickness of 0.7 mm on which ITO (indium tin oxide) was formed with a thickness of 150 nm. After performing pattering, the above transparent support substrate provided with the ITO transparent electrode was subjected to ultrasonic washing with isopropyl alcohol, followed by drying with desiccated nitrogen gas, and was subjected to UV ozone washing for 5 minutes. Then, the resulting transparent support substrate was fixed to a substrate holder of a commercial vacuum deposition apparatus.

In each of the resistance heating boats for vapor deposition in the vacuum vapor deposition apparatus, the constituent material of each layer was filled in an optimum amount for device fabrication. The resistance heating boat was made of molybdenum or tungsten.

After reducing the pressure to a vacuum degree of 1×10⁻⁴ Pa, the resistance heating boat containing HI-1 was energized and heated to deposit it on the ITO transparent electrode at a vapor deposition rate of 0.1 mn/sec to result in forming a hole injection layer having a thickness of 15 nm.

Next, HT-1 was vapor-deposited at a deposition rate of 0.1 mn/sec to form a hole transport layer having a thickness of 30 nm.

Subsequently, the resistance heating boats each containing H-3, the phosphorescent metal complex indicated in Table IX, and F-1 were energized and heated to obtain 80 volume % of the host, 19 volume % of the phosphorescent metal complex, 1 volume % of the fluorescent compound, respectively. Thus, a light emitting layer having a thickness of 40 nm was formed.

Next, HB-1 was vapor-deposited at a deposition rate of 0.1 mn/sec to form a first electron transport layer having a thickness of 5 nm. Further thereon, ET-1 was vapor-deposited at a deposition rate of 0.1 mn/sec to form a second electron transport layer having a thickness of 45 nm. Thereafter, lithium fluoride was evaporated to a layer thickness of 0.5 nm, and then aluminum was evaporated to a thickness of 100 nm to form a cathode. Thus, an organic EL element for evaluation was prepared.

After preparation of the organic EL element, a non-light emitting surface of the prepared organic EL element was covered with a glass cover under the atmosphere of high purity nitrogen gas of 99.999% or more. A glass substrate having a thickness of 300 μm was used as a sealing substrate. As a sealing material, an epoxy-based light curable adhesive (LUXTRACK LC0629B produced by Toagosei Co., Ltd,) was applied to the periphery of the glass substrate. The resulting one was superimposed on the cathode side to be brought into close contact with the transparent support substrate. Curing and sealing were carried out via exposure of UV radiation onto the glass substrate side, whereby the lighting devices for evaluation having the constitution illustrated in FIG. 11 and FIG. 12 were formed.

<Evaluation of continuous driving stability (half-life) and light emitting property (external extraction quantum efficiency)>

Evaluation of the continuous driving stability (half-life) and the light emitting property (external extraction quantum efficiency) was carried out by the same way as in Example 1.

For each lighting device for evaluation, relative ratios were obtained when the half-life and the external extraction quantum efficiency (EQE) of the lighting device for evaluation 4-1 were set to be 1. The HOMO energy level and the LUMO energy level of the fluorescent compound and the phosphorescent metal complex were determined by Gaussian 98, a software for calculating the molecular orbital (Gaussian 98, Revision A. 11.4, M. J. Frisch, et al, Gaussian, Inc., Pittsburgh PA, 2002).

The evaluation results are listed in Table IX and Table X.

TABLE IX

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 4-1 | BD-8 | 1.00 | 1.0 | 1.00 | 2.78 | Comparative |
| | | | | | | example |
| 4-2 | CD-18 | 0.51 | 3.1 | 1.61 | 2.75 | Present |
| | | | | | | invention |
| 4-3 | CD-19 | 0.48 | 2.2 | 1.31 | 2.42 | Present |
| | | | | | | invention |
| 4-4 | CD-24 | 0.49 | 3.4 | 1.59 | 2.64 | Present |
| | | | | | | invention |

TABLE X

| Fluorescent compound/ | | |
|---|---|---|
| Phosphorescent | LUMO energy level | HOMO energy level |
| metal complex | (eV) | (eV) |
| F-1 | −1.7 | −4.7 |
| CD-18 | −0.6 | −4.3 |
| CD-19 | −1.4 | −5.3 |
| CD-24 | −1.8 | −5.8 |

As indicated in Table IX, for the lighting devices 4-2 to 4-4 that emit blue fluorescence, Vₐₗₗ/V_{core} of the phosphorescent metal complex exceeds 2. In addition, it was revealed that the lighting devices 4-2 to 4-4, which used a phosphorescent metal complex (core-shell type dopant) according to the present invention as a fluorescent sensitizer, emitted light with high efficiency and long lifetime. In particular, in the lighting devices 4-2 and 4-4 in which the core-shell type phosphorescent metal complex and the fluorescent compound F-1 satisfy either one of Expression (c) and Expression (d), it was found that fluorescence was emitted with higher efficiency and longer lifetime. This is presumably because the carrier direct recombination on the fluorescent compound could be suppressed by satisfying at least one of Expression (c) and Expression (d).

### Example 5

Next, in Example 5, characteristics of a lighting device (organic EL element) that emits green fluorescence were confirmed.

### <Preparation of Lighting Device for Evaluation>

An anode was prepared to a glass substrate of 50 mm×50 mm having a thickness of 0.7 mm on which ITO (indium tin oxide) was formed with a thickness of 150 nm. After performing pattering, the above transparent support substrate provided with the ITO transparent electrode was subjected to ultrasonic washing with isopropyl alcohol, followed by drying with desiccated nitrogen gas, and was subjected to UV ozone washing for 5 minutes. Then, the resulting transparent support substrate was fixed to a substrate holder of a commercial vacuum deposition apparatus.

In each of the resistance heating boats for vapor deposition in the vacuum vapor deposition apparatus, the constituent material of each layer was filled in an optimum amount for device fabrication. The resistance heating boat was made of molybdenum or tungsten.

After reducing the pressure to a vacuum degree of 1×10⁻⁴ Pa, the resistance heating boat containing HI-2 was energized and heated to deposit it on the ITO transparent electrode at a vapor deposition rate of 0.1 mn/sec to result in forming a hole injection layer having a thickness of 10 nm.

Next, HT-1 was vapor-deposited at a deposition rate of 0.1 mn/sec to form a hole transport layer having a thickness of 20 nm.

Subsequently, the resistance heating boats each containing H-4, the phosphorescent metal complex indicated in Table XI, and F-3 were energized and heated to obtain 84 volume % of the host, 15 volume % of the phosphorescent metal complex, 1 volume % of the fluorescent compound, respectively. Thus, a light emitting layer having a thickness of 30 nm was formed.

Next, HB-3 was vapor-deposited at a deposition rate of 0.1 mn/sec to form a first electron transport layer having a thickness of 10 nm. Further thereon, ET-2 was vapor-deposited at a deposition rate of 0.1 mn/sec to form a second electron transport layer having a thickness of 40 nm. Thereafter, lithium fluoride was evaporated to a layer thickness of 0.5 nm, and then aluminum was evaporated to a thickness of 100 nm to form a cathode. Thus, an organic EL element for evaluation was prepared.

After preparation of the organic EL element, a non-light emitting surface of the prepared organic EL element was covered with a glass cover under the atmosphere of high purity nitrogen gas of 99.999% or more. A glass substrate having a thickness of 300 μm was used as a sealing substrate. As a sealing material, an epoxy-based light curable adhesive (LUXTRACK LC0629B produced by Toagosei Co., Ltd,) was applied to the periphery of the glass substrate. The resulting one was superimposed on the cathode side to be brought into close contact with the transparent support substrate. Curing and sealing were carried out via exposure of UV radiation onto the glass substrate side, whereby the lighting devices for evaluation having the constitution illustrated in FIG. 11 and FIG. 12 were formed.

### <Evaluation of Continuous Driving Stability (Half-Life) and Light Emitting Property (External Extraction Quantum Efficiency)>

Evaluation of the continuous driving stability (half-life) and the light emitting property (external extraction quantum efficiency) was carried out by the same way as in Example 1.

For each lighting device for evaluation, relative ratios were obtained when the half-life and the external extraction quantum efficiency (EQE) of the lighting device for evaluation 5-1 were set to be 1.

TABLE XI

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 5-1 | GD-1 | 1.00 | 1.0 | 1.00 | 1.00 | Comparative |
| | | | | | | example |
| 5-2 | GD-5 | 1.02 | 1.1 | 1.01 | 1.30 | Comparative |
| | | | | | | example |
| 5-3 | CD-40 | 0.74 | 2.1 | 1.29 | 2.78 | Present |
| | | | | | | invention |
| 5-4 | CD-41 | 0.75 | 2.0 | 1.31 | 2.20 | Present |
| | | | | | | invention |
| 5-5 | CD-45 | 0.51 | 3.1 | 1.49 | 2.64 | Present |
| | | | | | | invention |

As indicated in Table XI, for the lighting devices 5-3 to 5-5 that emit green fluorescence, Vₐₗₗ/V_{core} of the metal complex exceeds 2. In addition, it was revealed that the lighting devices 5-3 to 5-5, which used a phosphorescent metal complex (core-shell type dopant) according to the present invention as a fluorescent sensitizer. emitted fluorescence with high efficiency and long lifetime.

### Example 6

Next, in Example 6, characteristics of a lighting device (organic EL element) that emits red fluorescence were confirmed.

### <Preparation of Lighting Device for Evaluation>

An anode was prepared to a glass substrate of 50 mm×50 mm having a thickness of 0.7 mm on which ITO (indium tin oxide) was formed with a thickness of 150 nm. After performing pattering, the above transparent support substrate provided with the ITO transparent electrode was subjected to ultrasonic washing with isopropyl alcohol, followed by drying with desiccated nitrogen gas, and was subjected to UV ozone washing for 5 minutes.

On the transparent support substrate thus prepared was applied a 70% solution of poly (3,4-ethylenedioxythiphene)-polystyrene sulfonate (PEDOT/PSS, Baytron P A14083, made by Bayer AG.) diluted with water by using a spin coating method at 3,000 rpm for 30 seconds to form a film, and then it was dried at 200° C. for one hour. Thus, a hole injection layer having a thickness of 20 nm was prepared.

Then, the resulting transparent support substrate was fixed to a substrate holder of a commercial vacuum deposition apparatus.

In each of the resistance heating boats for vapor deposition in the vacuum vapor deposition apparatus, the constituent material of each layer was filled in an optimum amount for device fabrication. The resistance heating boat was made of molybdenum or tungsten.

After reducing the pressure to a vacuum degree of 1×10⁻⁴ Pa, the resistance heating boat containing HT-2 was energized and heated to deposit it on the hole injection layer at a vapor deposition rate of 0.1 nm/sec to result in forming a hole transport layer having a thickness of 20 nm.

Subsequently, the resistance heating boats each containing H-5, the metal complex indicated in Table XII, and F-4 were energized and heated to obtain 80 volume % of the host, 158 volume % of the phosphorescent metal complex, 1 volume % of the fluorescent compound, respectively. Thus, a light emitting layer having a thickness of 30 nm was formed. Next, HB-2 was vapor-deposited at a deposition rate of 0.1 nm/sec to form a first electron transport layer having a thickness of 5 nm.

Then, ET-1 was vapor-deposited at a deposition rate of 0.1 mn/sec to form an electron transport layer having a thickness of 40 nm.

Thereafter, lithium fluoride was evaporated to a layer thickness of 0.5 nm, and then aluminum was evaporated to a thickness of 100 nm to form a cathode. Thus, an organic EL element for evaluation was prepared.

After preparation of the organic EL element, a non-light emitting surface of the prepared organic EL element was covered with a glass cover under the atmosphere of high purity nitrogen gas of 99.999% or more. A glass substrate having a thickness of 300 μm was used as a sealing substrate. As a sealing material, an epoxy-based light curable adhesive (LUXTRACK LC0629B produced by Toagosei Co., Ltd,) was applied to the periphery of the glass substrate. The resulting one was superimposed on the cathode side to be brought into close contact with the transparent support substrate. Curing and sealing were carried out via exposure of UV radiation onto the glass substrate side, whereby the lighting devices for evaluation having the constitution illustrated in FIG. 11 and FIG. 12 were formed.

### <Evaluation of Continuous Driving Stability (Half-Life) and Light Emitting Property (External Extraction Quantum Efficiency)>

Evaluation of the continuous driving stability (half-life) and the light emitting property (external extraction quantum efficiency) was carried out by the same way as in Example 1.

For each lighting device for evaluation, relative ratios were obtained when the half-life and the external extraction quantum efficiency (EQE) of the lighting device for evaluation 6-1 were set to be 1.

TABLE XII

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No, | No. | Kq relative ratio | ratio | ratio | value | Remarks |
| 6-1 | RD-1 | 1.00 | 1.0 | 1.00 | 1.15 | Comparative |
| | | | | | | example |
| 6-2 | RD-2 | 1.01 | 1.1 | 1.01 | 2.24 | Comparative |
| | | | | | | example |
| 6-3 | CD-46 | 0.71 | 2.2 | 1.30 | 2.20 | Present |
| | | | | | | invention |
| 6-4 | CD-48 | 0.59 | 3.0 | 1.51 | 2.02 | Present |
| | | | | | | invention |
| 6-5 | CD-49 | 0.57 | 3.2 | 1.49 | 2.08 | Present |
| | | | | | | invention |

As indicated in Table XII, for the lighting devices 6-3 to 6-5 that emit red fluorescence, Vₐₗₗ/V_{core} of the metal complex exceeds 2. In addition, it was revealed that the lighting devices 6-3 to 6-5, which used a core-shell type phosphorescent metal complex having a structure defined in the present invention as a fluorescent sensitizer, emitted fluorescence with high efficiency and long lifetime.

### Example 7

Next, in Example 7, properties of a lighting device (and an element) that emits blue fluorescent light produced by a wet process using a coating solution were confirmed.

### <<Preparation of Lighting Device for Evaluation>>

### (Preparation of Substrate)

First, on the entire surface of a polyethylene naphthalate film (hereinafter abbreviated as PEN) (manufactured by Teijin DuPont Films Co. Ltd.) on which the anode is to be formed, an atmospheric pressure plasma discharge treatment using an apparatus having the structure described in JP-A 2004-68143 was carried out to form an inorganic gas barrier layer made of SiOₓ having a thickness of 500 nm. In this way, a flexible substrate having gas barrier properties of an oxygen permeability of 0.001 mL/(m²·24 h) or less and a water vapor permeability of 0.001 g/(m²·24 h) or less was prepared.

### (Formation of Anode)

ITO (indium tin oxide) having a thickness of 120 nm was formed on the above-described substrate by a sputtering method and patterned by a photolithography method. Thus, an anode was formed. The pattern was such that the area of the light emitting region was 5 cm×5 cm.

### (Formation of Hole Injection Layer)

The substrate on which the anode was formed was subjected to ultrasonic washing with isopropyl alcohol, followed by drying with desiccated nitrogen gas, and was subjected to UV ozone washing for 5 minutes. Then, a dispersion liquid of poly (3,4-ethylenedioxythiophene)/polystyrene sulfonate (PEDOT/PSS) was prepared in the same manner as in Example 16 of Japanese Patent No. 4,509,787. A 2 mass % solution prepared by diluting the above-described dispersion liquid with isopropyl alcohol was applied by a die coating method and followed by air dried to form a hole injection layer having a thickness of 40 nm.

### (Formation of Hole Transport Layer)

Subsequently, the substrate on which the hole injection layer was formed was transferred under a nitrogen atmosphere using nitrogen gas (grade G1), and the coating solution for forming a hole transport layer having the following composition was coated by a die coating method at 5 m/min, followed by air dried, and then kept at 130° C. for 30 minutes. Thus, a hole transport layer having a thickness of 30 nm was formed.

### <Coating Solution for Forming Hole Transport Layer>

| | | |
|---|---|---|
| Hole transport material HT-3 | 10 | mass parts |
| (weight average molecular weight Mw = 80000): | | |
| Chlorobenzene: | 3000 | mas parts |

### (Formation of Light Emitting Layer)

Subsequently, the substrate on which the hole transport layer was formed was coated by a die coating method at a coating rate of 5 m/min using a coating solution for forming a light emitting layer having the following composition, followed by air dried, and then kept at 120° C. for 30 minutes. Thus, a light emitting layer having a thickness of 50 nm was formed.

### <Coating Solution for Forming Light Emitting Layer>

| | | |
|---|---|---|
| Host compound H-6: | 9 | mass parts |
| Phosphorescent metal complex indicated in Table XIII: | 1 | mass part |
| Fluorescent compound F-1: | 0.1 | mass parts |
| Isopropyl acetate: | 2,000 | mass parts |

### (Formation of Blocking Layer)

Subsequently, the substrate on which the light emitting layer was formed was coated by a die coating method at a coating rate of 5 m/min using a coating solution for forming a blocking layer having the following composition, followed by air dried, and then kept at 80° C. for 30 minutes. Thus, a blocking layer having a thickness of 10 nm was formed.

### <Coating Solution for Forming Blocking Layer>

| | | |
|---|---|---|
| HB-4: | 2 | mass parts |
| Isopropyl alcohol (IPA): | 1500 | mass parts |
| 2,2,3,3,4,4,5,5-Octafluoro-1-pentanol: | 500 | mass parts |

### (Formation of Electron Transport Layer)

Subsequently, the substrate on which the blocking layer was formed was coated by a die coating method at a coating rate of 5 m/min using a coating solution for forming an electron transport layer having the following composition, followed by air dried, and then kept at 80° C. for 30 minutes. Thus, an electron transport layer having a thickness of 30 nm was formed.

### <Coating Solution for Forming Electron Transport Layer>

| | | |
|---|---|---|
| ET-1: | 6 | mass parts |
| 2,2,3,3-Tetrafluoro-1-propanol: | 2000 | mass parts |

### (Formation of Electron Injection Layer and Cathode)

Subsequently, the substrate was attached to a vacuum vapor deposition apparatus without exposure to the atmosphere.

Also, molybdenum resistance heating boats each containing sodium fluoride and potassium fluoride were attached to the vacuum evaporation apparatus, and the vacuum chamber was reduced to 4×10⁻⁵ Pa. Thereafter, the boat was energized and heated, and sodium fluoride was vapor-deposited on the electron transport layer at 0.02 mn/sec. Thus, a thin film having a thickness of 1 nm was formed. Similarly, potassium fluoride was vapor-deposited on the sodium fluoride thin film at 0.02 mn/sec. Thus, an electron injection layer with a layer thickness of 1.5 nm was formed.

Subsequently, aluminum was vapor-deposited to form a cathode having a thickness of 100 nm.

### (Sealing)

To the laminate body formed by the above steps, a sealing substrate was bonded using a commercially available roll laminating apparatus.

As a sealing substrate, the following material was prepared. An adhesive layer having a layer thickness of 1.5 μm was provided on a flexible aluminum foil having a thickness of 30 μm (made by Toyo Aluminum K.K.) using a two-liquid reaction type urethane adhesive for dry lamination, then a polyethylene terephthalate (PET) film having a thickness of 12 μm was laminated.

A thermosetting adhesive as a sealing adhesive was uniformly applied with a thickness of 20 μm along the adhesive surface (gloss surface) of the aluminum foil of the sealing substrate using a dispenser. This was dried under a vacuum of 100 Pa or less for 12 hours. Further, the sealing substrate was moved to a nitrogen atmosphere having a dew point temperature of −80° C. or less and an oxygen concentration of 0.8 ppm and dried for 12 hours or more, and the moisture content of the sealing adhesive was adjusted to be 100 ppm or less.

As the thermosetting adhesive, an epoxy adhesive obtained by mixing the following (A) to (C) was used.
(A) Bisphenol A diglycidyl ether (DGEBA)
(B) Dicyandiamide (DICY)
(C) Epoxy adduct type curing accelerator

The sealing substrate was brought into close contact with the above laminate body and tightly sealed under a pressure bonding condition of a pressure roll temperature of 100° C., a pressure of 0.5 MPa, and a machine speed of 0.3 m/min using a pressure roll.

As described above, the organic EL element 7-1 to the organic EL element 7-5 having the same configuration as that of the organic EL element having the configuration indicated in FIG. 13 were prepared and used as the lighting device 7-1 to the lighting device 7-5.

### <<Evaluation of Continuous Driving Stability (Half-Life) and Light Emitting Property (External Extraction Quantum Efficiency)>>

Evaluation of the continuous driving stability (half-life) and the light emitting property (external extraction quantum efficiency) was carried out by the same way as in Example 1.

For each lighting device for evaluation, relative ratios were obtained when the half-life and the external extraction quantum efficiency (EQE) of the lighting device for evaluation 7-1 were set to be 1.

TABLE XIII

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 7-1 | BD-2 | 1.00 | 1.0 | 1.00 | 2.15 | Comparative |
| | | | | | | example |
| 7-2 | CD-2 | 0.75 | 1.4 | 1.21 | 2.42 | Present |
| | | | | | | invention |
| 7-3 | CD-13 | 0.61 | 2.1 | 1.38 | 2.74 | Present |
| | | | | | | invention |
| 7-4 | CD-19 | 0.47 | 3.5 | 1.75 | 2.42 | Present |
| | | | | | | invention |
| 7-5 | CD-26 | 0.51 | 3.4 | 1.80 | 2.42 | Present |
| | | | | | | invention |

As indicated in Table XIII, for the lighting devices 7-2 to 7-5 that emit blue fluorescence, Vₐₗₗ/V_{core} of the metal complex exceeds 2. In addition, it was revealed that the lighting devices 7-2 to 7-5, which used a core-shell type phosphorescent metal complex having a chemical structure represented by the formula defined in the present invention as a fluorescent sensitizer, emitted fluorescence with high efficiency and long lifetime even in the lighting device produced by the coating process.

### Example 8

Next, in Example 8, characteristics of a lighting device (and an element) for emitting blue fluorescence prepared by an ink-jet method were confirmed.

### <<Preparation of Lighting Device for Evaluation>>

### (Preparation of Substrate)

First, on the entire surface of a polyethylene naphthalate film (hereinafter abbreviated as PEN) (manufactured by Teijin DuPont Films Co. Ltd.) on which the anode is to be formed, an atmospheric pressure plasma discharge treatment using an apparatus having the structure described in JP-A 2004-68143 was carried out to form an inorganic gas barrier layer made of SiOₓ having a thickness of 500 nm. In this way, a flexible substrate having gas barrier properties of an oxygen permeability of 0.001 mL/(m²·24 h) or less and a water vapor permeability of 0.001 g/(m²·24 h) or less was prepared.

### (Formation of Anode)

ITO (indium tin oxide) having a thickness of 120 nm was formed on the above-described substrate by a sputtering method and patterned by a photolithography method. Thus, an anode was formed. The pattern was such that the area of the light emitting region was 5 cm×5 cm.

### (Formation of Hole Injection Layer)

The substrate on which the anode was formed was subjected to ultrasonic washing with isopropyl alcohol, followed by drying with desiccated nitrogen gas, and was subjected to UV ozone washing for 5 minutes. Then, a dispersion liquid of poly (3,4-ethylenedioxythiophene)/polystyrene sulfonate (PEDOT/PSS) was prepared in the same manner as in Example 16 of Japanese Patent No. 4,509,787. A 2 mass % solution prepared by diluting the above-described dispersion liquid with isopropyl alcohol was applied by an ink-jet method and dried at 80° C. for 5 minutes to form a hole injection layer having a thickness of 40 nm.

### (Formation of Hole Transport Layer)

Subsequently, the substrate on which the hole injection layer was formed was transferred under a nitrogen atmosphere using nitrogen gas (grade G1), and the coating solution for forming a hole transport layer having the following composition was coated by an ink-jet method and followed by dried at 150° C. for 30 minutes. Thus, a hole transport layer having a thickness of 30 nm was formed.

### <Coating Solution for Forming Hole Transport Layer>

| | | |
|---|---|---|
| Hole transport material HT-3 | 10 | mass parts |
| (weight average molecular weight Mw = 80000): | | |
| para (p)-Xylene: | 3000 | mas parts |

### (Formation of Light Emitting Layer)

Subsequently, the substrate on which the hole transport layer was formed was coated by an ink-jet method using a coating solution for forming a light emitting layer having the following composition, and then dried at 130° C. for 30 minutes. Thus, a light emitting layer having a thickness of 50 nm was formed.

### <Coating Solution for Forming Light Emitting Layer>

| | | |
|---|---|---|
| Host compound H-4: | 9 | mass parts |
| Metal complex indicated in Table XIV: | 1 | mass part |
| Fluorescent compound F-1: | 0.1 | mass parts |
| n-Butyl acetate: | 2000 | mass parts |

### (Formation of Blocking Layer)

Subsequently, the substrate on which the light emitting layer was formed was coated by an ink-jet method using a coating solution for forming a blocking layer having the following composition, followed by dried at 80° C. for 30 minutes. Thus, a blocking layer having a thickness of 10 nm was formed.

### <Coating Solution for Forming Blocking Layer>

| | | |
|---|---|---|
| HB-4: | 2 | mass parts |
| Isopropyl alcohol (IPA): | 1500 | mass parts |
| 2,2,3,3,4,4,5,5-Octafluoro-1-pentanol: | 500 | mass parts |

### (Formation of Electron Transport Layer)

Subsequently, the substrate on which the blocking layer was formed was coated by an ink-jet method using a coating solution for forming an electron transport layer having the following composition, followed by dried at 80° C. for 30 minutes. Thus, an electron transport layer having a thickness of 30 nm was formed.

### <Coating Solution for Forming Electron Transport Layer>

| | | |
|---|---|---|
| ET-1: | 6 | mass parts |
| 2,2,3,3-Tetrafluoro-1-propanol: | 2000 | mass parts |

### (Formation of Electron Injection Layer and Cathode)

Subsequently, the substrate was attached to a vacuum vapor deposition apparatus without exposure to the atmosphere.

Also, molybdenum resistance heating boats containing sodium fluoride and potassium fluoride were attached to the vacuum evaporation apparatus, and the vacuum chamber was reduced to 4×10⁻⁵ Pa. Thereafter, the boat was energized and heated, and sodium fluoride was vapor-deposited on the electron transport layer at 0.02 mn/sec. Thus, a thin film having a thickness of 1 nm was formed. Similarly, potassium fluoride was vapor-deposited on the sodium fluoride thin film at 0.02 mn/sec. Thus, an electron injection layer with a layer thickness of 1.5 nm was formed.

Subsequently, aluminum was vapor-deposited to form a cathode having a thickness of 100 nm.

### (Sealing)

To the laminate body formed by the above steps, a sealing substrate was bonded using a commercially available roll laminating apparatus.

As a sealing substrate, the following material was prepared. An adhesive layer having a layer thickness of 1.5 μm was provided on a flexible aluminum foil having a thickness of 30 μm (made by Toyo Aluminum K.K.) using a two-liquid reaction type urethane adhesive for dry lamination, then a polyethylene terephthalate (PET) film having a thickness of 12 μm was laminated.

A thermosetting adhesive as a sealing adhesive was uniformly applied with a thickness of 20 μm along the adhesive surface (gloss surface) of the aluminum foil of the sealing substrate using a dispenser. This was dried under a vacuum of 100 Pa or less for 12 hours. Further, the sealing substrate was moved to a nitrogen atmosphere having a dew point temperature of −80° C. or less and an oxygen concentration of 0.8 ppm and dried for 12 hours or more, and the moisture content of the sealing adhesive was adjusted to be 100 ppm or less.

As the thermosetting adhesive, an epoxy adhesive obtained by mixing the following (A) to (C) was used.
(A) Bisphenol A diglycidyl ether (DGEBA)
(B) Dicyandiamide (DICY)
(C) Epoxy adduct type curing accelerator

The sealing substrate was brought into close contact with the above laminate body and tightly sealed under a pressure bonding condition of a pressure roll temperature of 100° C., a pressure of 0.5 MPa, and a machine speed of 0.3 m/min using a pressure roll. In the manner described above, an organic EL element 8-1 having the same configuration as that of the organic EL element having the structure indicated in FIG. 1 was produced.

### <<Evaluation of Continuous Driving Stability (Half-Life) and Light Emitting Property (External Extraction Quantum Efficiency)>>

Evaluation of the continuous driving stability (half-life) and the light emitting property (external extraction quantum efficiency) was carried out by the same way as in Example 1.

For each lighting device for evaluation, relative ratios were obtained when the half-life and the external extraction quantum efficiency (EQE) of the lighting device for evaluation 8-1 were set to be 1.

TABLE XIV

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 8-1 | BD-2 | 1.00 | 1.0 | 1.00 | 2.15 | Comparative |
| | | | | | | example |
| 8-2 | CD-2 | 0.75 | 1.3 | 1.24 | 2.42 | Present |
| | | | | | | invention |
| 8-3 | CD-13 | 0.61 | 2.0 | 1.37 | 2.74 | Present |
| | | | | | | invention |
| 8-4 | CD-19 | 0.47 | 3.2 | 1.77 | 2.42 | Present |
| | | | | | | invention |
| 8-5 | CD-26 | 0.51 | 3.5 | 1.81 | 2.42 | Present |
| | | | | | | invention |

As indicated in Table XIV, for the lighting devices 8-2 to 8-5 that emit blue fluorescence, Vₐₗₗ/V_{core} of the phosphorescent metal complex exceeds 2. In addition, it was revealed that the lighting devices 8-2 to 8-5, which used a core-shell type phosphorescent metal complex having a chemical structure represented by the formula defined in the present invention as a fluorescent sensitizer, emitted blue light with high efficiency and long lifetime even in the lighting device produced by an ink-jet process.

### Example 9

### (Preparation of Substrate)

In preparation of the substrate in Example 8, the film thickness of the gas barrier layer was suitably adjusted to have a water vapor permeability of 0.00001 to 0.8 g/(m²·day), and an oxygen permeability of 0.000012 to 1 mL/(m²·day·atm) was prepared.

### (Formation of Light Emitting Element)

In the same manner as in Example 8 except that the electron injecting layer in Example 8 was changed to the following, a substrate having the gas barrier layer thickness indicated in Table XV was used, respectively, and the lighting devices 8-11 to 15, 8-21 to 25, 8-31 to 35, 8-41 to 45, 8-51 and 8-52 were prepared.

### (Formation of Electron Injecting Layer)

Sodium fluoride and potassium fluoride in Example 8 were changed to lithium fluoride to form an electron injection layer with a thickness of 1.0 nm.

### [Evaluation Test of Dark Spot (DS)]

The lighting devices 8-11 to 15, 8-21 to 25, 8-31 to 35, 8-41 to 45, 8-51 and 8-52 each were stored for 500 hours under the environment of 85° C. and 8% RH. Thereafter, a current of 1 mA/cm² was applied to each lighting device to emit light. Next, with a 100-power optical microscope (MS-804 manufactured by Moritex Corporation, lens MP-ZE 25-200), a part of the light emitting part of the lighting device was enlarged and photographed. Then, the photographed image was cut into 2 mm square, and the presence or absence of occurrence of dark spot was observed for each image. From the observation result, the ratio of the area where the dark spot occurred to the light emitting area was obtained, and the dark spot resistance was evaluated according to the following criteria.
5: No dark spot is observed at all
4: The generation area of the dark spot is 0.1% or more and less than 1.0%
3: The generation area of the dark spot is 1.0% or more and less than 3.0%
2: Dark spot generation area is 3.0% or more and less than 6.0%
1: The area where the dark spot is generated is 6.0% or more

### [Evaluation of Continuous Driving Stability (Half-Life)]

In each of the lighting devices 8-11 to 15, 8-21 to 25, 8-31 to 35, 8-41 to 45, 8-51 and 8-52, continuous driving stability was evaluated in the environment of 85° C. and 85% RH.

TABLE XV

| | Thickness | | | | | | | |
|---|---|---|---|---|---|---|---|---|
| | of gas | | | | | | | |
| | barrier | | OTR | Phosphorescent | | | Half-life | |
| Lighting | layer | WVTR | [mL/(m² · | metal complex | Vₐₗₗ/V_{core} | DS | relative | |
| device No. | (nm) | [g/(m² · day)] | day · atm)] | No. | value | evaluation | ratio | Remarks |
| 8-11 | 900 | 1.0 × 10⁻⁵ | 1.2 × 10⁻⁵ | BD-2 | 2.15 | 5 | 1.00 | Comparative example |
| 8-12 | 900 | 1.0 × 10⁻⁵ | 1.2 × 10⁻⁵ | CD-2 | 2.42 | 5 | 1.24 | Present invention |
| 8-13 | 900 | 1.0 × 10⁻⁵ | 1.2 × 10⁻⁵ | CD-13 | 2.74 | 5 | 1.37 | Present invention |
| 8-14 | 900 | 1.0 × 10⁻⁵ | 1.2 × 10⁻⁵ | CD-19 | 2.42 | 5 | 1.77 | Present invention |
| 8-15 | 900 | 1.0 × 10⁻⁵ | 1.2 × 10⁻⁵ | CD-26 | 2.42 | 5 | 1.81 | Present invention |
| 8-21 | 500 | 1.0 × 10⁻³ | 1.2 × 10⁻³ | BD-2 | 2.15 | 2 | 0.50 | Comparative example |
| 8-22 | 500 | 1.0 × 10⁻³ | 1.2 × 10⁻³ | CD-2 | 2.42 | 5 | 1.10 | Present invention |
| 8-23 | 500 | 1.0 × 10⁻³ | 1.2 × 10⁻³ | CD-13 | 2.74 | 5 | 1.30 | Present invention |
| 8-24 | 500 | 1.0 × 10⁻³ | 1.2 × 10⁻³ | CD-19 | 2.42 | 5 | 1.60 | Present invention |
| 8-25 | 500 | 1.0 × 10⁻³ | 1.2 × 10⁻³ | CD-26 | 2.42 | 5 | 1.65 | Present invention |
| 8-31 | 200 | 1.0 × 10⁻¹ | 1.2 × 10⁻¹ | BD-2 | 2.15 | 1 | 0.20 | Comparative example |
| 8-32 | 200 | 1.0 × 10⁻¹ | 1.2 × 10⁻¹ | CD-2 | 2.42 | 4 | 0.87 | Present invention |
| 8-33 | 200 | 1.0 × 10⁻¹ | 1.2 × 10⁻¹ | CD-13 | 2.74 | 5 | 1.25 | Present invention |
| 8-34 | 200 | 1.0 × 10⁻¹ | 1.2 × 10⁻¹ | CD-19 | 2.42 | 4 | 1.24 | Present invention |
| 8-35 | 200 | 1.0 × 10⁻¹ | 1.2 × 10⁻¹ | CD-26 | 2.42 | 4 | 1.27 | Present invention |
| 8-41 | 50 | 8.0 × 10⁻¹ | 1.0 | BD-2 | 2.15 | 1 | 0.05 | Comparative example |
| 8-42 | 50 | 8.0 × 10⁻¹ | 1.0 | CD-2 | 2.42 | 3 | 0.70 | Present invention |
| 8-43 | 50 | 8.0 × 10⁻¹ | 1.0 | CD-13 | 2.74 | 4 | 1.10 | Present invention |
| 8-44 | 50 | 8.0 × 10⁻¹ | 1.0 | CD-19 | 2.42 | 3 | 1.02 | Present invention |
| 8-45 | 50 | 8.0 × 10⁻¹ | 1.0 | CD-26 | 2.42 | 3 | 1.05 | Present invention |
| 8-51 | 0 | 2.0 × 10 | 2.5 × 10 | BD-2 | 2.15 | 1 | 0.02 | Comparative example |
| 8-52 | 0 | 2.0 × 10 | 2.5 × 10 | CD-26 | 2.42 | 3 | 0.63 | Present invention |

### Effect of the Invention

As indicated in Table XV, Vₐₗₗ/V_{core} of the phosphorescent metal complex exceeds 2. It has become clear that the lighting device of the present invention using the compound represented by the formula defined in the present invention was capable of suppressing the generation of dark spots even if the gas barrier property of the flexible substrate is not high. In addition, the lighting device of the present invention was able to obtain satisfactory results also in driving evaluation under the environment of 85° C. and 85% RH. That is, by reducing the thickness, it was confirmed that there was no problem in practical use even for a barrier substrate which was prepared with low cost.

### Example 10

Lighting devices 9-2 to 9-5 were produced in the same manner as in Example 2 except that F-1 was changed to F-5. As for the evaluation of half-life and external extraction quantum efficiency, as in Example 2, the evaluation was expressed by the relative ratio when the value of the lighting device 2-1 was set to be 1. The results are shown in Table XVI.

TABLE XVI

| Lighting | Phosphorescent | Phosphorescent | Half-life | EQE | | |
|---|---|---|---|---|---|---|
| Device | metal complex | metal complex | relative | relative | Vₐₗₗ/V_{core} | |
| No. | No. | Kq relative ratio | ratio | ratio | value | Remarks |
| 2-1 | BD-2 | 1.00 | 1.0 | 1.00 | 2.15 | Comparative |
| | | | | | | example |
| 9-2 | CD-2 | 0.75 | 1.9 | 1.47 | 2.42 | Present |
| | | | | | | invention |
| 9-3 | CD-10 | 0.65 | 2.5 | 1.55 | 2.29 | Present |
| | | | | | | invention |
| 9-4 | CD-16 | 0.51 | 3.8 | 1.84 | 2.41 | Present |
| | | | | | | invention |
| 9-5 | CD-25 | 0.50 | 4.1 | 1.78 | 2.80 | Present |
| | | | | | | invention |

### Conclusion

As can be seen by comparing the results of Example 2 (Table VII) and Example 10 (Table XVI), it was revealed that Example 10 that used a core-shell type dopant of the present invention and improved the exciton discharging ability was proved to further improve the EQE relative ratio and the half-life relative ratio as compared with Example 2.

### Example 11

Lighting device 10-1 was produced in the same manner

as production of lighting device 9-4, except that the fluorescent compound (F-5) was not added to the light emitting layer.

The lighting devices 2-4, 9-4 and 10-1 were evaluated as follows and the evaluation results are listed in Table XVII. Each of the following evaluations was expressed as a relative ratio when the value of the lighting device 10-1 was set to be 1.

### (Acceleration Coefficient)

From the time when the initial luminance was halved by current-driving at 2.5 mA/cm² and 16.25 mA/cm², the multiplier obtained by extrapolating it with a power approximate curve was taken as the acceleration factor. That is, the acceleration coefficient is n in the following equation (E).

$${t}_{1} / {t}_{2} = {( {L}_{1} / {L}_{2} )}^{- n} \qquad Equation ( E )$$

L₁: Initial luminance at application of a current density of 2.5 mA/cm²
L₂: Initial luminance at application of a current density of 16.25 mA/cm²
t₁: Luminance half-life of the element at luminance L₁ (low luminance and low current 2.5 mA/cm²)
t₂: Luminance half-life of the element at luminance L₂ (high luminance and high current 16.25 mA/cm²

Here, the measurement of luminance was done with Spectroradiometer CS-2000 (produced by Konica Minolta Inc.).

TABLE XVII

| | Phos- | Fluo- | | Accel- | |
|---|---|---|---|---|---|
| Lighting | phorescent | rescent | Half- | eration | |
| | metal | com- | life | factor | |
| Device | complex | pound | Relative | relative | |
| No. | No. | No. | ratio | ratio | Remarks |
| 10-1 | CD-16 | — | 1.00 | 1.00 | Comparative |
| | | | | | example |
| 2-4 | CD-16 | F-1 | 1.24 | 0.95 | Present |
| | | | | | invention |
| 9-4 | CD-16 | F-5 | 1.55 | 0.90 | Present |
| | | | | | invention |

### Conclusion

By comparing the lighting devices 2-4 and 9-4, it was revealed that the overlapping of the emission spectrum of the phosphorescent metal complex and the absorption spectrum of the fluorescent compound is increased by changing from F-1 to F-5, and as a result, and The Förster energy transfer works more favorably, which in turn contributes efficiently to halving the long half-life and increasing the acceleration factor (refer to lighting devices 2-4 and 9-4).

### INDUSTRIAL APPLICABILITY

The organic EL element of the present invention is capable of emitting light with high luminous efficiency and long lifetime, and it may be used as a display device, a display, and various light emission sources.

### DESCRIPTION OF SYMBOLS

1: Display
3: Pixel
5: Scanning line
6: Data line
A: Display section
B: Control section
10: Core-shell type dopant
11: Core portion
12: Shell portion
13: Fluorescent compound
14: Host
20: Conventional dopant
101: Organic EL element
102: Glass cover
105: Cathode
106: Organic EL layer
107: Glass substrate having a transparent electrode
108: Nitrogen gas
109: Water catching agent
201: Flexible support substrate
202: Anode
203: Hole injection layer
204: Hole transport layer
205: Light emitting layer
206: Electron transport layer
207: Electron injection layer
208: Cathode
209: Sealing adhesive
210: Flexible sealing member
200: Organic EL element

What is claimed is:

1. An organic electroluminescent element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by Formula (1), and the phosphorescent metal complex satisfies the following Expression (a), 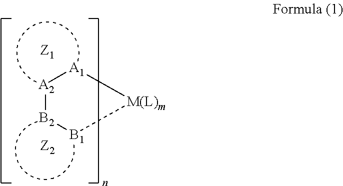
in Formula (1): M represents Ir or Pt; A₁, A₂, B₁ and B₂ each independently represent a carbon atom or a nitrogen atom; a ring Z₁ represents a 6-membered aromatic hydrocarbon ring, or a 5- or 6-membered aromatic heterocyclic ring formed with A₁ and A₂, or an aromatic condensed ring containing at least one of the aforesaid rings; a ring Z₂ represents a 5- or 6-membered aromatic heterocyclic ring formed with B₁ and B₂, or an aromatic condensed ring containing at least one of the aforesaid rings; among a bond between A₁ and M, and a bond between B₁ and M, one is a coordinate bond and the other is a covalent bond; the ring Z₁ and the ring Z₂ each independently may have a substituent, and the ring Z₁ and the ring Z₂ have at least one substituent represented by Formula (2); the substituent of the ring Z₁ and the substituent of the ring Z₂ may be bonded to form a condensed ring structure, and ligands represented by the ring Z₁ and the ring Z₂ may be linked to each other; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, the ligands represented by the ring Z₁ and the ring Z₂, or L may be the same or different; the ligand represented by the ring Z₁ and the ring Z₂ may be linked to L, 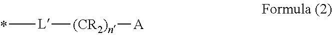
in Formula (2), a symbol * represents a linking site with the ring Z₁ or the ring Z₂ in Formula (1); L′ represents a single bond or a linking group; R represents a hydrogen atom or a substituent; n′ represents an integer of 3 or more; a plurality of Rs may be the same or different; and A represents a hydrogen atom or a substituent,
$$\{ {V}_{all} / {V}_{core} \} > 2 \qquad Expression ( a )$$
in Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions;
wherein the organic functional layer is a light emitting layer;
wherein an emission spectrum of the phosphorescent metal complex and an absorption spectrum of the fluorescent compound are overlapped;
wherein the phosphorescent metal complex is a sensitizer that transfers energy to the fluorescent compound to cause fluorescent light to be emitted from the fluorescent compound.

2. The organic electroluminescent element described in claim 1, wherein L′ in Formula (2) represents a non-conjugated linking group.

3. The organic electroluminescent element described in claim 1, wherein the ligands represented by Z₁ and Z₂ in Formula (1) contain three or more substituents.

4. The organic electroluminescent element described in claim 1, wherein the phosphorescent metal complex is a compound having a structure represented by any one of Formulas (3) to (5), and the phosphorescent metal complex satisfies the following Expression (b), 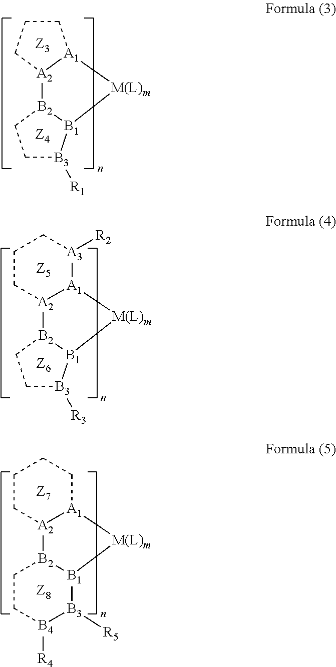
in Formulas (3) to (5): M represents Ir or Pt; A₁ to A₃, and B₁ to B₄ each independently represent a carbon atom or a nitrogen atom; among a bond between A₁ and M, and a bond between B₁ and M, one is a coordinate bond and the other is a covalent bond; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, ligands represented by a ring Z₃ and a ring Z₄, ligands represented by a ring Z₅ and a ring Z₆, and ligands represented by a ring Z₇ and a ring Z₈, or L may be the same or different; the ligands represented by the ring Z₃ to Z₈ may be linked to L,
in Formula (3), the ring Z₃ represents a 5-membered aromatic heterocyclic ring formed with A₁ and A₂, or an aromatic condensed ring containing the aforesaid ring; the ring Z₄ represents a 5-membered aromatic heterocyclic ring formed with B₁ to B₃, or an aromatic condensed ring containing the aforesaid ring; R₁ represents a substituent having 2 or more carbon atoms; the ring Z₃ and the ring Z₄ may have a substituent besides R₁ and may form a condensed ring structure by bonding of the substituents of the ring Z₃ and the ring Z4; the ligands represented by the ring Z₃ and the ring Z₄ may be linked to each other,
in Formula (4), the ring Z₅ represents a 6-membered aromatic hydrocarbon ring, a 6-membered aromatic heterocyclic ring formed with A₁ to A₃, or an aromatic condensed ring containing at least one of the aforesaid rings; the ring Z₆ represents a 5-membered aromatic heterocyclic ring formed with B₁ to B₃, or an aromatic condensed ring containing at least one of the aforesaid rings; R₂ and R₃ each represent a hydrogen atom or a substituent, at least one of R₂ and R₃ represents a substituent having 2 or more carbon atoms; the ring Z₅ and the ring Z₆ may have a substituent besides R₂ and R₃ and may form a condensed ring structure by bonding of the substituents of the ring Z₅ and the ring Z₆, and the ligands represented by the ring Z₅ and the ring Z₆ may be linked to each other,
in Formula (5), the ring Z₇ represents a 6-membered aromatic hydrocarbon ring, a 6-membered aromatic heterocyclic ring formed with A₁ and A₂, or an aromatic condensed ring containing at least one of the aforesaid rings; the ring Z₈ represents a 6-membered aromatic hydrocarbon ring or a 6-membered aromatic heterocyclic ring formed with B₁ to B₄, or an aromatic condensed ring containing at least one of the aforesaid rings; R₄ and R₅ each represent a hydrogen atom or a substituent, at least one of R₄ and R₅ represents a substituent having 2 or more carbon atoms; the ring Z₇ and the ring Z₈ may have a substituent besides R₄ and R₅ and may form a condensed ring structure by bonding of the substituents of the ring Z₇ and the ring Z₈, and the ligands represented by the ring Z₇ and the ring Z₈ may be linked to each other,
$$\{ {V}_{all} / {V}_{core} \} > 2 \qquad Expression ( b )$$
In Expression (b), Vₐₗₗ represents a molecular volume of a compound having a chemical structure represented by any one of Formulas (3) to (5) including the substituents bonded to the ring Z₃ to the ring Z₈; when M represents Ir, n=3 and m=0 are fixed, and when M represents Pt, n=2 and m=0 are fixed; V_{core} represents a molecular volume of a compound having a chemical structure in which the substituent bonded to the ring Z₃ to the ring Z₈ is replaced with a hydrogen atom from the chemical structure indicating the molecular volume of Vₐₗₗ; and when there are a plurality of ligands represented by the ring Z₃ and the ring Z₄, ligands represented by the ring Z₅ and the ring Z₆, ligands represented by the ring Z₇ and the ring Z₈, Vₐₗₗ and V_{core} satisfy Expression (b) in all cases expressed by the aforesaid conditions.

5. The organic electroluminescent element described in claim 4, wherein the ligands represented by the ring Z₃ and the ring Z₄ in Formula (3), the ligands represented by the ring Z₅ and the ring Z₆ in Formula (4), or the ligands represented by the ring Z₇ and the ring Z₈ in Formula (5) have three or more substituents.

6. The organic electroluminescent element described in claim 1, wherein the phosphorescent metal complex and the fluorescent compound satisfy the following Expression (A1);
$$0 < τ / {τ}_{0} , \leq 0.7 ; \qquad Expression ( A1 )$$
in Expression (A1), r is the light emission-attenuation lifetime of the light emitting layer single layer; to is the light emission-attenuation lifetime of the single film of the phosphorescent compound;
wherein the light emitting layer single layer refers to an evaluation thin film prepared as a spectrum measurement sample that includes a host compound, a phosphorescent compound, and a fluorescent compound;
wherein the single film of the phosphorescent compound refers to a thin film containing the host compound and the phosphorescent compound among the evaluation films that contains the host compound, the phosphorescent compound and the fluorescent compound.

7. The organic electroluminescent element described in claim 1, wherein the phosphorescent metal complex and the fluorescent compound satisfy at least one of the following Expression (c) and Expression (d),
$$P ( HOMO ) > FL ( HOMO ) \qquad Expression ( c )$$
in Expression (c), P(HOMO) represents a HOMO energy level of the phosphorescent metal complex, and FL(HOMO) represents a HOMO energy level of the fluorescent compound,
$$P ( LUMO ) < FL ( LUMO ) \qquad Expression ( d )$$
in Expression (d), P(LUMO) represents a LUMO energy level of the phosphorescent metal complex, and FL(LUMO) represents a LUMO energy level of the fluorescent compound.

8. The organic electroluminescent element described in claim 1, wherein the phosphorescent metal complex and the fluorescent compound satisfy the following Expression (A2);
$$0.6 \leq PLQE / {PLQE}_{0} \leq 1 ; \qquad Expression ( A2 )$$
in Expression (A2), PLQE is the absolute quantum yield of the light emitting layer single layer; PLQE₀ is the absolute quantum yield of the single film of the phosphorescent compound;
wherein the light emitting layer single layer refers to an evaluation thin film prepared as a spectrum measurement sample that includes a host compound, a phosphorescent compound, and a fluorescent compound;
wherein the single film of the phosphorescent compound refers to a thin film containing the host compound and the phosphorescent compound among the evaluation films that contains the host compound, the phosphorescent compound and the fluorescent compound.

9. The organic electroluminescent element described in claim 1, wherein {Vₐₗₗ/V_{core}}>2.5.

10. The organic electroluminescent element described in claim 1, wherein the fluorescent compound is selected from the group consisting of an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, and a rare earth complex compound.

11. The organic electroluminescent element described in claim 1, wherein the fluorescent compound is a boron complex.

12. The organic electroluminescent element described in claim 1, wherein the fluorescent compound is a delayed fluorescent compound.

13. The organic electroluminescent element described in claim 1, wherein the fluorescent compound comprises a fused ring system having at least five rings.

14. The organic electroluminescent element described in claim 1, wherein the fluorescent compound comprises at least four alkyl substituents.

15. A composition for organic materials containing a phosphorescent metal complex and a fluorescent compound, wherein the phosphorescent metal complex is a compound having a structure represented by Formula (1), and the phosphorescent metal complex satisfies the following Expression (a), 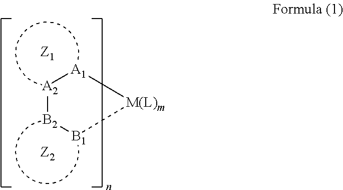
in Formula (1): M represents Ir or Pt; A₁, A₂, B₁ and B₂ each independently represent a carbon atom or a nitrogen atom; a ring Z₁ represents a 6-membered aromatic hydrocarbon ring, or a 5- or 6-membered aromatic heterocyclic ring formed with A₁ and A₂, or an aromatic condensed ring containing at least one of the aforesaid rings; a ring Z₂ represents a 5- or 6-membered aromatic heterocyclic ring formed with B₁ and B₂, or an aromatic condensed ring containing at least one of the aforesaid rings; among a bond between A₁ and M, and a bond between B₁ and M, one is a coordinate bond and the other is a covalent bond; the ring Z₁ and the ring Z₂ each independently may have a substituent, and the ring Z₁ and the ring Z₂ have at least one substituent represented by Formula (2); the substituent of the ring Z₁ and the substituent of the ring Z₂ may be bonded to form a condensed ring structure, and ligands represented by the ring Z₁ and the ring Z₂ may be linked to each other; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, the ligands represented by the ring Z₁ and the ring Z₂, or L may be the same or different; the ligand represented by the ring Z₁ and the ring Z₂ may be linked to L, 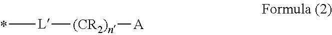
in Formula (2), a symbol * represents a linking site with the ring Z₁ or the ring Z₂ in Formula (1); L′ represents a single bond or a linking group; R represents a hydrogen atom or a substituent; n′ represents an integer of 3 or more; a plurality of Rs may be the same or different; and A represents a hydrogen atom or a substituent,
$$\{ {V}_{all} / {V}_{core} \} > 2 \qquad Expression ( a )$$
in Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions;
wherein an emission spectrum of the phosphorescent metal complex and an absorption spectrum of the fluorescent compound are overlapped;
wherein when the composition is used in a light emitting layer of an organic electroluminescent element, the phosphorescent metal complex is as a sensitizer that transfers energy to the fluorescent compound to cause fluorescent light to be emitted from the fluorescent compound.

16. The composition described in claim 15, wherein the phosphorescent metal complex is a compound having a structure represented by any one of Formulas (3) to (5), and the phosphorescent metal complex satisfies the following Expression (b), 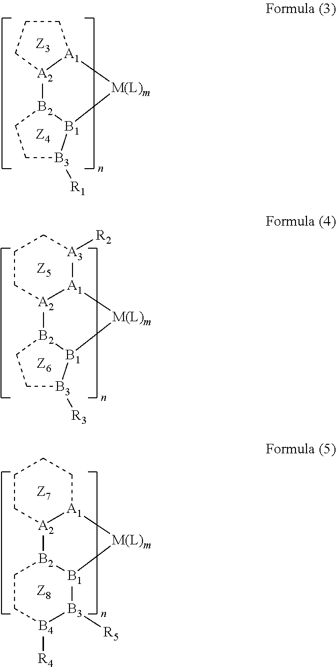
in Formulas (3) to (5): M represents Ir or Pt; A₁ to A₃, and B₁ to B₄ each independently represent a carbon atom or a nitrogen atom; among a bond between A₁ and M, and a bond between B₁ and M, one is a coordinate bond and the other is a covalent bond; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, ligands represented by a ring Z₃ and a ring Z₄, ligands represented by a ring Z₅ and a ring Z₆, and ligands represented by a ring Z₇ and a ring Z₈, or L may be the same or different; the ligands represented by the ring Z₃ to Z₈ may be linked to L,
in Formula (3), the ring Z₃ represents a 5-membered aromatic heterocyclic ring formed with A₁ and A₂, or an aromatic condensed ring containing the aforesaid ring; the ring Z₄ represents a 5-membered aromatic heterocyclic ring formed with B₁ to B₃ or an aromatic condensed ring containing the aforesaid ring; R₁ represents a substituent having 2 or more carbon atoms; the ring Z₃ and the ring Z₄ may have a substituent besides R₁ and may form a condensed ring structure by bonding of the substituents of the ring Z₃ and the ring Z4; the ligands represented by the ring Z₃ and the ring Z₄ may be linked to each other,
in Formula (4), the ring Z₅ represents a 6-membered aromatic hydrocarbon ring, a 6-membered aromatic heterocyclic ring formed with A₁ to A₃, or an aromatic condensed ring containing at least one of the aforesaid rings; the ring Z₆ represents a 5-membered aromatic heterocyclic ring formed with B₁ to B₃, or an aromatic condensed ring containing at least one of the aforesaid rings; R₂ and R₃ each represent a hydrogen atom or a substituent, at least one of R₂ and R₃ represents a substituent having 2 or more carbon atoms; the ring Z₅ and the ring Z₆ may have a substituent besides R₂ and R₃ and may form a condensed ring structure by bonding of the substituents of the ring Z₅ and the ring Z₆, and the ligands represented by the ring Z₅ and the ring Z₆ may be linked to each other,
in Formula (5), the ring Z₇ represents a 6-membered aromatic hydrocarbon ring, a 6-membered aromatic heterocyclic ring formed with A₁ and A₂, or an aromatic condensed ring containing at least one of the aforesaid rings; the ring Z₈ represents a 6-membered aromatic hydrocarbon ring or a 6-membered aromatic heterocyclic ring formed with B₁ to B₄, or an aromatic condensed ring containing at least one of the aforesaid rings; R₄ and R₅ each represent a hydrogen atom or a substituent, at least one of R₄ and R₅ represents a substituent having 2 or more carbon atoms; the ring Z₇ and the ring Z₈ may have a substituent besides R₄ and R₅ and may form a condensed ring structure by bonding of the substituents of the ring Z₇ and the ring Z₈, and the ligands represented by the ring Z₇ and the ring Z₈ may be linked to each other,
$$\{ {V}_{all} / {V}_{core} \} > 2 \qquad Expression ( b )$$
in Expression (b), Vₐₗₗ represents a molecular volume of a compound having a chemical structure represented by any one of Formulas (3) to (5) including the substituents bonded to the ring Z₃ to the ring Z₈; when M represents Ir, n=3 and m=0 are fixed, and when M represents Pt, n=2 and m=0 are fixed; V_{core} represents a molecular volume of a compound having a chemical structure in which the substituent bonded to the ring Z₃ to the ring Z₈ is replaced with a hydrogen atom from the chemical structure indicating the molecular volume of Vₐn; and when there are a plurality of ligands represented by the ring Z₃ and the ring Z₄, ligands represented by the ring Z₅ and the ring Z₆, ligands represented by the ring Z₇ and the ring Z₈, Vₐₗₗ and V_{core} satisfy Expression (b) in all cases expressed by the aforesaid conditions.

17. The composition described in claim 15, wherein the fluorescent compound is selected from the group consisting of an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, and a rare earth complex compound.

18. The composition described in claim 15, wherein the fluorescent compound is a boron complex.

19. The composition described in claim 15, wherein the fluorescent compound comprises a fused ring system having at least five rings.

20. An organic electroluminescent element comprising an anode, a cathode and one or a plurality of organic functional layers interposed between the anode and the cathode, wherein the organic functional layer contains a phosphorescent metal complex and a fluorescent compound, the phosphorescent metal complex is a compound having a structure represented by Formula (1), and the phosphorescent metal complex satisfies the following Expression (a), 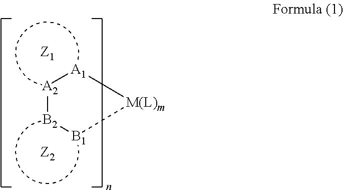
in Formula (1): M represents Ir or Pt; A₁, A₂, B₁ and B₂ each independently represent a carbon atom or a nitrogen atom; a ring Z₁ represents a 6-membered aromatic hydrocarbon ring, or a 5- or 6-membered aromatic heterocyclic ring formed with A₁ and A₂, or an aromatic condensed ring containing at least one of the aforesaid rings; a ring Z₂ represents a 5- or 6-membered aromatic heterocyclic ring formed with B₁ and B₂, or an aromatic condensed ring containing at least one of the aforesaid rings; among a bond between A₁ and M, and a bond between B₁ and M, one is a coordinate bond and the other is a covalent bond; the ring Z₁ and the ring Z₂ each independently may have a substituent, and the ring Z₁ and the ring Z₂ have at least one substituent represented by Formula (2); the substituent of the ring Z₁ and the substituent of the ring Z₂ may be bonded to form a condensed ring structure, and ligands represented by the ring Z₁ and the ring Z₂ may be linked to each other; L represents a monoanionic bidentate ligand coordinated to M, and L may have a substituent; m represents an integer of 0 to 2, n represents an integer of 1 to 3, when M represents Ir, m+n is 3, and when m represents Pt, m+n is 2, when m or n is 2 or more, the ligands represented by the ring Z₁ and the ring Z₂, or L may be the same or different; the ligand represented by the ring Z₁ and the ring Z₂ may be linked to L, 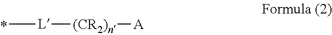
in Formula (2), a symbol * represents a linking site with the ring Z₁ or the ring Z₂ in Formula (1); L′ represents a single bond or a linking group; R represents a hydrogen atom or a substituent; n′ represents an integer of 3 or more; a plurality of Rs may be the same or different; and A represents a hydrogen atom or a substituent,
$$\{ {V}_{all} / {V}_{core} \} > 2 \qquad Expression ( a )$$
in Expression (a), Vₐₗₗ represents a molecular volume of a compound having a chemical structure represented by Formula (1) including the substituents bonded to the ring Z₁ and the ring Z₂; when M represents Ir, n=3 and m=0 are fixed, and when M represents Pt, n=2 and m=0 are fixed; V_{core} represents a molecular volume of a compound having a chemical structure in which the substituent bonded to the ring Z₁ and the ring Z₂ is replaced with a hydrogen atom from the chemical structure indicating the molecular volume of Vₐₗₗ; and when there are plural types of ligands represented by the ring Z₁ and the ring Z₂, Vₐₗₗ and V_{core} satisfy Expression (a) in all cases expressed by the aforesaid conditions;
wherein the organic functional layer is a light emitting layer;
wherein an emission spectrum of the phosphorescent metal complex and an absorption spectrum of the fluorescent compound are overlapped;
wherein the phosphorescent metal complex is a sensitizer that transfers energy to the fluorescent compound to cause fluorescent light to be emitted from the fluorescent compound;
wherein the fluorescent compound is a boron complex.
